(19) United States
(12) Patent Application Publication
(10) Pub. No.: US 2024/0223962 A1
(43) Pub. Date: Jul. 4, 2024

(54) VIBRATION APPARATUS AND DISPLAY APPARATUS INCLUDING THE SAME

(71) Applicant: LG Display Co., Ltd., Seoul (KR)

(72) Inventors: Uihyeon JEONG, Paju-si (KR); YongWoo LEE, Paju-si (KR); JounHo LEE, Paju-si (KR); Sooyoun KIM, Paju-si (KR); HwaYoul LEE, Paju-si (KR)

(73) Assignee: LG Display Co., Ltd., Seoul (KR)

(21) Appl. No.: 18/386,922

(22) Filed: Nov. 3, 2023

(30) Foreign Application Priority Data
Dec. 30, 2022 (KR) 10-2022-0190418

(51) Int. Cl. H04R 17/00; H04R 1/02; H10N 30/87

(52) U.S. Cl. CPC H04R 17/00; H04R 1/028; H10N 30/871; H04R 2499/15

(57) ABSTRACT

A vibration apparatus includes a conductive substrate, at least one vibration layer at one surface of the conductive substrate, and at least one electrode layer at one surface of the vibration layer. The vibration layer and the electrode layer are alternately arranged in a stack on the surface of the conductive substrate.

### CROSS-REFERENCE TO RELATED APPLICATIONS

This application claims priority to Korean Patent Application No. 10-2022-0190418 filed in the Republic of Korea on Dec. 30, 2022, the entire contents of which is hereby expressly incorporated by reference into the present application.

### BACKGROUND

### Technical Field

The present disclosure relates to a vibration apparatus and a display apparatus including the same.

### Discussion of the Related Art

Display apparatuses include a display panel which displays an image and a sound apparatus for outputting sounds associated with an image displayed by the display panel. In display apparatuses, a screen is being progressively enlarged but the demand for a screen that is light and thin is increasing.

In this regard, because the display apparatuses need to have a sufficient space for embedding a sound apparatus such as a speaker for outputting sounds, it can be challenging to lighten and miniaturize the thickness of the display apparatuses. Further, a sound generated by the sound apparatus embedded in the display apparatus is generally output in a rearward direction or a sideward direction of the display apparatus instead of a forward direction of a display panel. Thus, the sound may not travel well toward a viewer or a user who is watching an image at a front position with respect to the display panel, which can cause a limitation of the immersion experience of a viewer watching an image being reduced.

Moreover, a speaker applied to such display apparatuses can be, for example, an actuator including a magnet and a coil. However, when the actuator is applied to the display apparatus, the thickness of the display apparatus can increase, which is not desirable.

### SUMMARY OF THE DISCLOSURE

An aspect of the present disclosure is directed to providing a vibration apparatus and a display apparatus including the same, which can vibrate a display panel to output a sound in a forward direction of the display panel.

Another aspect of the present disclosure is directed to providing a vibration apparatus and a display apparatus including the same, which can output a sound in a forward direction of a display panel, enhance the quality of a sound, and enhance a sound pressure level characteristic.

Another aspect of the present disclosure is directed to providing a vibration apparatus and a display apparatus including the same, which can output a sound in a forward direction of a display panel and can be slimmed.

Another aspect of the present disclosure is directed to providing a vibration apparatus integrated into a display panel and a display apparatus including the same.

Additional features, advantages, and aspects of the present disclosure are set forth in the present disclosure and will also be apparent from the present disclosure or can be learned by practice of the inventive concepts provided herein. Other features, advantages, and aspects of the present disclosure can be realized and attained by the structure particularly pointed out in the present disclosure, or derivable therefrom, and claims hereof as well as the appended drawings.

To achieve these and other advantages and aspects of the present disclosure, as embodied and broadly described herein, in one or more aspects, a vibration apparatus can include a conductive substrate, at least one vibration layer at one surface of the conductive substrate, and at least one electrode layer at one surface of the vibration layer. The vibration layer and the electrode layer can be alternately arranged in a stack on the surface of the conductive substrate.

In one or more aspects, a vibration apparatus can include a display panel and one or more vibration generating apparatuses configured to vibrate the display panel. Each of the one or more vibration generating apparatuses can include a conductive substrate, at least one vibration layer at one surface of the conductive substrate, and at least one electrode layer at one surface of the vibration layer. The vibration layer and the electrode layer can be alternately arranged in a stack on the surface of the conductive substrate.

According to an embodiment of the present disclosure, a vibration apparatus and a display apparatus including the same, which can vibrate a display panel to output a sound in a forward direction of the display panel, can be provided.

According to an embodiment of the present disclosure, a vibration apparatus and a display apparatus including the same, which can output a sound in a forward direction of a display panel, enhance the quality of a sound, and enhance a sound pressure level characteristic, can be provided.

According to an embodiment of the present disclosure, a vibration apparatus and a display apparatus including the same, which can output a sound in a forward direction of a display panel and can be slimmed, can be provided.

According to an embodiment of the present disclosure, a vibration apparatus and a display apparatus including the same can be configured with a multi-layered piezoelectric device while excluding an isolation process of isolating a sacrificial layer from a piezoelectric layer, and thus, the manufacturing cost for process optimization for simplifying a process can be reduced and productivity can be enhanced.

According to an embodiment of the present disclosure, a vibration apparatus and a display apparatus including the same can realize a uni-materialization effect of simplifying a configuration of a part through integration of a display panel and the vibration apparatus.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description are exemplary and explanatory and are intended to provide further explanation of the disclosure as claimed.

### BRIEF DESCRIPTION OF THE DRAWINGS

The accompanying drawings, which are included to provide a further understanding of the disclosure and incorporated in and constitute a part of this disclosure, illustrate embodiments of the disclosure and together with the description serve to explain principles of the disclosure.

FIG. 1 illustrates a vibration apparatus according to an embodiment of the present disclosure.

FIG. 2 is a cross-sectional view taken along line I-I′ in FIG. 1.

FIG. 3 is a cross-sectional view taken along line II-II′ in FIG. 1.

FIG. 4 is a cross-sectional view taken along line III-III′ in FIG. 1.

FIG. 5 illustrates a connection structure of a signal cable connected with the vibration apparatus according to the embodiment in FIG. 1.

FIG. 6 illustrates a vibration apparatus according to another embodiment of the present disclosure.

FIG. 7 is a cross-sectional view taken along line IV-IV′ in FIG. 6.

FIG. 8 is a cross-sectional view taken along line V-V′ in FIG. 6.

FIG. 9 illustrates a connection structure of a signal cable connected with the vibration apparatus according to the embodiment in FIG. 6.

FIG. 10 illustrates a vibration apparatus according to another embodiment of the present disclosure.

FIG. 11 is a cross-sectional view taken along line VI-VI′ in FIG. 10.

FIG. 12 is a cross-sectional view taken along line VII-VII′ in FIG. 10.

FIG. 13 is a cross-sectional view taken along line VIII-VIII′ in FIG. 10.

FIG. 14 is a cross-sectional view taken along line IX-IX′ in FIG. 10.

FIG. 15 illustrates a connection structure of a signal cable connected with the vibration apparatus according to the embodiment in FIG. 10.

FIGS. 16 and 17 illustrate unimorph driving of a vibration apparatus according to embodiments.

FIGS. 18 to 21 illustrate bimorph driving of a vibration apparatus according to embodiments.

FIG. 22 illustrates a display apparatus according to embodiments.

FIG. 23 is a cross-sectional view taken along line A-A′ in FIG. 22 according to one embodiment.

FIG. 24 illustrates one subpixel provided in a display part of FIG. 23.

FIG. 25 is another cross-sectional view taken along line A-A′ in FIG. 22 according to another embodiment.

FIG. 26 illustrates a rear surface of a display panel and a vibration generating apparatus, in a display apparatus according to embodiments.

FIG. 27 is a cross-sectional view taken along line B-B′ in FIG. 26.

FIG. 28 illustrates a display apparatus according to an alternative embodiment of the present disclosure.

FIG. 29 is a cross-sectional view taken along line C-C′ in FIG. 28.

FIG. 30 illustrates a display apparatus according to another embodiment.

FIG. 31 illustrates a display apparatus according to another embodiment.

FIG. 32 illustrates a display apparatus according to another embodiment.

FIG. 33 illustrates a display apparatus according to another embodiment.

FIG. 34 illustrates a display apparatus according to another embodiment.

FIG. 35 is an enlarged view of a region B1 in FIG. 34.

FIG. 36 illustrates a display apparatus according to another embodiment.

FIG. 37 illustrates a display apparatus according to another embodiment.

FIG. 38 illustrates a display apparatus according to another embodiment.

FIG. 39 is a cross-sectional view taken along line D-D′ in FIG. 38.

FIG. 40 illustrates a display apparatus according to another embodiment.

FIG. 41 is a cross-sectional view taken along line E-E′ in FIG. 40.

FIG. 42 illustrates a rear surface of a display panel and a vibration generating apparatus, in a display apparatus according to another embodiment.

FIG. 43 is a cross-sectional view taken along line F-F′ in FIG. 42.

FIG. 44 illustrates a rear surface of a display panel and a vibration generating apparatus, in a display apparatus according to another embodiment.

FIG. 45 is a cross-sectional view taken along line G-G′ in FIG. 44.

FIG. 46 illustrates a plate member according to embodiments.

FIG. 47 illustrates a vibration generating apparatus to which the plate member of FIG. 46.

Throughout the drawings and the detailed description, unless otherwise described, the same drawing reference numerals should be understood to refer to the same or the like elements, features, and structures. The sizes, lengths, and thicknesses of layers, regions and elements, and depiction of thereof can be exaggerated for clarity, illustration, and/or convenience.

### DETAILED DESCRIPTION OF THE EMBODIMENTS

Reference is now made in detail to embodiments of the present disclosure, examples of which can be illustrated in the accompanying drawings. In the following description, when a detailed description of well-known functions, structures or configurations can unnecessarily obscure aspects of the present disclosure, the detailed description thereof may have been omitted for brevity. Further, repetitive descriptions can be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure can be thorough and complete, to assist those skilled in the art to understand the inventive concepts without limiting the protected scope of the present disclosure.

Shapes (e.g., sizes, lengths, widths, heights, thicknesses, locations, radii, diameters, and areas), ratios, angles, numbers, and the like disclosed herein, including those illustrated in the drawings for describing embodiments of the present disclosure are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like with respect to one or more elements is used, one or more other elements can be added unless a term such as “only” or the like is used. The terms used in the present disclosure are merely used in order to describe example embodiments, and are not intended to limit the scope of the present disclosure. The terms of a singular form can include plural forms unless the context clearly indicates otherwise.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range can be caused by various factors (e.g., process factors, internal or external impact, noise, or the like). In interpreting a numerical value, the value is interpreted as including an error range unless explicitly stated otherwise.

In describing a positional relationship, when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more parts can be located between two other parts unless a more limiting term, such as “immediate(ly),” “direct(ly),” or “close(ly),” is used. For example, when a structure is described as being positioned “on,” “on a top of,” “upon,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as “after,” “subsequent,” “next,” “before,” “preceding,” “prior to,” or the like a case which is not consecutive or not sequential can be included and thus one or more other events may occur therebetween, unless a more limiting term, such as “just,” “immediate(ly),” or “direct(ly)” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It is understood that, although the term “first”, “second,” or the like can be used herein to describe various elements (e.g., layers, films, regions, components, sections, or the like), these elements should not be limited by these terms. These terms are used only to partition one element from another. For example, a first element could be a second element, and, similarly, a second element could be a first element, without departing from the scope of the present disclosure. Furthermore, the first element, the second element, and the like can be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like can be used. These terms are intended to identify the corresponding element(s) from the other element(s), and these are not used to define the essence, basis, order, sequence or number of the elements.

For the expression that an element (e.g., layer, film, region, component, section, or the like is “connected,” “coupled,” “attached,” “adhered,” or the like to another element, the element can be not only directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like “contacts,” “overlaps,” or the like with another element, the element can be not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and can be meant as lines or directions having wider directivities within the range within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C can refer to only A; only B; only C; any of A, B, and C (e.g., A, B, or C); or some combination of A, B, and C (e.g., A and B; A and C; or B and C); or all of A, B, and C. Furthermore, an expression “A/B” can be understood as A and/or B. For example, an expression “A/B” can refer to only A; only B; A or B; or A and B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two.

In one or more aspects, the phrases “each other” and “one another” can be used interchangeably simply for convenience unless stated otherwise. For example, an expression “different from each other” can be understood as being different from one another. In another example, an expression “different from one another” can be understood as being different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure can be partially or entirety coupled to or combined with each other, can be technically associated with each other and can be variously inter-operated, linked or driven together. The embodiments of the present disclosure can be implemented or carried out independently of each other, or can be implemented or carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, embodiments of the present disclosure are not limited to a scale, dimension, size, and thickness illustrated in the drawings.

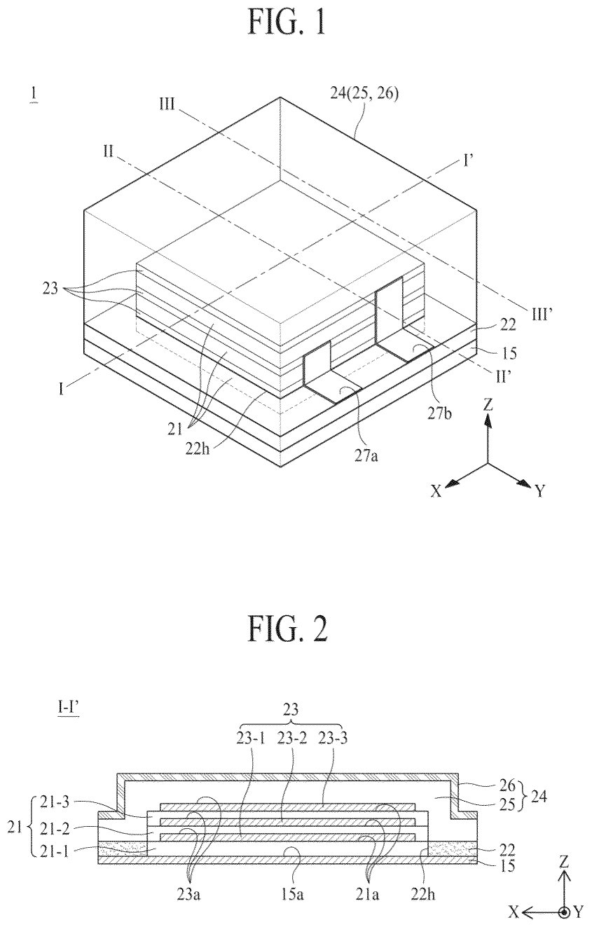

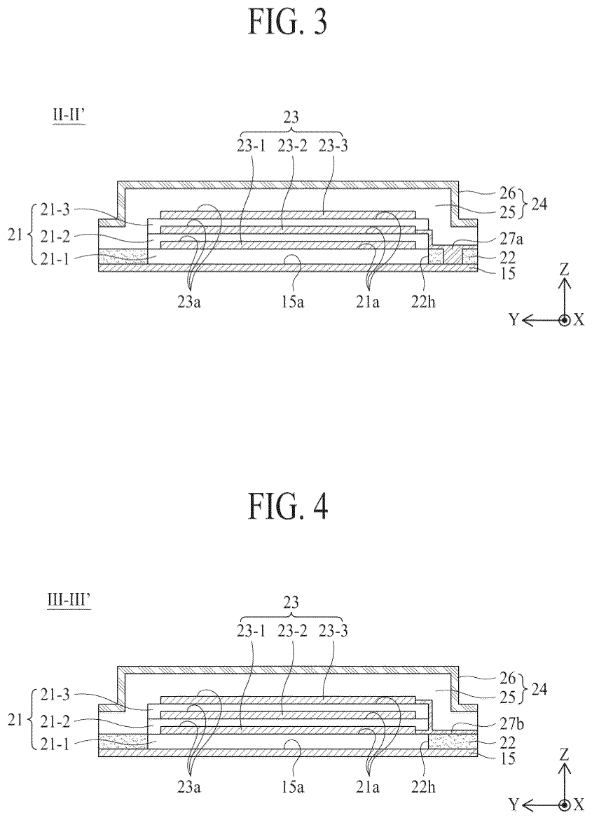

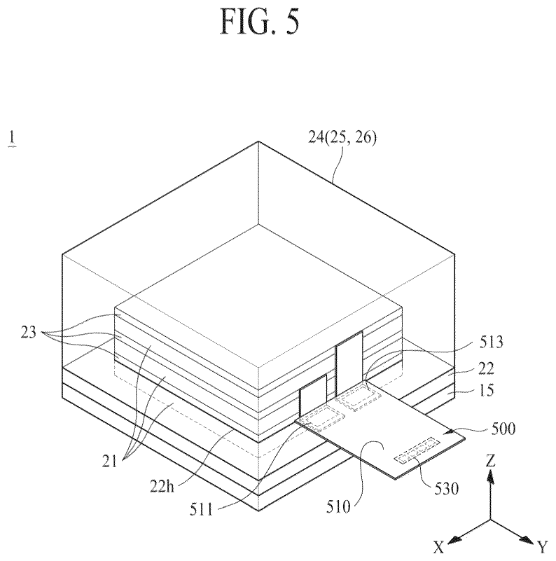

FIG. 1 illustrates a vibration apparatus according to an embodiment of the present disclosure. FIG. 2 is a cross-sectional view taken along line I-I′ in FIG. FIG. 3 is a cross-sectional view taken along line II-II′ in FIG. 1. FIG. 4 is a cross-sectional view taken along line III-III′ in FIG. 1. FIG. 5 illustrates a connection structure of a signal cable connected with a vibration apparatus according to the embodiment in FIG. 1.

Referring to FIGS. 1 to 4, a vibration apparatus 1 according to an embodiment can be configured to vibrate based on a driving signal (or a sound signal or a voice signal). For example, the vibration apparatus 1 can be a vibration generating apparatus, a vibration device, a vibration generating device, a vibration film, a vibration generating film, a vibrator, a vibration generator, an active vibrator, an active vibration generator, or an active vibration member, but embodiments of the present disclosure are not limited thereto.

The vibration apparatus 1 can include a conductive substrate 15 (or a plate member), a plurality of vibration layers 21, and a plurality of electrode layers 23.

The vibration apparatus 1 can be implemented or provided as one body with or a portion of a display apparatus including a plurality of pixels. For example, the display apparatus can include a display panel, including a plurality of pixels implementing a black and white, or color image, and a driver for driving the display panel. Each of the plurality of pixels can be a subpixel configuring one of a plurality of colors implementing a color image. An apparatus according to embodiments can include a notebook computer, a television (TV), a computer monitor, an equipment apparatus including a specific form of a vehicle or a vehicular or automotive apparatus, and a set device (or a set apparatus) or a set electronic apparatus such as a smartphone or an electronic pad, which are complete products (or final products) including a display panel such as a liquid crystal display panel or an organic light emitting display panel.

The conductive substrate 15 (or a plate member) can include a conductive material or a metal material. For example, the conductive substrate 15 (or the plate member) can include one or more materials of an alloy of iron (Fe) and nickel (Ni) (Fe—Ni alloy), stainless steel, aluminum (Al), magnesium (Mg), a Mg alloy, an alloy of Mg and lithium (Li) (Mg—Li alloy), and an Al alloy, but embodiments of the present disclosure are not limited thereto. For example, the conductive substrate 15 (or the plate member) can include an opaque metal material which are low in resistance and good in heat dissipation characteristic and can be implemented as a driving electrode of the vibration apparatus 1. For example, the conductive substrate 15 (or the plate member) can be a first driving electrode, a first electrode, a conductive plate, a metal electrode, an electrode member, an electrode plate, a lower electrode, a lower electrode plate, a common electrode member, or a common electrode, but embodiments of the present disclosure are not limited thereto.

According to embodiments, the conductive substrate 15 (or the plate member) can be implemented or provided as one body with or a portion of a display apparatus. For example, the conductive substrate 15 (or the plate member) can be implemented or provided as one body with or a portion of a display apparatus or a display panel. The conductive substrate 15 (or the plate member) can dissipate heat which occurs in the display apparatus or the display panel. The conductive substrate 15 (or the plate member) can protect the display apparatus or the display panel from an external impact and can prevent external water or moisture from penetrating into a light emitting device layer in the light emitting display apparatus. The conductive substrate 15 (or the plate member) can compensate for the stiffness of the display panel. For example, the conductive substrate 15 (or the plate member) can be a first driving electrode, a first electrode, a plate, a conductive plate, a conductive plate member, a heat dissipation member, a heat dissipation plate, a conductive plate, a heat dissipation substrate, an encapsulation substrate, an encapsulation plate, a stiff plate, a second substrate, a rear substrate, a rear member, a rear plate, an internal substrate, or an internal plate, but embodiments of the present disclosure are not limited thereto.

The vibration apparatus 1 according to embodiments can include a plurality of vibration layers 21 and a plurality of electrode layers 23. For example, the plurality of vibration layers 21 and the plurality of electrode layers 23 can be alternately stacked or formed. For example, the plurality of vibration layers 21 and the plurality of electrode layers 23 can be provided or disposed at one surface of the conductive substrate 15 (or the plate member). The plurality of vibration layers 21 and the plurality of electrode layers 23 can be provided at a first surface or a second surface, which is opposite to or different from the first surface, of the conductive substrate 15 (or the plate member). For example, the plurality of vibration layers 21 and the plurality of electrode layers 23 can be provided or disposed at a second surface 15a of the conductive substrate 15 (or the plate member).

The plurality of vibration layers 21 can include a first vibration layer 21-1, a second vibration layer 21-2, and a third vibration layer 21-3. For example, the plurality of vibration layers 21 can include two or more layers, but embodiments of the present disclosure are not limited thereto. Further, the plurality of electrode layers 23 can include a first electrode layer 23-1, a second electrode layer 23-2, and a third electrode layer 23-3. The plurality of vibration layers 21 can be provided to be equal to the number of electrode layers 23, and the number of the vibration layers 21 and the number of the electrode layers 23 can each be provided as two or more, but embodiments of the present disclosure are not limited thereto. Here, instance, the number of the vibration layers 21 can be equal to the number of the electrode layers 23. For instance, in FIG. 2, there can be three vibration layers 21 (21-1, 21-2, 21-3) and three electrode layers 23 (23-1, 23-2, 23-3).

The plurality of vibration layers 21 and the plurality of electrode layers 23 can be alternately stacked or formed. For example, the first vibration layer 21-1 of the plurality of vibration layers 21 can be disposed at the second surface 15a of the conductive substrate 15 (or the plate member), and the first electrode layer 23-1 of the plurality of electrode layers 23 can be disposed at a second surface 21a of the first vibration layer 21-1. For example, the first vibration layer 21-1 and the first electrode layer 23-1 can be configured to correspond (adjacent) to each other. Further, the first vibration layer 21-1 can be disposed between the first electrode layer 23-1 and the conductive substrate 15 (or the plate member). Further, the second vibration layer 21-2 of the plurality of vibration layers 21 can be disposed at a second surface 23a of the first electrode layer 23-1, and the second electrode layer 23-2 of the plurality of electrode layers 23 can be disposed at a second surface 21a of the second vibration layer 21-2. For example, the second vibration layer 21-2 and the second electrode layer 23-2 can be configured to correspond (adjacent) to each other. Further, the first electrode layer 23-1 can be disposed between the first vibration layer 21-1 and the second vibration layer 21-2. Further, the second vibration layer 21-2 can be disposed between the first electrode layer 23-1 and the second electrode layer 23-2. Further, the third vibration layer 21-3 of the plurality of vibration layers 21 can be disposed at a second surface 23a of the second electrode layer 23-2, and the third electrode layer 23-3 of the plurality of electrode layers 23 can be disposed at a second surface 21a of the third vibration layer 21-3. For example, the third vibration layer 21-3 and the third electrode layer 23-3 can be configured to correspond (adjacent) to each other. Further, the second electrode layer 23-2 can be disposed between the second vibration layer 21-2 and the third vibration layer 21-3. Further, the third vibration layer 21-3 can be disposed between the second electrode layer 23-2 and the third electrode layer 23-3. Accordingly, the plurality of vibration layers 21 and the plurality of electrode layers 23 can be alternately stacked or formed.

The plurality of vibration layers 21 can be configured to vibrate based on the driving signal (or the sound signal or the voice signal) applied to the conductive substrate 15 (or the plate member) and the plurality of electrode layers 23.

Each of the plurality of vibration layers 21 can include a piezoelectric material or an electroactive material having a piezoelectric effect. For example, the piezoelectric material can have a characteristic where pressure or twisting is applied to a crystalline structure by an external force, a potential difference occurs due to dielectric polarization caused by a relative position change of a positive (+) ion and a negative (−) ion, and a vibration is generated by an electric field based on a voltage applied thereto. Conversely, a piezoelectric material may change shape or size when a potential difference is applied to it. With repeated applications of alternating potential differences, the piezoelectric material can be made to vibrate at the same frequency at the applied alternating potential difference. For example, each of the plurality of vibration layers 21 can be a piezoelectric layer, a piezoelectric material layer, an electroactive layer, a piezoelectric material portion, an electroactive portion, a piezoelectric structure, piezoelectric ceramic, a vibration portion, a vibration generating portion, a displacement portion, a displacement generating portion, a sound generating portion, or an active vibration portion, but embodiments of the present disclosure are not limited thereto.

Each of the plurality of vibration layers 21 can include a ceramic-based material capable of implementing a relatively high vibration, or can include piezoelectric ceramic having a perovskite-based crystalline structure.

The piezoelectric ceramic can include single crystalline ceramic having a single crystalline structure, or can include polycrystalline ceramic or a ceramic material having a polycrystalline structure. A piezoelectric material of the single crystalline ceramic can include α-AlPO₄, α-SiO₂, LiNbO₃, Tb₂(MoO₄)₃, LizB₄O₇, or ZnO, but embodiments of the present disclosure are not limited thereto. The piezoelectric material of the single crystalline ceramic can include a lead zirconate titanate (PZT)-based material including lead (Pb), zirconium (Zr), and titanium (Ti) or can include a lead zirconate nickel niobate (PZNN)-based material including lead (Pb), zinc (Zn), nickel (Ni), and niobium (Nb), but embodiments of the present disclosure are not limited thereto. For example, each of the plurality of vibration layers 21 can include one or more of CaTiO₃, BaTiO₃, and SrTiO₃ without Pb, but embodiments of the present disclosure are not limited thereto.

Each of the plurality of electrode layers 23 can include a transparent conductive material, a semitransparent conductive material, or an opaque conductive material. For example, the transparent conductive material or the semitransparent conductive material of each of the plurality of electrode layers 23 can include indium tin oxide (ITO) or indium zinc oxide (IZO), but embodiments of the present disclosure are not limited thereto. The opaque conductive material of each of the plurality of electrode layers 23 can include gold (Au), silver (Ag), platinum (Pt), palladium (Pd), molybdenum (Mo), magnesium (Mg), carbon, or glass frit-containing Ag, or can include an alloy thereof, but embodiments of the present disclosure are not limited thereto. For example, the plurality of electrode layers 23 can include Ag having low resistivity, so as to enhance an electrical characteristic and/or a vibration characteristic of the plurality of vibration layers 21. For example, the carbon can be carbon black, ketjen black, carbon nano tube, or a carbon material including graphite, but embodiments of the present disclosure are not limited thereto.

In the plurality of electrode layers 23 including Ag including the glass frit, a content of glass frit can be 1 wt % to 12 wt %, but embodiments of the present disclosure are not limited thereto. The glass frit can include a PbO or Bi₂O₃-based material, but embodiments of the present disclosure are not limited thereto. Accordingly, a coupling force (or an adhesive force) between the plurality of electrode layers 23 and the plurality of vibration layers 21 can increase based on the glass frit. For example, a coupling force (or an adhesive force) between a first surface of each of the plurality of electrode layers 23 and a second surface 21a of a corresponding (or adjacent) vibration layer 21 of the plurality of vibration layers 21 can increase based on the glass frit.

The plurality of vibration layers 21 and the plurality of electrode layers 23 can be provided or disposed at the second surface 15a of the conductive substrate 15 (or the plate member). The first vibration layer 21-1 of the plurality of vibration layers 21 can be coupled or adhered to the second surface 15a of the conductive substrate 15 (or the plate member). Also, the plurality of electrode layers 23 and the plurality of vibration layers 21 can be alternately stacked or formed on the first vibration layer 21-1 coupled or connected to the conductive substrate 15 (or the plate member). The plurality of vibration layers 21 can include the first vibration layer 21-1, the second vibration layer 21-2, and the third vibration layer 21-3. Further, the plurality of electrode layers 23 can include the first electrode layer 23-1, the second electrode layer 23-2, and the third electrode layer 23-3. The plurality of vibration layers 21 and the plurality of electrode layers 23 can be configured to correspond (adjacent) to each other. For example, the first surface of the first vibration layer 21-1 can be electrically connected with or electrically contact the second surface 15a of the conductive substrate 15 (or the plate member).

Further, the second surface 21a of the first vibration layer 21-1 can be electrically connected with or electrically contact the first surface of the first electrode layer 23-1. Also, the first surface of the second vibration layer 21-2 can be electrically connected with or electrically contact the second surface 23a of the first electrode layer 23-1. Further, the second surface 21a of the second vibration layer 21-2 can be electrically connected with or electrically contact the first surface of the second electrode layer 23-2. Also, the first surface of the third vibration layer 21-3 can be electrically connected with or electrically contact the second surface 23a of the second electrode layer 23-2. Further, the second surface 21a of the third vibration layer 21-3 can be electrically connected with or electrically contact the first surface of the third electrode layer 23-3. For example, when the number of vibration layers 21 is four or more or the number of electrode layers 23 is four or more, four or more vibration layers 21 and electrode layers 23 can be alternately stacked or formed by repeating the above-described process.

Each of the plurality of vibration layers 21 and the plurality of electrode layers 23 can include a three or more-angled polygonal shape, a non-tetragonal shape, a circular shape, or an oval shape the shapes being the planform or plan view shapes of the electrode layers, viewed normal to the plane of the substrate), but embodiments of the present disclosure are not limited thereto. For example, the non-tetragonal shape can include one or more of one or more lines and one or more curves having a curvature, but embodiments of the present disclosure are not limited thereto.

The plurality of vibration layers 21 and the plurality of electrode layers 23 can be configured or implemented to be alternately stacked or formed on the second surface 15a of the conductive substrate 15 (or the plate member) by a tape casting scheme. For example, the plurality of vibration layers 21 and the plurality of electrode layers 23 can be alternately stacked or formed on the second surface 15a of the conductive substrate 15 (or the plate member) by a tape casting process (or scheme) using a piezoelectric material and a conductive material on the conductive substrate 15 (or the plate member).

According to embodiments, each of the plurality of vibration layers 21 and the plurality of electrode layers 23 can be formed (or manufactured) through a step of preparing a metal paste and a slurry including a piezoelectric powder (or a ceramic powder) and additives, a step of coating (or tape casting or forming) the slurry on the second surface of the conductive substrate 15 (or the plate member), a step of drying (or curing) the coated (or formed) slurry, a step of coating (or tape casting or forming) the metal paste on a second surface of the cured slurry, a step of drying (or curing) the coated (or formed) metal paste, a step of alternately and repeatedly coating (or forming) and drying (or curing) the slurry and the metal paste, and a step of molding (or sintering) the alternately stacked (or formed) slurry and metal paste at least once. For example, the additives added to the slurry can include a material or substance of the piezoelectric material composition field, but embodiments of the present disclosure are not limited thereto. Also, the additives of the slurry can include one or more of a dispersant, a solvent, a binder, and a plasticizer, but embodiments of the present disclosure are not limited thereto. Further, the additives added to the metal paste can include a material or substance of the electrode material composition field, but embodiments of the present disclosure are not limited thereto. For example, the metal paste can be Ag, Au, Cu, and Ag/Cu, but embodiments of the present disclosure are not limited thereto. For example, the additives of the metal paste can be sintered simultaneously with piezoelectric ceramic and can include a binder for reinforcing an adhesive force with ceramic, but embodiments of the present disclosure are not limited thereto.

According to embodiments, the binder can include a high temperature binder. For example, the binder can include a glass frit. The binder can remain in a particle state on the second surface of the conductive substrate 15 (or the plate member) and/or the second surface of the cured metal paste in drying the slurry. The binder can be changed to a liquid state when a piezoelectric particle (or a ceramic particle) grows at a molding (or sintering) temperature of the slurry, can move to an interface between the conductive substrate 15 (or the plate member) and/or the cured metal paste and a piezoelectric, and can be coagulated as a molding temperature is reduced, thereby increasing a coupling force (or an adhesive force) between the conductive substrate 15 (or the plate member) and/or the cured metal paste and the piezoelectric. For example, a content of glass frit can be 1 wt % to 12 wt %, but embodiments of the present disclosure are not limited thereto. The glass frit can include a PbO or Bi₂O₃-based material, but embodiments of the present disclosure are not limited thereto. For example, the metal paste can be a middle electrode or an upper electrode of the piezoelectric, but embodiments of the present disclosure are not limited thereto.

According to another embodiment of the present disclosure, the slurry can further include a sintering agent. For example, the sintering agent can include MnO₂, Fe₂O₃, CuO, and ZnO, but embodiments of the present disclosure are not limited thereto. As another example of the present disclosure, the sintering temperature can be reduced through a sol-gel scheme, and thus, ceramic and an electrode layer can be sintered simultaneously. The sol-gel scheme can be a scheme which densely forms a microstructure of a sintered body (for example, ceramic).

The plurality of vibration layers 21 and the plurality of electrode layers 23 according to embodiments can be configured by the tape casting scheme, and thus, may not be limited to a specific shape and can include a three or more-angled polygonal shape, a non-tetragonal shape, a circular shape, or an oval shape, but embodiments of the present disclosure are not limited thereto.

Each of the plurality of vibration layers 21 can be polarized (or poling) by a certain voltage applied from the outside to the conductive substrate 15 (or the plate member) and the first driving electrode and the second driving electrode of the plurality of electrode layers 23 in a certain temperature atmosphere or a temperature atmosphere which is changed from a high temperature to a room temperature, but embodiments of the present disclosure are not limited thereto. For example, each of the plurality of vibration layers 21 can alternately and repeatedly contract and/or expand based on an inverse piezoelectric effect based on a first vibration driving signal and a second vibration driving signal applied from the outside to the conductive substrate 15 (or the plate member) and the first driving electrode and the second driving electrode of the plurality of electrode layers 23, and thus, can vibrate. For example, the plurality of vibration layers 21 can vibrate based on a vertical-direction vibration and/or a horizontal-direction (or a direction parallel to the plane of the vibration layers) vibration according to the first vibration driving signal and the second vibration driving signal applied to the conductive substrate 15 (or the plate member) and the first driving electrode and the second driving electrode of the plurality of electrode layers 23. Accordingly, a displacement of the vibration apparatus 1 can be increased or enhanced based on the contraction and/or expansion of the plurality of vibration layers 21 in a horizontal direction (or a direction parallel to the plane of vibration layers).

The vibration apparatus 1 according to embodiments can further include an insulation layer 22.

The insulation layer 22 can be provided on the conductive substrate 15 (or the plate member). For example, the insulation layer 22 can be provided on the second surface 15a of the conductive substrate 15 (or the plate member). The insulation layer 22 can be disposed on the second surface 15a of the conductive substrate 15 (or the plate member) at a periphery of each of the plurality of vibration layers 21 and the plurality of electrode layers 23. For example, the insulation layer 22 can include an opening region 22h which exposes a portion of the second surface 15a of the conductive substrate 15 (or the plate member). For example, the plurality of vibration layers 21 and the plurality of electrode layers 23 can be provided to overlap the opening region 22h of the insulation layer 22.

The insulation layer 22 can be disposed at the second surface 15a of the conductive substrate 15 (or the plate member) to surround a periphery of the first vibration layer 21-1 corresponding (or adjacent) to the conductive substrate 15 (or the plate member) among the plurality of vibration layers 21. For example, the insulation layer 22 can be disposed at a portion or all of the other portion, except a disposition region of the first vibration layer 21-1, of the second surface 15a of the conductive substrate 15 (or the plate member).

The insulation layer 22 can be formed to have a thickness which is the same as or different from that of the first vibration layer 21-1. For example, the insulation layer 22 can be formed to have the same thickness as that of the first vibration layer 21-1. The insulation layer 22 can cover the second surface 15a of the conductive substrate 15 (or the plate member), and thus, can prevent the occurrence of an electrical connection (or short circuit) with the plurality of electrode layers 23 on the conductive substrate 15 (or the plate member). The insulation layer 22 can include an organic material or an inorganic material.

Each of the plurality of electrode layers 23 can be provided to respectively correspond to the plurality of vibration layers 21. For example, the plurality of electrode layers 23 can be provided to be equal to the number of vibration layers 21. Each of the plurality of electrode layers 23 can be provided at or coupled (or connected) to the second surface 21a of a corresponding (or adjacent) vibration layer 21. For example, the plurality of electrode layers 23 can be provided to respectively correspond to the plurality of vibration layers 21 in a one-to-one relationship. At least one of the plurality of electrode layers 23 can be between adjacent vibration layers 21. For example, the other electrode layers 23-1 and 23-2, except an electrode layer of an uppermost layer (i.e. farthest from the conductive substrate 15), of the plurality of electrode layers 23 can be disposed between adjacent vibration layers 21. Therefore, each of the plurality of vibration layers 21 can vibrate based on a vibration driving signal (or a voltage or a signal) applied to the conductive substrate 15 (or the plate member) and the plurality of electrode layers 23.

For example, each of the plurality of vibration layers 21 can vibrate based on a first vibration driving signal (or a first voltage or a first signal) applied to the conductive substrate 15 (or the plate member) and some of the plurality of electrode layers 23 and a second vibration driving signal (or a second voltage or a second signal) applied to the other some of the plurality of electrode layers 23. The plurality of electrode layers 23 can have the same size (e.g. area) as that of the plurality of vibration layers 21, or can have a size (e.g. area) which is less than that of the plurality of vibration layers 21. Each of the plurality of electrode layers 23 can be disposed at a center portion of a corresponding (or adjacent) vibration layer 21. For example, the plurality of electrode layers 23 can have the same shape (in a plan view normal to the plane of the substrate) as that of the plurality of vibration layers 21, but embodiments of the present disclosure are not limited thereto. For example, each of the plurality of electrode layers 23 can be an electrode layer, an upper electrode, an upper electrode layer, a middle electrode, a middle electrode layer, a first driving electrode, a second driving electrode, an individual electrode, an individual electrode layer, a patterned electrode, or a patterned electrode layer, but embodiments of the present disclosure are not limited thereto.

According to embodiments, to prevent an electrical connection (or short circuit) between the conductive substrate 15 (or the plate member) and the plurality of electrode layers 23 or the plurality of electrode layers 23, each of the plurality of electrode layers 23 can be formed at the other portion, except a periphery portion of the second surface 21a, of a corresponding (or adjacent) vibration layer 21 of the plurality of vibration layers 21. For example, each of the plurality of electrode layers 23 can be formed at entire of the other second surface, except a periphery portion, of a corresponding (or adjacent) vibration layer 21 of the plurality of vibration layers 21. For example, a distance between a lateral surface (or an outer wall) of each of the plurality of electrode layers 23 and a lateral surface (or an outer wall) of each of the plurality of vibration layers 21 can be at least 0.5 mm or more. For example, the distance between the lateral surface of each of the plurality of electrode layers 23 and the lateral surface of each of the plurality of vibration layers 21 can be at least 1 mm or more, but embodiments of the present disclosure are not limited thereto.

According to embodiments, the conductive substrate 15 (or the plate member) and the plurality of electrode layers 23 can be configured to receive a signal having a polarity which differs from that of a corresponding (or adjacent) electrode layer. For example, the conductive substrate 15 (or the plate member) and the first electrode layer 23-1 can be supplied with signals having different polarities. Alternatively, or in addition, two adjacent electrode layers of the plurality of electrode layers 23 can be supplied with signals having different polarities. For example, the first electrode layer 23-1 and the second electrode layer 23-2 can be supplied with signals having different polarities. Alternatively, or in addition, the second electrode layer 23-2 and the third electrode layer 23-3 can be supplied with signals having different polarities.

It will be understood that a difference in voltage polarity between the conductive substrate and an adjacent electrode layer (or between adjacent electrode layers) is not essential to achieving vibration. As long as a voltage difference is applied between the conductive substrate and an adjacent electrode layer (or between adjacent electrode layers), the vibration layer can be made to change size or shape. Repeated application of a voltage difference or a varying voltage will achieve vibration of the vibration layer. The voltage may be varied so that the potential difference varies, for example between a positive and negative value. Therefore, it will be understood that the conductive substrate may be configured to be supplied with a different voltage (or voltage signal) to an electrode layer adjacent to the conductive substrate among the one or more electrode layers such that a potential difference is applied across a vibration layer of the one or more vibration layers sandwiched between the conductive substrate and the electrode layer adjacent to the conductive substrate. Alternatively, or in addition, two adjacent electrode layers of the plurality of electrode layers may be configured to be supplied with a different voltage (or voltage signal) to each other such that a potential difference is applied across a vibration layer sandwiched between the two adjacent electrode layers.

Embodiments include the vibration apparatuses described herein connected to a driver or other signal generating apparatus which is configured to supply the voltages or voltage signals (e.g. having the differing values or polarities) to the conductive substrate and electrode layers as described herein. Therefore, adjacent electrodes may be connected to different signal lines to allow the application of the different signals/different polarities described. For example, the conductive substrate may be connected to a first signal line and an electrode layer adjacent to the conductive substrate among the plurality of electrode layers may be connected to a second signal line different from the first signal line. Alternatively, or in addition, a first electrode layer of the plurality of electrode layers is connected to the first signal line and a second electrode layer of the plurality of electrode layers is connected to the second signal line, wherein the first electrode layer is adjacent to the second electrode layer.

The signals lines may be supplied with different voltages or voltage signals (for example by the driver or other signal generating component) such that the conductive substrate and electrode layers are supplied with those voltages or voltage signals. For example, the first signal line and second signal line may be connected to a driver arranged to apply a first voltage signal to the first signal line and a second voltage signal to the second signal line, wherein the second voltage is different from the first voltage. A difference between the first voltage signal and the second voltage signal may alternate between a positive and a negative voltage. Alternatively, or in addition, a magnitude of a difference between the first voltage signal and the second voltage signal may vary with time.

In embodiments, there is provided a vibration generating apparatus with at least one vibration layer comprising: a first piezoelectric material layer, a second piezoelectric material layer and a third piezoelectric material layer. The vibration generating apparatus includes at least one electrode layer comprising a first electrode layer, a second electrode layer and a third electrode layer. The vibration layers and the electrode layers are alternately arranged in a stack on the surface of the conductive substrate. The conductive substrate and the second electrode layer are configured to be connected to a first voltage supply line, and the first electrode layer and the third electrode layer are configured to be connected to a second voltage supply line different from the first voltage supply line such that the first, second and third piezoelectric material layers vibrate in a thickness direction of the conductive substrate in response to application of a first and second voltage signal, respectively, to the first and second voltage supply lines.

The conductive substrate 15 (or the plate member) and the plurality of electrode layers 23 can be configured so that electrode layers supplied with the same polarity (or voltage) configure one group and electrode layers of the same group are electrically connected with one another. For example, the conductive substrate 15 (or the plate member) and the second electrode layer 23-2 can be configured as electrode layers of a first group and can be electrically connected with each other. The electrode layer of the first group can be a first driving electrode. Further, the first electrode layer 23-1 and the third electrode layer 23-3 can be configured as electrode layers of a second group and can be electrically connected with each other. The electrode layer of the second group can be a second driving electrode.

Referring to FIGS. 1, 3, and 4, the vibration apparatus 1 according to the embodiment can further include at least one contact patterns 27a and 27b. For example, the at least one contact pattern 27a and 27b can include a first contact pattern 27a and a second contact pattern 27b.

The first contact pattern 27a can be connected with or coupled to the conductive substrate 15 (or the plate member) and one or more of the plurality of electrode layers 23. For example, the first contact pattern 27a can be connected or coupled to the conductive substrate 15 (or the plate member) and the second electrode layer 23-2 of the plurality of electrode layers 23. The first contact pattern 27a can be configured so that the conductive substrate 15 (or the plate member) and the second electrode layer 23-2 are electrically connected with (or contact) each other. Also, the first contact pattern 27a can be supplied with the first driving signal from the outside and can apply or transfer the first driving signal to the conductive substrate 15 (or the plate member) and the second electrode layer 23-2. The first contact pattern 27a can extend from the plate member 15 and the plurality of electrode layers 23 and can be exposed at an outside (e.g. outer part of the vibration apparatus 2, such as the outer edge of the stack). For example, the first contact pattern 27a connected with the conductive substrate 15 (or the plate member) can extend or protrude from a portion of the conductive substrate 15 (or the plate member). For example, the first contact pattern 27a connected with the conductive substrate 15 (or the plate member) can be exposed at the outside through a removed portion of a portion of the insulation layer 22. Further, the first contact pattern 27a connected with the second electrode layer 23-2 of the plurality of electrode layers 23 can extend or protrude from a portion of the second electrode layer 23-2. For example, the first contact pattern 27a connected with the second electrode layer 23-2 of the plurality of electrode layers 23 can extend from a portion of the second electrode layer 23-2 to the second vibration layer 21-2 and can be exposed at the outside. One end (or one side or one portion) of the first contact pattern 27a can be connected with each of the conductive substrate 15 (or the plate member) and the second electrode layer 23-2, and the other end (or the other side or the other portion) of the first contact pattern 27a can extend to the insulation layer 22 along a lateral surface of each of the plurality of vibration layers 23.

The second contact pattern 27b can be connected with or coupled to the other some of the plurality of electrode layers 23 of the vibration apparatus 1. For example, the second contact pattern 27b can be connected or coupled to the first electrode layer 23-1 and the third electrode layer 23-3 of the plurality of electrode layers 23. The second contact pattern 27b can be configured so that the first electrode layer 23-1 and the third electrode layer 23-3 are electrically connected with (or contact) each other. Further, the second contact pattern 27b can be supplied with the second driving signal from the outside and can apply or transfer the second driving signal to the first electrode layer 23-1 and the third electrode layer 23-3. The second contact pattern 27b can extend from the first electrode layer 23-1 and the third electrode layer 23-3 and can be exposed at the outside. For example, the second contact pattern 27b connected with the first electrode layer 23-1 can extend or protrude from a portion of the first electrode layer 23-1. For example, the second contact pattern 27b connected with the first electrode layer 23-1 can extend from a portion of the first electrode layer 23-1 to the first vibration layer 21-1 and can be exposed at the outside. Further, the second contact pattern 27b connected with the third electrode layer 23-3 can extend or protrude from a portion of the third electrode layer 23-3. For example, the second contact pattern 27b connected with the third electrode layer 23-3 can extend from a portion of the third electrode layer 23-3 to the third vibration layer 21-3 and can be exposed at the outside. One end (or one side or one portion) of the second contact pattern 27b can be connected with each of the first electrode layer 23-1 and the third electrode layer 23-3, and the other end (or the other side or the other portion) of the second contact pattern 27b can extend to the insulation layer 22 along the lateral surface of each of the plurality of vibration layers 23.

The vibration apparatus 1 according to embodiments can further include a protection layer 24.

The protection layer 24 can be configured to protect the vibration apparatus 1. The protection layer 24 can be configured to protect the insulation layer 22, the plurality of vibration layers 21, and the plurality of electrode layers 23. For example, the protection layer 24 can be configured to protect the third electrode layer 23-3 of an uppermost layer of the plurality of electrode layers 23. The protection layer 24 can be configured to protect the lateral surfaces of the plurality of vibration layers 21 and the plurality of electrode layers 23, which are stacked or formed under the third electrode layer 23-3. For example, the protection layer 24 can be configured to surround or cover the plurality of vibration layers 21 and the plurality of electrode layers 23. For example, the protection layer 24 can include an inorganic material or an organic material, but embodiments of the present disclosure are not limited thereto.

According to embodiments, the protection layer 24 can include a cover member 26 and an adhesive layer 25.

The cover member 26 can be provided to protect the vibration apparatus 1. The cover member 26 can be provided to protect the insulation layer 22, the plurality of vibration layers 21, and the plurality of electrode layers 23. For example, the cover member 26 can be configured to surround or cover the plurality of vibration layers 21 and the plurality of electrode layers 23. The cover member 26 may also surround or cover the first and second contact patterns 27a and 27b, thereby protecting them. For example, the cover member 26 can be a cover film, a cover layer, a protection member, or a protection layer, but embodiments of the present disclosure are not limited thereto. For example, the cover member 26 can be a polyimide (PI) film, a polyethylene terephthalate (PET) film, or a polyethylene naphthalate (PEN), but embodiments of the present disclosure are not limited thereto.

The cover member 26 can be connected with or coupled to a second surface 23a of the third electrode layer 23-3 of an uppermost layer of the plurality of electrode layers 23 by an adhesive layer 25. For example, the cover member 26 can be connected with or coupled to the third electrode layer 23-3 by a film laminating process by the adhesive layer 25. For example, the cover member 26 can be connected with or coupled to the insulation layer 22, the third electrode layer 23-3, and the lateral surfaces of the plurality of vibration layers 21 and the plurality of electrode layers 23, which are stacked or formed under the third electrode layer 23-3.

The adhesive layer 25 can be disposed between the third electrode layer 23-3 and the cover member 26. For example, the adhesive layer 25 can be provided or disposed between the insulation layer 22 and the cover member 26 to cover or surround the plurality of vibration layers 21 and the plurality of electrode layers 23. For example, the adhesive layer 25 can be provided or filled between the insulation layer 22 and the cover member 26 to fully surround the second surface 23a of the third electrode layer 23-3 and the lateral surfaces of the plurality of vibration layers 21 and the plurality of electrode layers 23, which are stacked or formed under the third electrode layer 23-3. For example, the plurality of vibration layers 21 and the plurality of electrode layers 23 can be buried or embedded between the conductive substrate 15 (or the plate member), and the insulation layer 22 and the adhesive layer 25.

The adhesive layer 25 can include an electrical insulating material which has adhesive properties and is capable of compression and decompression. For example, the adhesive layer 25 can include epoxy-based resin, acrylic-based resin, silicone-based resin, or urethane-based resin, but embodiments of the present disclosure are not limited thereto.

The vibration apparatus 1 according to embodiments can replace a sacrificial layer, used for molding of the plurality of vibration layers 21, with the conductive substrate 15 (or the plate member) and can use the conductive substrate 15 (or the plate member) as a driving electrode of the molded first vibration layer 21-1, and thus, an isolation process of a vibration layer can be excluded, thereby reducing the manufacturing cost for process optimization for simplifying a process and enhancing productivity. Further, the vibration apparatus 1 according to embodiments can be implemented or provided as one body with or a portion of a display apparatus, and in this case, the conductive substrate 15 can be used as the plate member of the display panel and can be used as a driving electrode of the vibration apparatus 1, and thus, one electrode can be omitted and a thickness can be slimmed by a thickness of one omitted electrode, thereby decreasing a thickness of a display apparatus.

Referring to FIG. 5, the vibration apparatus 1 according to embodiments can further include a signal cable 500 (which can be more generally described as a signal line, e.g. any conductor capable of carrying a signal).

The signal cable 500 can be electrically connected with the vibration apparatus 1. For example, the signal cable 500 can be electrically connected with the plurality of electrode layers 23 and the conductive substrate 15 (or the plate member) of the vibration apparatus 1. For example, the signal cable 500 can be electrically connected with the first contact pattern 27a and/or the second contact pattern 27b of the vibration apparatus 1.

The signal cable 500 can be provided as one body with the vibration apparatus 1. For example, a portion of the signal cable 500 can be inserted (or accommodated) into the adhesive layer 25 between the conductive substrate 15 (or the plate member) and the cover member 26, and thus, can be provided as one body with the vibration apparatus 1. Accordingly, the vibration apparatus 1 can vibrate based on signals applied from the conductive substrate 15 (or the plate member) and the signal cable 500.

The signal cable 500 can include a line part 510, a first contact line 511 (or a first contact part), a second contact line 513 (or a second contact part), and a terminal part 530.

A portion or one periphery portion of the line part 510 can be inserted (or accommodated) 1 between the conductive substrate 15 and the protection layer 24, or can be provided as one body with the vibration apparatus 1. For example, the portion or one periphery portion of the line part 510 can be covered by the cover member 26 of the vibration apparatus 1. For example, the portion or one periphery portion of the line part 510 can be inserted (or accommodated) into the adhesive layer 25 of the vibration apparatus 1, and thus, can be fixed to the vibration apparatus 1 or can be provided as one body with the vibration apparatus 1. Accordingly, a connection defect between the vibration apparatus 1 and the signal cable 500 caused by the movement or bending of the signal cable 500 which is caused by a manufacturing process attaching the line part 510 to the first and second contact patterns 27a and 27b can be minimized.

The line part 510 can include a base film, a line layer including first and second signal lines formed in the base film, and an insulation layer covering the line layer.

The first contact line 511 (or the first contact part) can be provided to be electrically connected with (or contact) the first contact pattern 27a (or the first driving electrode) of the vibration apparatus 1. For example, the first contact line 511 can be a portion of the first signal line exposed at one periphery portion of the line part 510, or can be a first finger line (or a first protrusion signal line or the first signal line) which extends (or protrudes) to have a certain length from the first signal line of the line part 510. The first contact line 511 can be electrically connected with (or contact) or electrically and directly connected with (or contact) the first contact pattern 27a of the vibration apparatus 1. Alternatively, the first contact line 511 can be electrically connected with (or contact) the first contact pattern 27a by a conductive double-sided tape or an anisotropic conductive film. The first contact line 511 can be covered by the cover member 26 of the vibration apparatus 1, and thus, can be fixed to the vibration apparatus 1 or can be provided as one body with the vibration apparatus 1. Accordingly, a connection defect between the vibration apparatus 1 and the signal cable 500 caused by the movement or bending of the signal cable 500 can be minimized.

The second contact line 513 (or the second contact part) can be provided to be electrically connected with (or contact) the second contact pattern 27b (or the second driving electrode) of the vibration apparatus 1. For example, the second contact line 513 can be a portion of the second signal line exposed at one periphery portion of the line part 510, or can be a second finger line (or a second protrusion signal line or the second signal line) which extends (or protrudes) to have a certain length from the second signal line of the line part 510. The second contact line 513 can be electrically connected with (or contact) or electrically and directly connected with (or contact) the second contact pattern 27b of the vibration apparatus 1. Alternatively, the second contact line 513 can be electrically connected with (or contact) the second contact pattern 27b by a conductive double-sided tape or an anisotropic conductive film. The second contact line 513 can be covered by the cover member 26 of the vibration apparatus 1, and thus, can be fixed to the vibration apparatus 1 or can be provided as one body with the vibration apparatus 1. Accordingly, a connection defect between the vibration apparatus 1 and the signal cable 500 caused by the movement or bending of the signal cable 500 can be minimized.

The terminal part 530 can be provided at the other periphery portion of the line part 510. The terminal part 530 can be provided to expose a portion of each of the first and second signal lines disposed at the other periphery portion of the line part 510. For example, the terminal part 530 can be electrically connected with a vibration driving signal (or a sound processing circuit), or can include a connector which is electrically connected with the vibration driving signal (or the sound processing circuit).

The signal cable 500 can be electrically coupled (or connected) to the first contact pattern 27a and the second contact pattern 27b, and thus, can apply or transfer the first and second vibration driving signals, supplied from the vibration driving signal (or the sound processing circuit), to the first contact pattern 27a and the second contact pattern 27b of the vibration apparatus 1 through the terminal part 530. For example, the first vibration driving signal can be applied or transferred to the conductive substrate 15 (or the plate member) and the second electrode layer 23-2 of the plurality of electrode layers 23 through or by the first contact pattern 27a. Further, the second vibration driving signal can be applied or transferred to the first electrode layer 23-1 and the third electrode layer 23-3 of the plurality of electrode layers 23 through or by the second contact pattern 27b.

The vibration apparatus 1 can vibrate based on the first and second vibration driving signals (or sound signals) applied to, through the signal cable 500, the conductive substrate 15 (or the plate member) and the second electrode layer 23-2 connected with the first contact pattern 27a and the first electrode layer 23-1 and the third electrode layer 23-3 connected with the second contact pattern 27b.

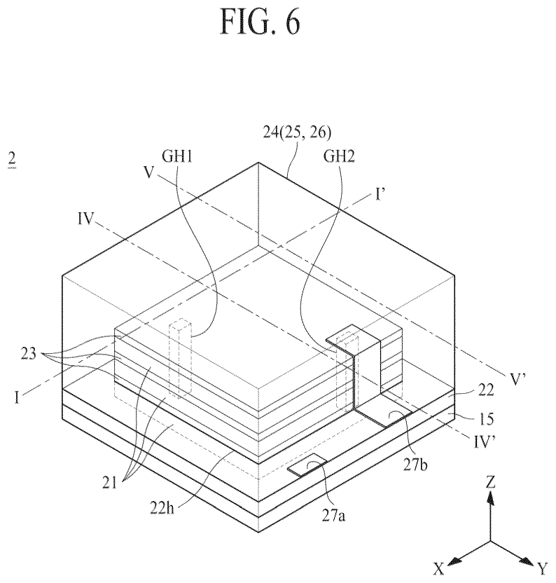

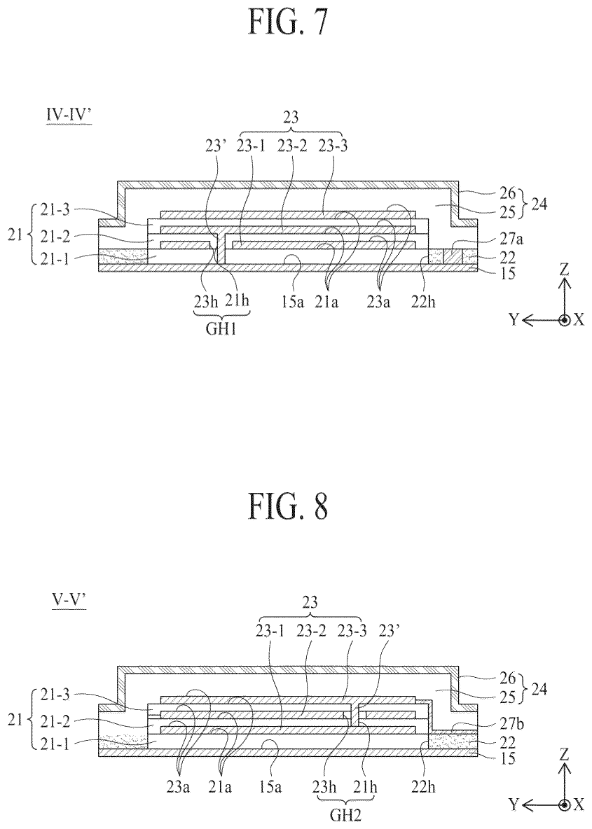

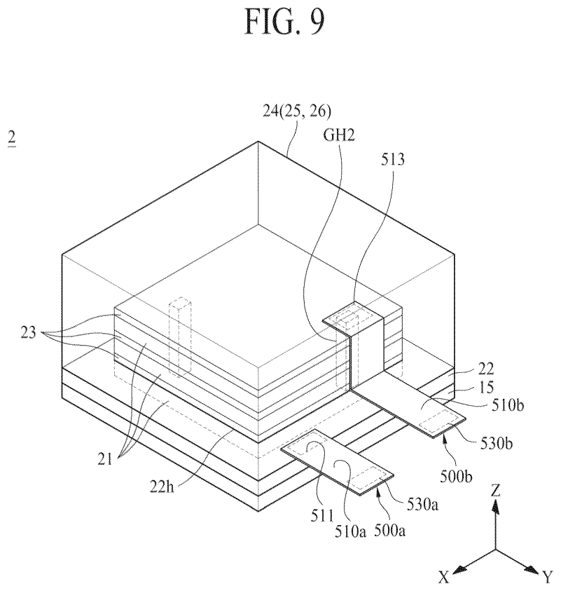

FIG. 6 illustrates a vibration apparatus according to another embodiment of the present disclosure. FIG. 7 is a cross-sectional view taken along line IV-IV′ in FIG. 6. FIG. 8 is a cross-sectional view taken along line V-V′ in FIG. 6. FIG. 9 illustrates a connection structure of a signal cable connected with a vibration apparatus in FIG. 6. FIGS. 6 to 9 illustrate an embodiment where a through hole is added to the vibration apparatus 1 described above with reference to FIGS. 1 to 5. In the following description, therefore, a through hole and relevant elements will be described in detail, the other elements are referred to by the same reference numerals as FIGS. 1 to 5, and repeated descriptions thereof may be omitted or will be briefly given. Further, the cross-sectional view taken along line I-I′ in FIG. 6 can be substantially the same as FIG. 2, and the illustration is omitted.

Referring to FIGS. 6 to 8, a vibration apparatus 2 according to another embodiment of the present disclosure can further include at least one through holes GH1 and GH2 which are in a plurality of vibration layers 21 and a plurality of electrode layers 23.

The at least one through holes GH1 and GH2 can be provided to electrically connect electrode layers, supplied with signals having a same polarity, with each other. For example, the at least one through holes GH1 and GH2 can include a through hole GH1 of a first group configured to electrically connect a conductive substrate 15 (or a plate member) with a second electrode layer 23-2 and a through hole GH2 of a second group configured to electrically connect a first electrode layer 23-1 with a third electrode layer 23-3. For example, the through hole GH1 of the first group and the through hole GH2 of the second group can be configured not to overlap each other. For example, the conductive substrate 15 (or the plate member) and the second electrode layer 23-2 connected with each other through the through hole GH1 of the first group can be a first driving electrode to which a first vibration driving signal is applied. Further, the first electrode layer 23-1 and the third electrode layer 23-3 connected with each other through the through hole GH2 of the second group can be a second driving electrode to which a second vibration driving signal is applied.

The through hole GH1 of the first group can include a first hole 21h passing through a first vibration layer 21-1 and a second vibration layer 21-2 between the conductive substrate 15 (or the plate member) and the second electrode layer 23-2 and a second hole 23h passing through the first electrode layer 23-1 between the conductive substrate 15 (or the plate member) and the second electrode layer 23-2. For example, the first hole 21h can have a size which is less than that of the second hole 23h. For example, a connection pattern 23′ between the conductive substrate 15 (or the plate member) and the second electrode layer 23-2 can be electrically connected with each of the conductive substrate 15 (or the plate member) and the second electrode layer 23-2 through the first hole 21h. Further, the connection pattern 23′ can be spaced apart from the second hole 23h and can be electrically disconnected or separated from the first electrode layer 23-1. Because the conductive substrate 15 (or the plate member) and the second electrode layer 23-2 are electrically connected with each other through or by the through hole GH1 of the first group, a first contact pattern 27a can be configured to be connected with the conductive substrate 15 (or the plate member).

The through hole GH2 of the second group can include a first hole 21h passing through the second vibration layer 21-2 and a third vibration layer 21-3 between the first electrode layer 23-1 and the third electrode layer 23-3 and a second hole 23h passing through the second electrode layer 23-2 between the first electrode layer 23-1 and the third electrode layer 23-3. For example, the first hole 21h can have a size which is less than that of the second hole 23h. For example, a connection pattern 23′ between the first electrode layer 23-1 and the third electrode layer 23-3 can be electrically connected with each of the first electrode layer 23-1 and the third electrode layer 23-3 through the first hole 21h. Further, the connection pattern 23′ can be spaced apart from the second hole 23h and can be electrically disconnected or separated from the second electrode layer 23-2. Because the first electrode layer 23-1 and the third electrode layer 23-3 are electrically connected with each other through or by the through hole GH2 of the second group, a first contact pattern 27a can be configured to be connected with the third electrode layer 23-3 of an uppermost layer of the plurality of electrode layers 23.

Referring to FIG. 9, the vibration apparatus 2 according to another embodiment can further include a signal cable 500. The signal cable 500 can include a first signal cable 500a and a second signal cable 500b. The first signal cable 500a can be configured to be electrically connected with the first contact pattern 27a. Further, the second signal cable 500b can be configured to be electrically connected with the second contact pattern 27b.

In the vibration apparatus 2 according to another embodiment, the first contact pattern 27a and the second contact pattern 27b can be omitted, and the first signal cable 500a can be electrically connected with (or contact) or electrically and directly connected with (or contact) the conductive substrate 15 (or the plate member). Further, the second signal cable 500b can be electrically connected with (or contact) or electrically and directly connected with (or contact) the third electrode layer 23-3. For example, a first contact line 511 (or a first contact part) of the first signal cable 500a can be provided to be directly connected with or coupled to the conductive substrate 15 (or the plate member) of the vibration apparatus 1. Further, a second contact line 513 (or a second contact part) of the second signal cable 500b can be provided to be directly connected with or coupled to the third electrode layer 23-3 of the vibration apparatus 1.

The vibration apparatus 2 according to another embodiment can vibrate based on a first vibration driving signal directly applied to the conductive substrate 15 (or the plate member) through or by the first signal cable 500a and a second vibration driving signal directly applied to the third electrode layer 23-3 through or by the second signal cable 500b.

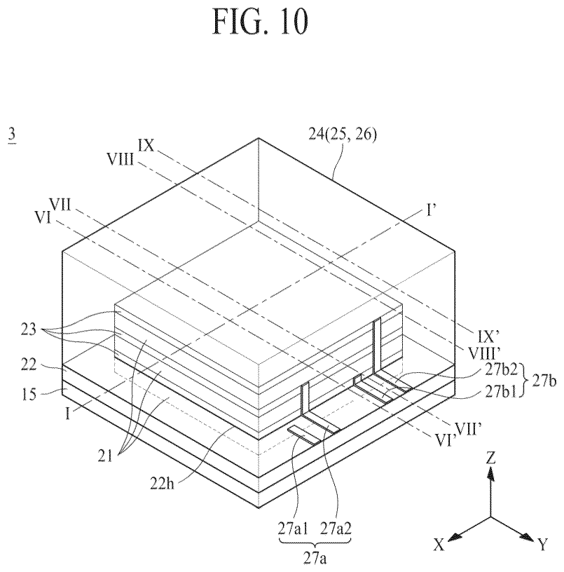

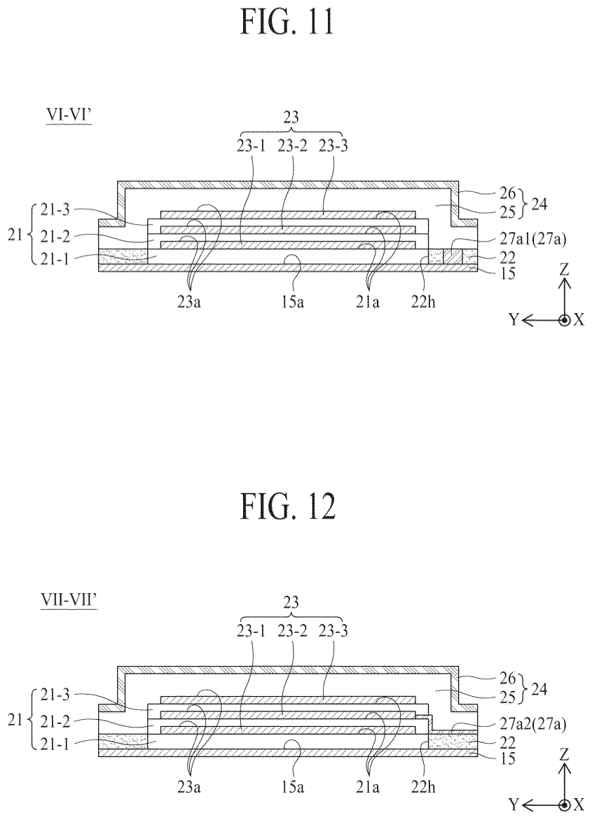

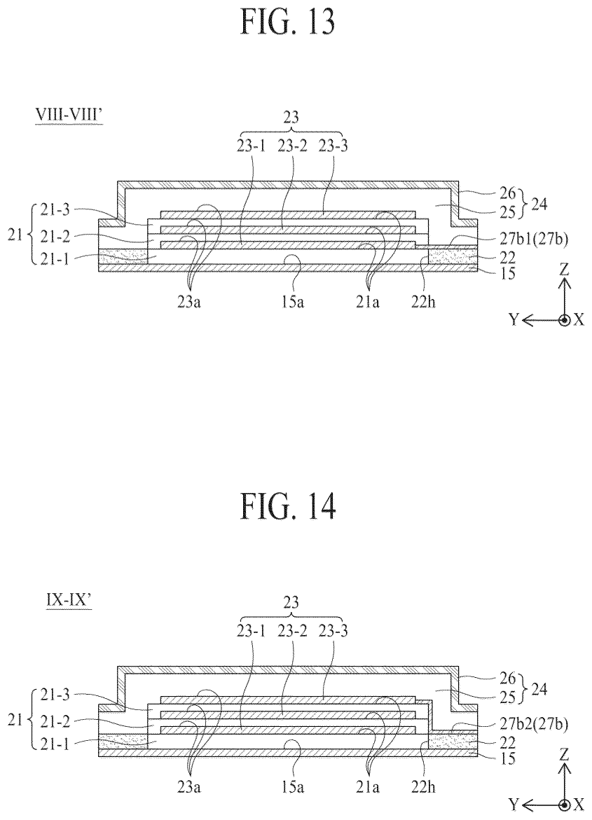

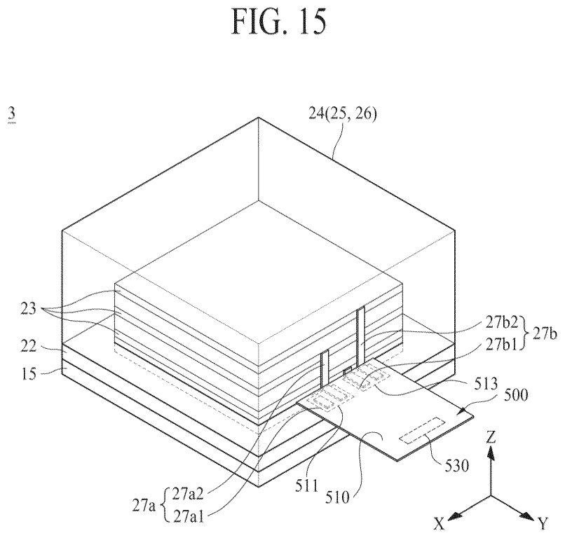

FIG. 10 illustrates a vibration apparatus according to another embodiment of the present disclosure. FIG. 11 is a cross-sectional view taken along line VI-VI′ in FIG. 10. FIG. 12 is a cross-sectional view taken along line VII-VII′ in FIG. 10. FIG. 13 is a cross-sectional view taken along line VIII-VIII′ in FIG. 10. FIG. 14 is a cross-sectional view taken along line IX-IX′ in FIG. 10 a. FIG. 15 illustrates a connection structure of a signal cable connected with a vibration apparatus in FIG. 10. FIGS. 10 to 15 illustrate an embodiment implemented by modifying a contact pattern in the vibration apparatus 1 described above with reference to FIGS. 1 to 5. In the following description, therefore, a modified element will be described in detail, the other elements are referred to by the same reference numerals as FIGS. 1 to 5, and repeated descriptions thereof may be omitted or will be briefly given. Further, the cross-sectional view taken along line I-I′ in FIG. 10 can be substantially the same as FIG. 2, and the illustration is omitted.

Referring to FIGS. 10 to 15, a vibration apparatus 3 according to another embodiment of the present disclosure can include a plurality of first contact patterns 27a and a plurality of second contact patterns 27b. Each of the plurality of first contact patterns 27a and the plurality of second contact patterns 27b can be provided to individually connect with each of a plurality of electrode layers 23 and a conductive substrate 15 (or a plate member).

The first contact pattern 27a can be individually connected with an electrode layer to which a signal having the same polarity is applied. For example, the first contact pattern 27a can include a 1-1^{st} contact pattern 27al and a 1-2^{nd} contact pattern 27a2. The 1-1^{st} contact pattern 27al can be individually and electrically connected with the conductive substrate 15 (or the plate member). Further, the 1-2^{nd} contact pattern 27a2 can be individually and electrically connected with a second electrode layer 23-2.

The second contact pattern 27b can be individually connected with an electrode layer to which a signal having the same polarity is applied. For example, the second contact pattern 27b can include a 2-1^{st} contact pattern 27b1 and a 2-2^{nd} contact pattern 27b2. The 2-1^{st} contact pattern 27b1 can be individually and electrically connected with a first electrode layer 23-1. Further, the 2-2^{nd} contact pattern 27b2 can be individually and electrically connected with a third electrode layer 23-3.

The vibration apparatus 3 can control or adjust a polarization direction (or a poling direction) of a plurality of vibration layers 21 through the plurality of first contact patterns 27a and the plurality of second contact patterns 27b individually connected with each of the plurality of electrode layers 23 and the conductive substrate 15 (or the plate member). For example, a signal polarity applied to an electrode layer through the plurality of first contact patterns 27a and the plurality of second contact patterns 27b can be controlled in a process of forming a vibration layer. Accordingly, the vibration apparatus 3 can be configured so that the plurality of vibration layers 21 are bimorph-driven.

Referring to FIG. 15, the vibration apparatus 3 can further include a signal cable 500.

The signal cable 500 can be configured to be electrically connected with the vibration apparatus 3. For example, the signal cable 500 can be electrically connected with the plurality of first contact patterns 27a and the plurality of second contact patterns 27b individually connected with the conductive substrate 15 (or the plate member), a first electrode layer 23-1, a second electrode layer 23-2, and a third electrode layer 23-3 of the vibration apparatus 3.

A first contact line 511 (or a first contact part) of the signal cable 500 can be individually connected with the plurality of first contact patterns 27a of the vibration apparatus 3 in common. For example, the first contact line 511 can be electrically connected with a 1-1^{st} contact pattern 27al and a 1-2^{nd} contact pattern 27a2 in common. A second contact line 513 (or a second contact part) of the signal cable 500 can be individually connected with the plurality of second contact patterns 27b of the vibration apparatus 3 in common. For example, the second contact line 513 can be electrically connected with a 2-1^{st} contact pattern 27b1 and a 2-2^{nd} contact pattern 27b2 in common.

The vibration apparatus 3 can vibrate based on first and second vibration driving signals (or sound signals) applied to, through the signal cable 500, the conductive substrate 15 (or the plate member) and the second electrode layer 23-2 connected with the plurality of first contact patterns 27a and the first electrode layer 23-1 and the third electrode layer 23-3 connected with the plurality of second contact patterns 27b.

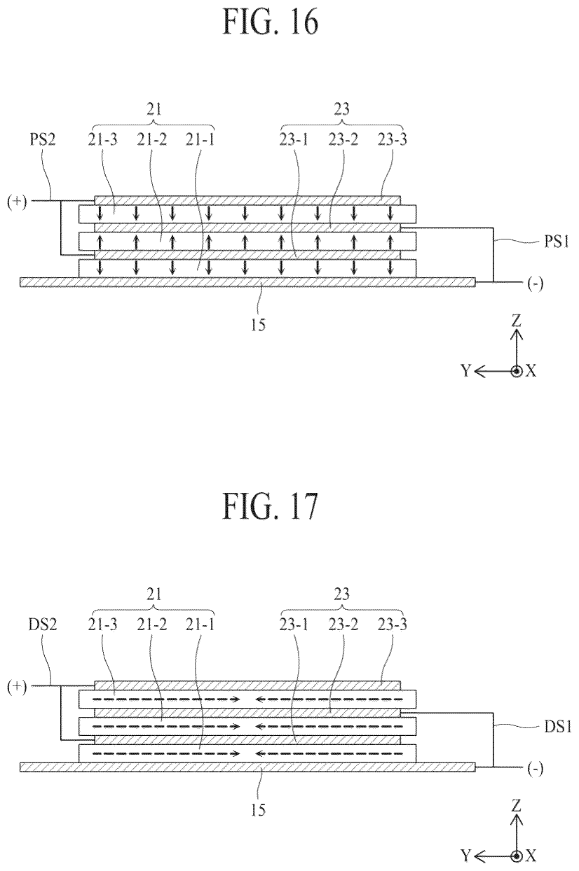

FIGS. 16 and 17 illustrate unimorph driving of a vibration apparatus according to embodiments. This kind of driving can be applied to any of the first to third embodiments described with reference to FIGS. 1-15.

Referring to FIG. 16, a plurality of vibration layers 21 can be polarized (or poling) by a certain voltage applied to a conductive substrate 15 and a plurality of electrode layers 23. For example, a first polarization voltage PS1 can be connected with and applied to the conductive substrate 15 and a second electrode layer 23-2 in common. Further, a second polarization voltage PS2 can be connected with and applied to a first electrode layer 23-1 and a third electrode layer 23-3 in common. For example, the first polarization voltage PS1 can be a negative (−) voltage signal, and the second polarization voltage PS2 can be a positive (+) voltage signal. An arrow in each of FIGS. 16 and 17 represents a polarization direction (or a poling direction).

Therefore, a first vibration layer 21-1 can be configured so that a polarization direction thereof is downward (i.e., towards the conductive substrate 15), based on that the negative (−) voltage signal is applied to the conductive substrate 15 disposed at a first surface of the first vibration layer 21-1 and the positive (+) voltage signal is applied to the first electrode layer 23-1 disposed at a second surface of the first vibration layer 21-1. Further, a second vibration layer 21-2 can be configured so that a polarization direction thereof is upward (i.e., away from the conductive substrate 15), based on that the positive (+) voltage signal is applied to the first electrode layer 23-1 disposed at a first surface of the second vibration layer 21-2 and the negative (−) voltage signal is applied to the second electrode layer 23-2 disposed at a second surface of the second vibration layer 21-2. Further, a third vibration layer 21-3 can be configured so that a polarization direction thereof is downward, based on that the negative (−) voltage signal is applied to the second electrode layer 23-2 disposed at a first surface of the third vibration layer 21-3 and the positive (+) voltage signal is applied to the third electrode layer 23-3 disposed at a second surface of the third vibration layer 21-3.

Referring to FIG. 17, the plurality of vibration layers 21 can be vibration-driven based on a first driving signal DS1 and a second driving signal DS2. For example, the first driving signal DS1 can be connected with and applied to the conductive substrate 15 and the second electrode layer 23-2 in common. Further, the second driving signal DS2 can be connected with and applied to the first electrode layer 23-1 and the third electrode layer 23-3 in common. For example, the first driving signal DS1 can be a negative (−) voltage signal, and the second driving signal DS2 can be a positive (+) voltage signal. For example, the first driving signal DS1 and the second driving signal DS2 may be alternating current (AC) voltage signals.

Alternatively, the first driving signal DS1 and the second driving signal DS2 may be direct current (DC) voltage signals. The first driving signal may be ground or 0V and the second driving signal may be a negative (−) signal, or vice versa. Alternatively, the first driving signal may be ground or 0V and the second driving signal may be a positive (+) signal, or vice versa.

The voltage or driving signals described herein may be provided by a signal driver (or other signal generating apparatus) connected to or included as part of the vibration apparatus. The signal driver may supply the signals to the conductive substrate and electrode layers via the signal lines described herein. For example, the first driving signal DS1 and second driving signal DS2 may be supplied to the conductive substrate and the first electrode layer via the first and second signal lines, respectively.

Therefore, each of the plurality of vibration layers 21 can be vibration-driven in the same direction. For example, the first vibration layer 21-1 can contract or expand in a direction toward a center portion thereof. Further, the second vibration layer 21-2 can contract or expand in a direction toward a center portion thereof. Further, the third vibration layer 21-3 can contract or expand in a direction toward a center portion thereof. Accordingly, the first vibration layer 21-1, the second vibration layer 21-2, and the third vibration layer 21-3 can perform unimorph driving where contraction and/or expansion are alternately repeated in the same direction.

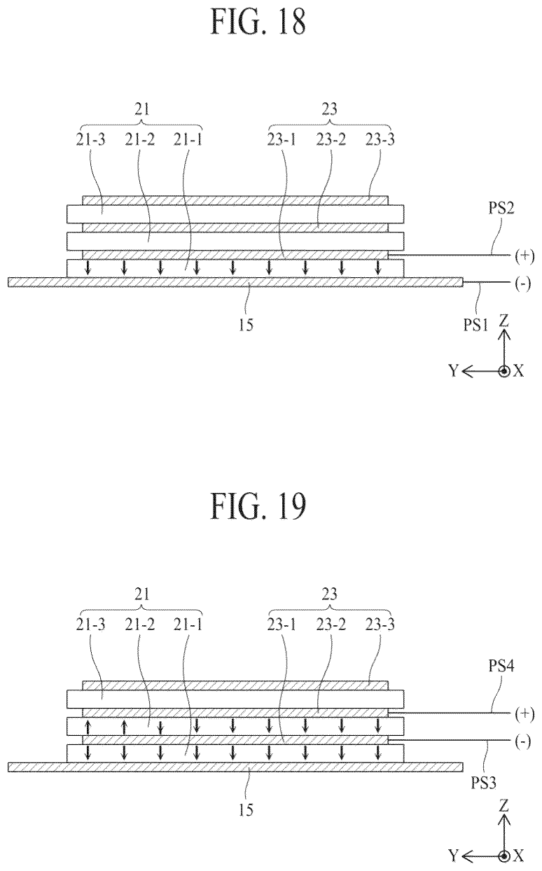

FIGS. 18 to 21 illustrate for describing bimorph driving of a vibration apparatus according to another embodiment of the present disclosure. This kind of driving can be applied to any of the first to third embodiments described with reference to FIGS. 1-15.

Referring to FIGS. 18 to 21, a plurality of vibration layers 21 according to another embodiment of the present disclosure can be individually polarized. For example, each of the plurality of vibration layers 21 can be polarized in the same direction. For example, a first polarization voltage PS1 can be connected with and applied to a conductive substrate 15. Further, a second polarization voltage PS2 can be connected with and applied to a first electrode layer 23-1. For example, the first polarization voltage PS1 can be a negative (−) voltage signal, and the second polarization voltage PS2 can be a positive (+) voltage signal. An arrow in each of FIGS. 18 to 21 represents a polarization direction (or a poling direction).

Therefore, a first vibration layer 21-1 can be configured so that a polarization direction thereof is downward, based on that the negative (−) voltage signal is applied to the conductive substrate 15 disposed at a first surface of the first vibration layer 21-1 and the positive (+) voltage signal is applied to the first electrode layer 23-1 disposed at a second surface of the first vibration layer 21-1.

Referring to FIG. 19, each of a plurality of vibration layers 21 according to another embodiment of the present disclosure can be individually polarized. For example, each of the plurality of vibration layers 21 can be polarized in the same direction. For example, a third polarization voltage PS3 can be connected with and applied to a first electrode layer 23-1. Further, a fourth polarization voltage PS4 can be connected with and applied to a second electrode layer 23-2. For example, the third polarization voltage PS3 can be a negative (−) voltage signal, and the fourth polarization voltage PS4 can be a positive (+) voltage signal.

Therefore, a second vibration layer 21-2 can be configured so that a polarization direction thereof is downward, based on that the negative (−) voltage signal is applied to the first electrode layer 23-1 disposed at a first surface of the second vibration layer 21-2 and the positive (+) voltage signal is applied to the second electrode layer 23-2 disposed at a second surface of the second vibration layer 21-2.

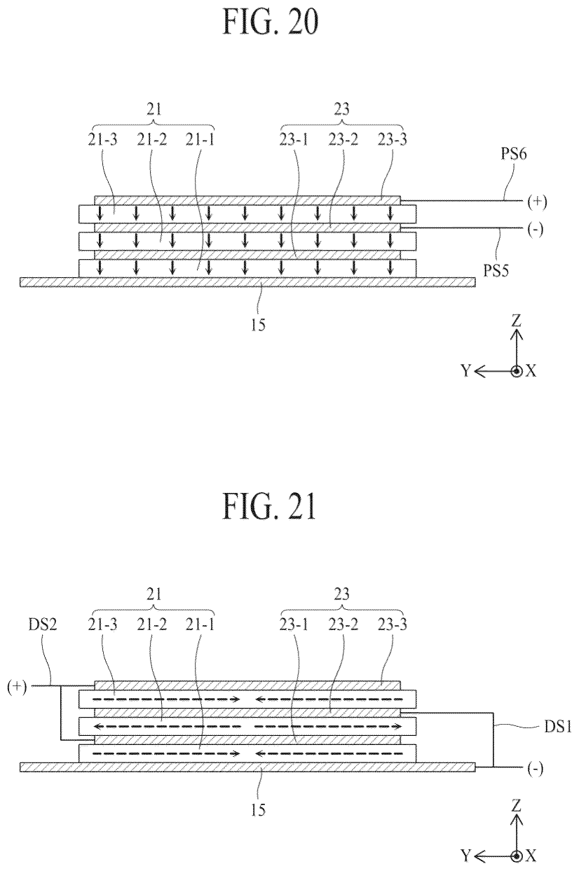

Referring to FIG. 20, each of a plurality of vibration layers 21 according to another embodiment of the present disclosure can be individually polarized. For example, each of the plurality of vibration layers 21 can be polarized in the same direction. For example, a fifth polarization voltage PS5 can be connected with and applied to a second electrode layer 23-2. Further, a sixth polarization voltage PS6 can be connected with and applied to a third electrode layer 23-3. For example, the fifth polarization voltage PS5 can be a negative (−) voltage signal, and the sixth polarization voltage PS6 can be a positive (+) voltage signal.

Therefore, a third vibration layer 21-3 can be configured so that a polarization direction thereof is downward, based on that the negative (−) voltage signal is applied to the second electrode layer 23-2 disposed at a first surface of the third vibration layer 21-3 and the positive (+) voltage signal is applied to the third electrode layer 23-3 disposed at a second surface of the third vibration layer 21-3.

Referring to FIG. 21, the plurality of vibration layers 21 according to another embodiment of the present disclosure can be vibration-driven based on a first driving signal DS1 and a second driving signal DS2. For example, the first driving signal DS1 can be connected with and applied to a conductive substrate 15 and a second electrode layer 23-2 in common. Further, the second driving signal DS2 can be connected with and applied to a first electrode layer 23-1 and a third electrode layer 23-3 in common. For example, the first driving signal DS1 can be a negative (−) voltage signal, and the second driving signal DS2 can be a positive (+) voltage signal.

Therefore, each of the plurality of vibration layers 21 can be vibration-driven in the same direction. For example, the first vibration layer 21-1 can contract or expand in a direction toward a center portion thereof. Further, the second vibration layer 21-2 can contract or expand in a direction toward a left side and a right side thereof. Further, the third vibration layer 21-3 can contract or expand in a direction toward a center portion thereof. Accordingly, the first vibration layer 21-1, the second vibration layer 21-2, and the third vibration layer 21-3 can perform unimorph driving where contraction and/or expansion are alternately repeated in different directions.

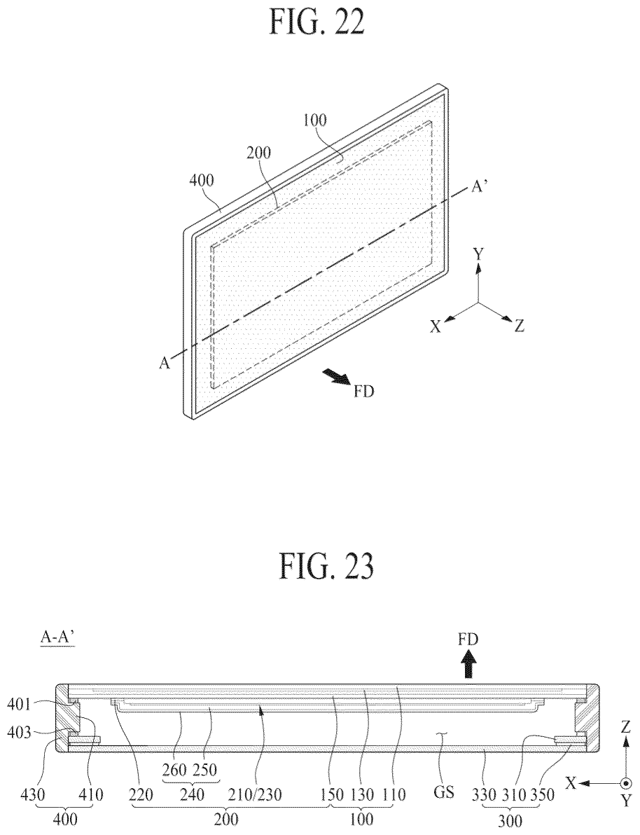

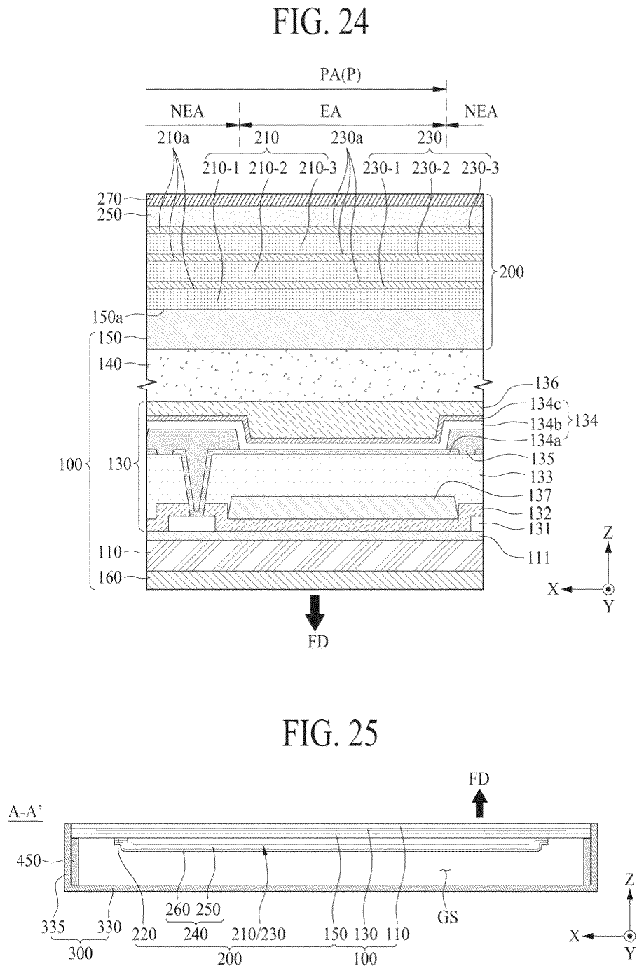

FIG. 22 illustrates a display apparatus according to embodiments. FIG. 23 is a cross-sectional view taken along line A-A′ in FIG. 22. FIG. 24 illustrates one subpixel provided in a display part of FIG. 23. FIG. 25 is another cross-sectional view taken along line A-A′ in FIG. 23. It may be understood that any of the layer and/or connection structures of the first to third embodiments described with reference to FIGS. 1-15 having any of the driving methods described with reference to FIGS. 16-21 may be applied to any of the embodiments described with reference to FIGS. 22-47 and vice versa.

Referring to FIGS. 22 to 24, the display apparatus (or a light emitting display apparatus or a flexible display apparatus) according to embodiments can include a display panel 100 and one or more vibration generating apparatuses 200.

The display panel 100 can be configured to display an image and can be configured to output a sound, based on vibrations of one or more vibration generating apparatuses 200. For example, the display panel 100 can provide a user with a sound and/or a haptic feedback, based on a vibration.

The display panel 100 according to embodiments can include a base member 110, a display part 130, and a plate member 150 (or a conductive substrate).

The base member 110 can include one or more of a glass material and a plastic material. For example, the base member 110 can include a polyimide material. For example, the base member 110 can include a stack structure of a glass layer and a plastic layer, but embodiments of the present disclosure are not limited thereto. For example, the base member 110 can be a base substrate, a first substrate, a display substrate, a front substrate, a front member, or an external substrate, but embodiments of the present disclosure are not limited thereto.

In a case where the plastic material is used as a material of the base member 110, polyimide which is good in thermal resistance and is capable of enduring a high temperature can be used based on that a high temperature deposition process is performed on elements of a display panel on the base member 110, but embodiments of the present disclosure are not limited thereto. All of a first surface (or an internal surface) of the base member 110 can be covered by one or more buffer layers 111.

The buffer layer 111 can prevent a material included in the base member 110 from being diffused to a transistor layer in a high temperature process of a manufacturing process of a thin film transistor (TFT). Further, the buffer layer 111 can prevent external water or moisture from penetrating into a light emitting device layer. The buffer layer 111 can include an inorganic material, but embodiments of the present disclosure are not limited thereto.

The display part 130 can be provided on the base member 110 or the buffer layer 111. The display part 130 can be provided on the base member 110 or the buffer layer 111 to display an image.

The display part 130 can include a plurality of pixels P which display an image, based on signals supplied to signal lines provided on the base member 110 or the buffer layer 111. For example, the display part 130 can include a pixel array part disposed in a pixel area PA provided by a plurality of gate lines and/or a plurality of data lines. The pixel array part can include the plurality of pixels P which display an image, based on the signals supplied to the signal lines. The signal lines can include a gate line, a data line, and a pixel driving power line, but embodiments of the present disclosure are not limited thereto.

Each of the plurality of pixels P (or the pixel area PA) can include an emission region EA and a non-emission region NEA surrounding the emission region EA. The emission region EA can be an opening region, an emission portion, or an opening portion, but embodiments of the present disclosure are not limited thereto. The non-emission region NEA can be a non-emission portion or a circuit region. Each of the plurality of pixels P can be a minimum-unit region which actually emits light and can be defined as a subpixel. At least three adjacent pixels P can be one unit pixel for displaying a color. For example, one unit pixel can include a red pixel, a green pixel, and a blue pixel adjacent to one another and can further include a white pixel for luminance enhancement.

Each of the plurality of pixels P can be configured to display an image in a bottom emission type. Based on the bottom emission type, light emitted from a pixel P can pass through the base member 110 and can be emitted in a rearward direction of the base member 110. Alternatively, each of the plurality of pixels P may be configured to display an image in a top emission type. Based on the top emission type, light emitted from a pixel P may be emitted in a forward direction of the base member 110, but embodiments of the present disclosure are not limited thereto. For example, when each of the plurality of pixels P is configured to display an image in the top emission type, the vibration generating apparatus 200 is connected to a rear surface of the base member 110.

Each of the plurality of pixels P can include a pixel circuit 131, an overcoat layer 133, and a light emitting device layer (or a light emitting device) 134.

The pixel circuit 131 can be provided in the non-emission region NEA of the pixel P along with signal lines and can be connected with a gate line, a data line, and a pixel driving power line which are adjacent thereto. The pixel circuit 131 can control or adjust a current flowing in the light emitting device layer 134 according to a data signal from the data line in response to a scan pulse from the gate line, based on a pixel driving power supplied through the pixel driving power line. The pixel circuit 134 can include a switching TFT, a driving TFT, and a capacitor, but embodiments of the present disclosure are not limited thereto.

Each of the TFTs can include a gate electrode, a gate insulation layer, a semiconductor layer, a source electrode, and a drain electrode. Here, the TFT can be an amorphous silicon (a-Si) TFT, a polysilicon (poly-Si) TFT, an oxide TFT, or an organic TFT, but embodiments of the present disclosure are not limited thereto.

The switching TFT can be turned on based on the scan pulse supplied through the gate line and can transfer a data signal, supplied through the data line, to the driving TFT. The capacitor can be provided in an overlap region between a gate electrode and a source electrode of the driving TFT and can store a voltage corresponding to the data signal supplied to the gate electrode of the driving TFT. The driving TFT can be turned on by a voltage transferred from the switching TFT and/or a voltage of the capacitor, and thus, can control the amount of current flowing from the pixel driving power line to the light emitting device layer 134. For example, the driving TFT can control or adjust a data current flowing from the pixel driving power line to the light emitting device layer 134, based on the data signal transferred from the switching TFT, and thus, the light emitting device layer 134 can emit light having brightness corresponding to the data signal.

The display apparatus can further include a scan driving circuit (or gate driving circuit) which is provided in a non-display part at a periphery of the display part 130 of the base member 110. The scan driving circuit can generate the scan pulse, based on a gate control signal, and can supply the scan pulse to the gate line. The scan driving circuit can be configured with a shift register including a transistor which is formed in the non-display part of the base member 110 formed by the same process as a TFT along with a TFT of the pixel P.

The pixel circuit 131 can be covered by a passivation layer 132. For example, the passivation layer 132 can be provided on the base member 110 to cover the pixel circuit 131. The passivation layer 132 can include an inorganic material, but embodiments of the present disclosure are not limited thereto. For example, the passivation layer 132 can be omitted. For example, the passivation layer 132 can be a protection layer, but embodiments of the present disclosure are not limited thereto. The overcoat layer 133 can be provided on the base member 110 to cover the pixel circuit 131. The overcoat layer 133 can be configured to provide a flat surface on the pixel circuit 131. For example, the overcoat layer 133 can include an organic material, but embodiments of the present disclosure are not limited thereto. For example, the overcoat layer 133 can be a protection layer or a planarization layer, but the terms are not limited thereto.

The light emitting device layer 134 can be provided on the overcoat layer 133. The light emitting device layer 134 can be a pixel electrode 134a, a light emitting device 134b, and a common electrode 134c.

The pixel electrode 134a (or an anode electrode) can be provided on the overcoat layer 133 overlapping all of the emission region EA of each pixel area PA and a portion of the non-emission region NEA. For example, the pixel electrode 134a can be provided in a pattern form. The pixel electrode 134a can be electrically connected with the driving TFT of the pixel circuit 131 through a contact hole provided in the overcoat layer 133. The pixel electrode 134a can include a transparent conductive material, but embodiments of the present disclosure are not limited thereto.

A periphery portion of the pixel electrode 134a disposed at a portion of the non-emission region NEA of each pixel area PA can be covered by a bank layer 135. The bank layer 135 can be provided on the overcoat layer 133 to cover the periphery portion of the pixel electrode 134a and the pixel circuit 131, and thus, can define (or divide) the emission region EA (or an opening region or a light extraction region) of each of the plurality of pixels P.

The light emitting device 134b can be formed or provided on the pixel electrode 134a. The light emitting device 134b can be provided to directly contact the pixel electrode 134a. For example, the light emitting device 134b can include an organic light emitting device or an inorganic light emitting device. For example, the light emitting device 134b can include one of an organic emission layer, an inorganic emission layer, and a quantum dot emission layer, or can include a stack or combination structure of an organic emission layer (or an inorganic emission layer) and a quantum dot emission layer, but embodiments of the present disclosure are not limited thereto.

The common electrode 134c (or a cathode electrode) can be connected with the light emitting device 134b provided in each of the plurality of pixels P in common. The common electrode 134c can include a metal material having a high reflectance so as to reflect light, which is emitted from the light emitting device 134b and is incident thereon, toward the base member 110.

The light emitting device 134b can be implemented to emit light of the same color (for example, white light) for each pixel, or can be implemented to emit light of a different color (for example, red, green, or blue light) for each pixel. The light emitting device 134b can have a stack structure including two or more structures or a single structure including the same color for each pixel. Alternatively, the light emitting device 134b can have a stack structure including two or more structures including one or more different colors for each pixel. Two or more structures including one or more different colors can be configured with one or more of blue, red, yellow-green, and green, or a combination thereof, but embodiments of the present disclosure are not limited thereto. Examples of a combination can include a combination of blue and red, a combination of red and yellow-green, a combination of red and green, and a combination of red, yellow-green, and green, but embodiments of the present disclosure are not limited thereto. In a stack structure including two or more structures having the same color or one or more different colors, a charge generating layer can be further provided between two or more structures. The charge generating layer can have a PN junction structure and can include an N-type charge generating layer and a P-type charge generating layer.

The light emitting device 134b can include a micro light emitting diode device electrically connected with the pixel electrode 134a and the common electrode 134c. The micro light emitting diode device can be a light emitting diode implemented as an integrated circuit (IC) or chip type. The micro light emitting diode device can include a first terminal electrically connected with the pixel electrode 134a and a second terminal electrically connected with the common electrode 134c.

The display apparatus or the display part 130 can further include a color filter layer 137.

The color filter layer 137 can be provided between the base member 110 and the overcoat layer 33 to overlap the emission region EA of the pixel P. The color filter layer 137 can be provided between the passivation layer 132 and the overcoat layer 33 to overlap the emission region EA. Alternatively, the color filter layer 137 can be disposed between the base member 110 and the buffer layer 111, or can be provided between the buffer layer 111 and the passivation layer 132 to overlap the emission region EA.

The color filter layer 137 can include a color filter which transmits only wavelength of a color set in each of the plurality of pixels P. For example, the color filter layer 137 can include a red color filter, a green color filter, and a blue color filter, but embodiments of the present disclosure are not limited thereto.

The display panel 100 or the display part 130 can further include an encapsulation layer 136.

The encapsulation layer 136 can be provided to surround or cover the display part 130. The encapsulation layer 136 can be configured to prevent external water or moisture from penetrating into the light emitting device layer 134. The encapsulation layer 136 can be formed of an inorganic material layer or an organic material layer, or can be formed in a multi-layer structure where an inorganic material layer and an organic material layer are alternately stacked or formed, but embodiments of the present disclosure are not limited thereto. For example, the encapsulation layer 136 can be omitted.

The display apparatus or the display panel 100 a can further include a functional film 160.

The functional film 160 can be disposed on a second surface (or an outer surface or a light extraction surface), which is opposite to a first surface, of the base member 110. For example, the functional film 160 can be coupled or adhered to the second surface of the base member 110 by a transparent adhesive member. The functional film 160 can include one or more of an antireflection layer (or an antireflection film), a barrier layer (or a barrier film), a touch sensing layer, and a light path control layer (or a light path control film), but embodiments of the present disclosure are not limited thereto.

The antireflection layer can be a polarization layer (or a polarizing film) which blocks reflected light which is reflected by the TFTs and/or the signal lines disposed on the base member 110 and travels to the outside again. For example, the antireflection layer can include a circular polarization layer (or a circular polarizing film). The barrier layer can include a material (for example, a polymer material) having a low water penetration rate, and thus, can prevent the penetration of water or oxygen from the outside. The touch sensing layer can include a touch electrode layer based on a mutual capacitance type or a self-capacitance type, and thus, can output touch data corresponding a user touch through the touch electrode layer. The light path control layer can include a structure where a high refraction layer and a low refraction layer are alternately stacked or formed, and thus, can change a path of light incident from each pixel P to minimize a color shift phenomenon based on a viewing angle.

The plate member 150 (or the conductive substrate) can be provided to cover the display part 130. The plate member 150 (or the conductive substrate) can be attached on the display part 130 by an adhesive member 140. The adhesive member 140 can be provided on the base member 110 to surround the display part 130. A first surface of the plate member 150 (or the conductive substrate) can be coupled to (or attached on) the adhesive member 140, or can be directly coupled to (or attached on) the adhesive member 140. Accordingly, the display part 130 can be surrounded by the base member 110 and the adhesive member 140, and thus, can be buried or embedded between the base member 110 and the adhesive member 140. For example, a second surface 150a, which is opposite to or different from the first surface, of the plate member 150 (or the conductive substrate) can be a rear surface of the display apparatus or a rear surface (or a backside) of the display panel 100.

The plate member 150 (or the conductive substrate) can dissipate heat which occurs in the display panel 100. The plate member 150 (or the conductive substrate) can protect the display part 130 or the display panel 100 from an external impact and can prevent external water or moisture from penetrating into the light emitting device layer 134. The plate member 150 (or the conductive substrate) can compensate for the stiffness of the display panel 100. For example, the plate member 150 (or the conductive substrate) can be a first driving electrode, a first electrode, a plate, a conductive plate, a conductive plate member, a heat dissipation member, a heat dissipation plate, a conductive substrate, a heat dissipation substrate, an encapsulation substrate, an encapsulation plate, a stiff plate, a second substrate, a rear substrate, a rear member, a rear plate, an internal substrate, or an internal plate, but embodiments of the present disclosure are not limited thereto.

The plate member 150 (or the conductive substrate) can include a conductive material or a metal material. For example, the plate member 150 can include one or more materials of an alloy of Fe and Ni, stainless steel, aluminum (Al), magnesium (Mg), a Mg alloy, a Mg—Li alloy, and an Al alloy, but embodiments of the present disclosure are not limited thereto.

The adhesive member 140 can be disposed between the display part 130 and the plate member 150 (or the conductive substrate) and can bond or attach the plate member 150 to the display part 130. For example, the adhesive member 140 can be a filler. For example, the adhesive member 140 can include a pressure sensitive adhesive (PSA), an optically clear adhesive (OCA), or an optically clear resin (OCR), but embodiments of the present disclosure are not limited thereto. For example, the adhesive member 140 can further include a vibration transfer medium. For example, the vibration transfer medium can reduce the loss of a vibration transferred to the base member 110. For example, the vibration transfer medium can include a piezoelectric material which is included in or added to the adhesive member 140, but embodiments of the present disclosure are not limited thereto.

The display apparatus or the vibration generating apparatus 200 according to embodiments can further include an insulation layer 220.

The insulation layer 220 can be provided on the plate member 150 (or the conductive substrate). For example, the insulation layer 220 can be provided on the second surface 150a of the plate member 150 (or the conductive substrate). The insulation layer 220 can be provided in at least a portion of the plate member 150 (or the conductive substrate). The insulation layer 220 can be disposed at the second surface 150a of the plate member 150 (or the conductive substrate) at a periphery of each of the plurality of vibration layers 210 and the plurality of electrode layers 230 of the vibration generating apparatus 200. For example, the insulation layer 220 can be provided to surround the periphery of each of the plurality of vibration layers 210 and the plurality of electrode layers 230 at the second surface 150a of the plate member 150 (or the conductive substrate). For example, the plurality of vibration layers 210 and the plurality of electrode layers 230 of the vibration generating apparatus 200 can be provided not to overlap the insulation layer 220.

The insulation layer 220 can be disposed at the second surface 150a of the plate member 150 (or the conductive substrate) to surround a periphery of the first vibration layer 210-1 corresponding (or adjacent) to the plate member 150 (or the conductive substrate) among the plurality of vibration layers 210. For example, the insulation layer 220 can be disposed at a portion or all of the other portion, except a disposition region of the first vibration layer 210-1, of the second surface 150a of the plate member 150 (or the conductive substrate).

The insulation layer 220 can be formed to have a thickness which is the same as or different from that of the first vibration layer 210-1. For example, the insulation layer 220 can be formed to have the same thickness as that of the first vibration layer 210-1. The insulation layer 220 can cover the second surface 150a of the plate member 150 (or the conductive substrate), and thus, can prevent the occurrence of an electrical connection (or short circuit) with the plurality of electrode layers 230 on the plate member 150. The insulation layer 220 can include an organic material or an inorganic material, but embodiments of the present disclosure are not limited thereto.

The vibration generating apparatus 200 can be configured to vibrate the display panel 100. The vibration generating apparatus 200 can be directly provided in the display panel 100, or can be directly connected with a rear surface of the display panel 100. For example, the vibration generating apparatus 200 can be integrated into the display panel 100. For example, the display panel 100 can be a display panel provided as one body with a vibration apparatus.

The vibration generating apparatus 200 can include the plate member 150 (or the conductive substrate) of the display panel 100. The plate member 150 (or the conductive substrate) of the display panel 100 can be used as an electrode of the vibration generating apparatus 200. For example, the vibration generating apparatus 200 can be a vibration device, a vibration apparatus, a vibrator, a vibration generator, an active vibration member, a displacement device, a displacement apparatus, a sound generating device, a sound generator, a sound generating apparatus, a speaker, or a piezoelectric speaker, but embodiments of the present disclosure are not limited thereto.

The vibration generating apparatus 200 can alternately repeat contraction and/or expansion based on a piezoelectric effect to vibrate in a thickness direction Z, and thus, can vibrate the display panel 100. For example, the vibration generating apparatus 200 can alternately and repeatedly contract and/or expand based on an inverse piezoelectric effect to vibrate in a thickness direction Z, and thus, can directly vibrate the display panel 100.

The vibration generating apparatus can include a plate member 150 (or a conductive substrate), a plurality of vibration layers 210, and a plurality of electrode layers 230.

The plurality of vibration layers 210 can include a first vibration layer 210-1, a second vibration layer 210-2, and a third vibration layer 210-3. For example, the plurality of vibration layers 210 can include two or more layers, but embodiments of the present disclosure are not limited thereto. Further, the plurality of electrode layers 230 can include a first electrode layer 230-1, a second electrode layer 230-2, and a third electrode layer 230-3. The plurality of vibration layers 210 can be provided to be equal to the number of electrode layers 230 and the number of vibration layers 21 and the number of electrode layers 23 can each be provided as two or more, but embodiments of the present disclosure are not limited thereto.

The plate member 150 (or the conductive substrate), the plurality of vibration layers 210, and the plurality of electrode layers 230 can be alternately stacked or formed. For example, the first vibration layer 210-1 of the plurality of vibration layers 210 can be disposed at the second surface 150a of the plate member 150, and the first electrode layer 230-1 of the plurality of electrode layers 230 can be disposed at a second surface 210a of the first vibration layer 210-1. For example, the first vibration layer 210-1 and the first electrode layer 230-1 can be configured to correspond (adjacent) to each other. Further, the first vibration layer 210-1 can be disposed between the first electrode layer 230-1 and the plate member 150. Further, the second vibration layer 210-2 of the plurality of vibration layers 210 can be disposed at a second surface 230a of the first electrode layer 230-1, and the second electrode layer 230-2 of the plurality of electrode layers 230 can be disposed at a second surface 210a of the second vibration layer 210-2. For example, the second vibration layer 210-2 and the second electrode layer 230-2 can be configured to correspond (adjacent) to each other. Further, the first electrode layer 230-1 can be disposed between the first vibration layer 210-1 and the second vibration layer 210-2. Further, the second vibration layer 210-2 can be disposed between the first electrode layer 230-1 and the second electrode layer 230-2. Further, the third vibration layer 210-3 of the plurality of vibration layers 210 can be disposed at a second surface 230a of the second electrode layer 230-2, and the third electrode layer 230-3 of the plurality of electrode layers 230 can be disposed at a second surface 210a of the third vibration layer 210-3. For example, the third vibration layer 210-3 and the third electrode layer 230-3 can be configured to correspond (adjacent) to each other. Further, the second electrode layer 230-2 can be disposed between the second vibration layer 210-2 and the third vibration layer 210-3. Further, the third vibration layer 210-3 can be disposed between the second electrode layer 230-2 and the third electrode layer 230-3. Accordingly, the plurality of vibration layers 210 and the plurality of electrode layers 230 can be alternately stacked or formed.

The plate member 150 (or the conductive substrate) of the display panel 100 can be configured as a driving electrode which drives (or vibrates) the plurality of vibration layers 210 along with the plurality of electrode layers 230. For example, the plate member 150 (or the conductive substrate) can be a first driving electrode to which a first vibration driving signal is applied. For example, the plate member 150 (or the conductive substrate) can be a first driving electrode, a first electrode, a conductive plate, a metal electrode, an electrode member, an electrode plate, a lower electrode, a lower electrode plate, a common electrode member, or a common electrode.

The plurality of vibration layers 210 can be provided at a first surface or a second surface, which is opposite to the first surface, of the plate member 150 (or the conductive substrate). For example, the plurality of vibration layers 210 can be provided at the second surface of the plate member 150 (or the conductive substrate). For example, a vibration layer 210 adjacent to the plate member 150 among the plurality of vibration layers 210 can be directly formed at or directly coupled to (or connected to) the second surface of the plate member 150. The other vibration layer 210 of the plurality of vibration layers 210 can be stacked or formed on the second surface of the plate member 150.

At least some of the plurality of electrode layers 230 can be a first driving electrode to which a first vibration driving signal is applied along with the plate member 150. Further, the other some of the plurality of electrode layers 230 can be a second driving electrode to which a second vibration driving signal is applied. For example, the first driving signal and the second driving signal can be signals having different polarities, but embodiments of the present disclosure are not limited thereto.

Each of the plurality of electrode layers 230 can be provided to respectively correspond to the plurality of vibration layers 210. For example, the plurality of electrode layers 230 can be provided to be equal to the number of vibration layers 210. Each of the plurality of electrode layers 230 can be provided at or coupled to (or connected to) the second surface 21a of a corresponding (or adjacent) vibration layer 210. For example, the plurality of electrode layers 230 can be provided to respectively correspond to the plurality of vibration layers 210 in a one-to-one relationship. At least one of the plurality of electrode layers 230 can be between adjacent vibration layers 210. For example, the other electrode layers 230, except an electrode layer of an uppermost layer, of the plurality of electrode layers 230 can be disposed between adjacent vibration layers 210. Therefore, each of the plurality of vibration layers 210 can vibrate based on a vibration driving signal (or a voltage or a signal) applied to the plate member 150 (or the conductive substrate) of the display panel 100 and the plurality of electrode layers 230. For example, each of the plurality of vibration layers 210 can vibrate based on a first vibration driving signal (or a first voltage or a first signal) applied to the plate member 150 (or the conductive substrate) of the display panel 100 and some of the plurality of electrode layers 230 and a second vibration driving signal (or a second voltage or a second signal) applied to the other some of the plurality of electrode layers 230. The plurality of electrode layers 230 can have the same size as that of the plurality of vibration layers 210, or can have a size which is less than that of the plurality of vibration layers 210. Each of the plurality of electrode layers 230 can be disposed at a center portion of a corresponding (or adjacent) vibration layer 210. For example, the plurality of electrode layers 230 can have the same shape as that of the plurality of vibration layers 210, but embodiments of the present disclosure are not limited thereto. For example, the plurality of electrode layers 230 can each be an electrode layer, an upper electrode, an upper electrode layer, a middle electrode, a middle electrode layer, a first driving electrode, a second driving electrode, an individual electrode, an individual electrode layer, a patterned electrode, or a patterned electrode layer, but embodiments of the present disclosure are not limited thereto.

To prevent an electrical connection (or short circuit) between the plate member 150 (or the conductive substrate) and the plurality of electrode layers 230, each of the plurality of electrode layers 230 can be formed at the other portion, except a periphery portion of the second surface 210a, of a corresponding (or adjacent) vibration layer 210 of the plurality of vibration layers 210. For example, each of the plurality of electrode layers 230 can be formed at all of the other second surface, except a periphery portion, of a corresponding (or adjacent) vibration layer 210 of the plurality of vibration layers 210. For example, a distance between a lateral surface (or an outer wall) of each of the plurality of electrode layers 230 and a lateral surface (or an outer wall) of each of the plurality of vibration layers 210 can be at least 0.5 mm or more. For example, the distance between the lateral surface of each of the plurality of electrode layers 230 and the lateral surface of each of the plurality of vibration layers 210 can be at least 1 mm or more, but embodiments of the present disclosure are not limited thereto.

Each of the plurality of vibration layers 210 can include a piezoelectric material or an electroactive material having a piezoelectric effect. For example, the piezoelectric material can have a characteristic where pressure or twisting is applied to a crystalline structure by an external force, a potential difference occurs due to dielectric polarization caused by a relative position change of a positive (+) ion and a negative (−) ion, and a vibration is generated by an electric field based on a voltage applied thereto. For example, each of the plurality of vibration layers 210 can be a piezoelectric layer, a piezoelectric material layer, an electro active layer, a piezoelectric material portion, an electro active portion, a piezoelectric structure, piezoelectric ceramic, a vibration portion, a vibration generating portion, a displacement portion, a displacement generating portion, a sound generating portion, or an active vibration portion, but embodiments of the present disclosure are not limited thereto.

Each of the plurality of vibration layers 210 can include a ceramic-based material capable of implementing a relatively high vibration, or can include piezoelectric ceramic having a perovskite-based crystalline structure.

The piezoelectric ceramic can include single crystalline ceramic having a single crystalline structure, or can include polycrystalline ceramic or a ceramic material having a polycrystalline structure. A piezoelectric material of the single crystalline ceramic can include α-AlPO₄, α-SiO₂, LiNbO₃, Tb₂(MoO₄)₃, LizB₄O₇, or ZnO, but embodiments of the present disclosure are not limited thereto. The piezoelectric material of the single crystalline ceramic can include a lead zirconate titanate (PZT)-based material including lead (Pb), zirconium (Zr), and titanium (Ti) or can include a lead zirconate nickel niobate (PZNN)-based material including lead (Pb), zinc (Zn), nickel (Ni), and niobium (Nb), but embodiments of the present disclosure are not limited thereto. For example, each of the plurality of vibration layers 210 can include one or more of CaTiO₃, BaTiO₃, and SrTiO₃ without Pb, but embodiments of the present disclosure are not limited thereto.

Each of the plurality of electrode layers 230 can include a transparent conductive material, a semitransparent conductive material, or an opaque conductive material. For example, the transparent conductive material or the semitransparent conductive material of each of the plurality of electrode layers 230 can include indium tin oxide (ITO) or indium zinc oxide (IZO), but embodiments of the present disclosure are not limited thereto. The opaque conductive material of each of the plurality of electrode layers 230 can include gold (Au), silver (Ag), platinum (Pt), palladium (Pd), molybdenum (Mo), magnesium (Mg), carbon, or glass frit-containing Ag, or can include an alloy thereof, but embodiments of the present disclosure are not limited thereto. For example, the plurality of electrode layers 230 can include Ag having low resistivity, so as to enhance an electrical characteristic and/or a vibration characteristic of the plurality of vibration layers 210. For example, the carbon can be carbon black, ketjen black, carbon nano tube, or a carbon material including graphite, but embodiments of the present disclosure are not limited thereto.

In the plurality of electrode layers 230 including Ag including the glass frit, a content of glass frit can be 1 wt % to 12 wt %, but embodiments of the present disclosure are not limited thereto. The glass frit can include a PbO or Bi₂O₃-based material, but embodiments of the present disclosure are not limited thereto. Accordingly, a coupling force (or an adhesive force) between the plurality of electrode layers 230 and the plurality of vibration layers 210 can increase based on the glass frit. For example, a coupling force (or an adhesive force) between a first surface of each of the plurality of electrode layers 230 and a second surface 210a of a corresponding (or adjacent) vibration layer 210 of the plurality of vibration layers 210 can increase based on the glass frit.

The plurality of vibration layers 210 and the plurality of electrode layers 230 can be provided on the second surface 150a of the plate member 150 through a process before a coupling process between the plate member 150 (or the conductive substrate) and the display part 130. A first surface of a vibration layer 210 adjacent to the plate member 150 among the plurality of vibration layers 210 can be coupled to or contact the second surface 150a of the plate member 150. Further, the plurality of electrode layers 230 and the plurality of vibration layers 210 can be alternately provided on the vibration layer 210 coupled to the plate member 150. For example, a first surface of the first vibration layer 210-1 of the plurality of vibration layers 210 can be electrically coupled to or electrically contact the second surface 150a of the plate member 150. Further, a second surface 210a of the first vibration layer 210-1 can be electrically coupled to or electrically contact a first surface of the first electrode layer 230-1 of the plurality of electrode layers 230. Further, a first surface of the second vibration layer 210-2 of the plurality of vibration layers 210 can be electrically coupled to or electrically contact the second surface 230a of the first electrode layer 230-1. Further, a second surface 210a of the second vibration layer 210-2 can be electrically coupled to or electrically contact a first surface of the second electrode layer 230-2 of the plurality of electrode layers 230. Further, a first surface of the third vibration layer 210-3 of the plurality of vibration layers 210 can be electrically coupled to or electrically contact the second surface 230a of the second electrode layer 230-2. Further, a second surface 210a of the third vibration layer 210-3 can be electrically coupled to or electrically contact a first surface of the third electrode layer 230-3 of the plurality of electrode layers 230. For example, when the number of vibration layers 210 is four or more or the number of electrode layers 230 is four or more, four or more vibration layers 210 and electrode layers 230 can be alternately stacked or formed by repeating the above-described process.

Each of the plurality of vibration layers 210 and the plurality of electrode layers 230 can include a three or more-angled polygonal shape, a non-tetragonal shape, a circular shape, or an oval shape, but embodiments of the present disclosure are not limited thereto. For example, the non-tetragonal shape can include one or more of one or more lines and one or more curves having a curvature, but embodiments of the present disclosure are not limited thereto.

The plurality of vibration layers 210 and the plurality of electrode layers 230 can be configured or implemented to be alternately stacked or formed on the second surface 150a of the plate member 150 by a tape casting scheme. For example, the plurality of vibration layers 210 and the plurality of electrode layers 230 can be alternately stacked or formed on the second surface 150a of the plate member 150 by a tape casting process (or scheme) by a piezoelectric material and a conductive material on the plate member 150.

Each of the plurality of vibration layers 210 and the plurality of electrode layers 230 can be formed (or manufactured) through a step of preparing a metal paste and a slurry including a piezoelectric powder (or a ceramic powder) and additives, a step of coating (or tape casting or forming) the slurry on the second surface of the plate member 150, a step of drying (or curing) the coated (or formed) slurry, a step of coating (or tape casting or forming) the metal paste on a second surface of the cured slurry, a step of drying (or curing) the coated (or formed) metal paste, a step of alternately and repeatedly coating (or forming) and drying (or curing) the slurry and the metal paste, and a step of molding (or sintering) the alternately stacked (or formed) slurry and metal paste at least once. For example, the additives added to the slurry can include a material or substance of the piezoelectric material composition field, but embodiments of the present disclosure are not limited thereto. Further, the additives of the slurry can include one or more of a dispersant, a solvent, a binder, and a plasticizer, but embodiments of the present disclosure are not limited thereto. Further, the additives added to the metal paste can include a material or substance of the electrode material composition field, but embodiments of the present disclosure are not limited thereto. For example, the metal paste can be Ag, Au, Cu, and Ag/Cu, but embodiments of the present disclosure are not limited thereto. For example, the additives of the metal paste can be sintered simultaneously with piezoelectric ceramic and can include a binder for reinforcing an adhesive force with ceramic, but embodiments of the present disclosure are not limited thereto.

According to embodiments, the binder can include a high temperature binder. For example, the binder can include a glass frit. The binder can remain in a particle state on the second surface of the plate member 150 and/or the second surface of the cured metal paste in drying the slurry. The binder can be changed to a liquid state when a piezoelectric particle (or a ceramic particle) grows at a molding (or sintering) temperature of the slurry, can move to an interface between the plate member 150 and/or the cured metal paste and a piezoelectric, and can be coagulated as a molding temperature is reduced, thereby increasing a coupling force (or an adhesive force) between the plate member 150 and/or the cured metal paste and the piezoelectric. For example, a content of glass frit can be 1 wt % to 12 wt %, but embodiments of the present disclosure are not limited thereto. The glass frit can include a PbO or Bi₂O₃-based material, but embodiments of the present disclosure are not limited thereto. For example, the metal paste can be a middle electrode or an upper electrode of the piezoelectric, but embodiments of the present disclosure are not limited thereto.

The plurality of vibration layers 210 and the plurality of electrode layers 230 can be configured by the tape casting scheme, and thus, may not be limited to a specific shape and can include a three or more-angled polygonal shape, a non-tetragonal shape, a circular shape, or an oval shape, but embodiments of the present disclosure are not limited thereto.

The plurality of vibration layers 210 can overlap the display part 130 of the display panel 100. For example, the plurality of vibration layers 210 can have a size corresponding to the display part 130 of the display panel 100. For example, a size of the plurality of vibration layers 210 can be less than or equal to that of the display part 130. For example, a size of the plurality of vibration layers 210 can be 0.9 to 1.1 times a size of the display part 130, but embodiments of the present disclosure are not limited thereto. For example, a size of the plurality of vibration layers 210 can be equal to or almost equal to that of the display part 130 of the display panel 100, and thus, can cover a large region of the display panel 100 and a vibration generated by the plurality of vibration layers 210 can vibrate an entire region of the display panel 100, thereby enhancing satisfaction of a user and increasing a sense of localization of a sound. Further, a contact area (or a panel coverage) between the display panel 100 and the vibration generating apparatus 200 can increase, and thus, a vibration region of the display panel 100 can increase, thereby enhancing a sound of a middle-low pitched sound band generated based on a vibration of the display panel 100.

Each of the plurality of vibration layers 210 can be polarized (or poling) by a certain voltage applied from the outside to the plate member 150 (or the conductive substrate) and the first driving electrode and the second driving electrode of the plurality of electrode layers 230 in a certain temperature atmosphere or a temperature atmosphere which is changed from a high temperature to a room temperature, but embodiments of the present disclosure are not limited thereto. For example, each of the plurality of vibration layers 210 can alternately and repeatedly contract and/or expand based on an inverse piezoelectric effect based on a first vibration driving signal and a second vibration driving signal applied from the outside to the plate member 150 (or the conductive substrate) and the first driving electrode and the second driving electrode of the plurality of electrode layers 230, and thus, can vibrate. For example, the plurality of vibration layers 210 can vibrate based on a vertical-direction vibration and/or a horizontal-direction (or a direction parallel to a plane) vibration according to the first vibration driving signal and the second vibration driving signal applied to the plate member 150 (or the conductive substrate) and the first driving electrode and the second driving electrode of the plurality of electrode layers 230. Accordingly, a displacement of the vibration generating apparatus 200 or the display panel 100 can be increased or enhanced based on the contraction and/or expansion of the plurality of vibration layers 210 in a horizontal direction (or a direction parallel to a plane).

The display panel or the vibration generating apparatus 200 can further include a protection layer 240.

The protection layer 240 can be configured to protect the vibration generating apparatus 200. The protection layer 240 can be configured to protect the insulation layer 220, the plurality of vibration layers 210, and the plurality of electrode layers 230. For example, the protection layer 240 can be configured to protect the third electrode layer 230-3 of an uppermost layer of the plurality of electrode layers 230. The protection layer 240 can be configured to protect the lateral surfaces of the plurality of vibration layers 210 and the plurality of electrode layers 230, which are stacked or formed under the third electrode layer 230-3. For example, the protection layer 240 can be configured to surround or cover the plurality of vibration layers 210 and the plurality of electrode layers 230. For example, the protection layer 240 can include an inorganic material or an organic material, but embodiments of the present disclosure are not limited thereto.

The protection layer 240 can include a cover member 260 and an adhesive layer 250.

The cover member 260 can be provided to protect the vibration generating apparatus 200. The cover member 260 can be provided to protect the insulation layer 220, the plurality of vibration layers 210, and the plurality of electrode layers 230. For example, the cover member 260 can be configured to surround or cover the plurality of vibration layers 210 and the plurality of electrode layers 230. For example, the cover member 260 can be a cover film, a cover layer, a protection member, or a protection layer, but embodiments of the present disclosure are not limited thereto. For example, the cover member 260 can be a polyimide (PI) film, a polyethylene terephthalate (PET) film, or a polyethylene naphthalate (PEN), but embodiments of the present disclosure are not limited thereto.

The cover member 260 can be connected with or coupled to a second surface 230a of the third electrode layer 230-3 of an uppermost layer of the plurality of electrode layers 230 by an adhesive layer 250. For example, the cover member 260 can be connected with or coupled to the third electrode layer 230-3 by a film laminating process by the adhesive layer 250. For example, the cover member 260 can be connected with or coupled to the insulation layer 220, the third electrode layer 230-3, and the lateral surfaces of the plurality of vibration layers 210 and the plurality of electrode layers 230, which are stacked or formed under the third electrode layer 230-3.

The adhesive layer 250 can be disposed between the third electrode layer 230-3 and the cover member 260. For example, the adhesive layer 250 can be provided or disposed between the insulation layer 220 and the cover member 260 to cover or surround the plurality of vibration layers 210 and the plurality of electrode layers 230. For example, the adhesive layer 250 can be provided or filled between the insulation layer 220 and the cover member 260 to fully surround the second surface 230a of the third electrode layer 230-3 and the lateral surfaces of the plurality of vibration layers 210 and the plurality of electrode layers 230, which are stacked or formed under the third electrode layer 230-3. For example, the plurality of vibration layers 210 and the plurality of electrode layers 230 can be buried or embedded between the plate member 150 (or the conductive substrate), and the insulation layer 220 and the adhesive layer 250.

The adhesive layer 250 can include an electrical insulating material which has adhesive properties and is capable of compression and decompression. For example, the adhesive layer 250 can include epoxy-based resin, acrylic-based resin, silicone-based resin, or urethane-based resin, but embodiments of the present disclosure are not limited thereto.

In the vibration generating apparatus 200, the plate member 150 (or the conductive substrate) of the display panel 100 can be used as a first driving electrode, and thus, one electrode can be omitted and a thickness can be slimmed by a thickness of one omitted electrode, thereby decreasing a thickness of a display apparatus.

The display apparatus can further include a supporting member 300 which is disposed at a rear surface of the display member 100 (or the plate member 150).

The supporting member 300 can be disposed on the rear surface of the display panel 100. For example, the supporting member 300 can cover the rear surface of the display panel 100 and the vibration generating apparatus 200. For example, the supporting member 300 can be provided to surround a lateral surface and the rear surface of the display panel 100.

The supporting member 300 can cover the entire rear surface of the display panel 100 with a gap space GS therebetween. The supporting member 300 can be spaced apart from a rearmost surface of the display panel 100 with the gap space GS therebetween, or can be spaced apart from the vibration generating apparatus 200. For example, the gap space GS can be referred to as an air gap, a vibration space, and a sound sounding box, but embodiments of the present disclosure are not limited to the terms.

The supporting member 300 can include one or more of a glass material, a metal material, and a plastic material. Fox example, the supporting member 300 can be a rear structure, a set structure, a supporting structure, a supporting cover, a back cover, a cover bottom, a rear member, a case, or a housing, but embodiments of the present disclosure are not limited to the terms. For example, the supporting member 300 can be implemented as an arbitrary type frame or a plate structure disposed on the rear surface of the display member 100.

The supporting member 300 can include a first supporting member 310 and a second supporting member 330.

The first supporting member 310 can be disposed between the display panel 100 and the second supporting member 330. For example, the first supporting member 310 can be disposed between a rear edge (or a rear periphery) of the display panel 100 and a front edge portion (or a front periphery portion) of the second supporting member 330. The first supporting member 310 can support one or more of an edge portion (or a periphery portion) of the display panel 100 and an edge portion (or a periphery portion) of the second supporting member 330. In another embodiment of the present disclosure, the first supporting member 310 can cover the rear surface of the display panel 100. For example, the first supporting member 310 can cover the entire rear surface of the display panel 100. For example, the first supporting member 310 can be a member which covers the entire rear surface of the display panel 100. For example, the first supporting member 310 can include one or more materials of a glass material, a metal material, and a plastic material. For example, the first supporting member 310 can be an inner plate, a first rear structure, a first supporting structure, a first supporting cover, a first back cover, a first rear member, an internal plate, or an internal cover, but the terms are not limited thereto. For example, the first supporting member 310 can be omitted.

The first supporting member 310 can be spaced apart from the rearmost surface of the display member 100 with the gap space GS therebetween, or can be spaced apart from the vibration generating apparatus 200.

The second supporting member 330 can be disposed on a rear surface of the first supporting member 310. The second supporting member 330 can be a member which covers the entire rear surface of the display panel 100. For example, the first supporting member 310 can be disposed between the rear surface of the display panel 100 and a front surface of the second supporting member 330. For example, the second supporting member 330 can include one or more of a glass material, a metal material, and a plastic material. For example, the second supporting member 330 can be an outer plate, a rear plate, a back plate, a back cover, a rear cover, a second rear structure, a second supporting structure, a second supporting cover, a second back cover, a second rear member, an external plate, or an external cover, but the terms are not limited thereto.

The supporting member 300 can further include a connection member 350 (or a coupling member).

The connection member 350 can be disposed between the first supporting member 310 and the second supporting member 330. For example, the first supporting member 310 and the second supporting member 330 can be coupled to or connected with each other by the connection member 350. For example, the connection member 350 can be an adhesive, an adhesive resin, a double-sided tape, a double-sided foam tape, a double-sided foam pad, or a double-sided adhesive foam pad, but embodiments of the present disclosure are not limited thereto. For example, the connection member 350 can have elasticity for absorbing an impact, but embodiments of the present disclosure are not limited thereto. For example, the connection member 350 can be disposed in an entire region between the first supporting member 310 and the second supporting member 350. According to another embodiment of the present disclosure, the connection member 350 can be formed in a mesh structure having an air gap between the first supporting member 310 and the second supporting member 330.

The display apparatus can further include a middle frame 400.

The middle frame 400 can be disposed between a rear periphery of the display panel 100 and a front periphery portion of the supporting member 300. The middle frame 400 can support one or more of a rear periphery portion of the display panel 100 and a front periphery portion of the supporting member 300. The middle frame 400 can surround one or more of lateral surfaces of each of the display panel 100 and the supporting member 300. The middle frame 400 can provide the air space GS between the display panel 100 and the supporting member 300. The middle frame 400 can be referred to as a middle cabinet, a middle cover, a middle chassis, a connection member, a frame, a frame member, or a lateral cover member, but embodiments of the present disclosure are not limited to the terms.

The middle frame 400 can include a first supporting part 410 and a second supporting part 430. For example, the second supporting part 430 can be a sidewall part, but embodiments of the present disclosure are not limited to the terms.

The first supporting part 410 can be disposed between the rear edge (or the rear periphery) of the display panel 100 and the front edge (or the front periphery) of the supporting member 300, and thus, can provide a gap space GS between the display panel 100 and the supporting member 300. A front surface of the first supporting part 410 can be coupled to or connected with the rear edge portion (or the rear periphery portion) of the display panel 100 by a first connection member 401. A rear surface of the first supporting part 410 can be coupled to the front edge (or the front periphery) of the supporting member 300 by a second connection member 403. For example, the first supporting part 410 can have a single tetragonal picture frame structure, or can include a picture frame structure having a plurality of division bar shapes, but embodiments of the present disclosure are not limited thereto.

The second supporting part 430 can be arranged in parallel with the thickness direction Z of the display apparatus or the display panel 100. For example, the second supporting part 430 can be vertically coupled to (or connected to) an outer surface of the first supporting part 410 in parallel with the thickness direction Z of the display panel 100. The second supporting part 430 can surround one or more of an outer surface of the display panel 100 and an outer surface of the supporting member 300, thereby protecting the outer surface of each of the display panel 100 and the supporting member 300. The first supporting part 410 can protrude from an inner surface of the second supporting part 430 to the gap space GS between the display panel 100 and the supporting member 300.

The display apparatus, as illustrated in FIG. 25, can include a panel connection member (or a connection member) 450 instead of the middle frame 400.

Referring to FIG. 25, the panel connection member 450 can be disposed between the rear periphery portion of the display member 100 and the front periphery portion of the supporting member 300, and thus, can provide a gap space GS between the display member 100 and the supporting member 300. The panel connection member 450 can be disposed between the rear periphery portion of the display member 100 and the front periphery portion of the supporting member 300, and thus, can be attached on (or coupled to) the display member 100 on the supporting member 300. For example, the panel connection member 450 can be implemented with a double-sided tape, a single-sided tape, or a double-sided foam tape, but embodiments of the present disclosure are not limited thereto. For example, an adhesive layer of the panel connection member 450 can include epoxy-based adhesive material, acryl-based adhesive material, silicone-based adhesive material, or urethane-based adhesive material, but embodiments of the present disclosure are not limited thereto. For example, to minimize the transfer of a vibration of the display member 100 to the supporting member 300, the adhesive layer of the panel connection member 450 can include a urethane-based material, having a relatively ductile characteristic, compared to acryl-based material. Accordingly, a vibration loss of the display panel 100 caused by a vibration transferred to the supporting member 300 from the display panel 100 can be minimized.

In the display apparatus, in a case where the panel connection member 450 is provided instead of the middle frame 400, the supporting member 300 can include a bending sidewall which is bent from one side (or an end or one portion) of the second supporting member 330 to surround one or more of outer surfaces (or outer sidewalls) of the display panel 100. The bending sidewall can have a single sidewall structure or a hemming structure. The hemming structure can be a structure where an end portion of an arbitrary member is bent in a curved shape and overlaps or is spaced apart from another portion in parallel. For example, to enhance a sense of beauty of a lateral surface in design, the bending sidewall can include a first bending sidewall which is bent from one side (or an end or one portion) of the second supporting member 330 and a second bending sidewall which is bent from the first bending sidewall to a region between the first bending sidewall and an outer surface of the display member 100. The second bending sidewall can contact an inner surface of the first bending sidewall, or can be spaced apart from an inner surface of the first bending sidewall. Accordingly, the second bending sidewall can prevent that the outer surface of the display member 100 contacts the inner surface of the first bending sidewall. And/or, the second bending sidewall may reduce or prevent that an external impact in a lateral direction is transferred to the outer surface of the display member 100.

The display apparatus can generate a vibration sound and/or a sound from a vibration of the display panel 100 based on a vibration of the vibration generating apparatus 200 provided on the plate member 150 (or the conductive substrate) of the display panel 100, and thus, can output a sound in a forward direction FD of the display panel 100. Further, the plate member 150 (or the conductive substrate) of the display panel 100 can protect the display part 130 from an external impact and can be used as an electrode of the vibration generating apparatus 200, and thus, the display apparatus can be reduced in thickness or slimmed based on a reduction in thickness of the vibration generating apparatus 200. Accordingly, the display apparatus can output a sound in the forward direction FD of the display panel 100 and can be slimmed.

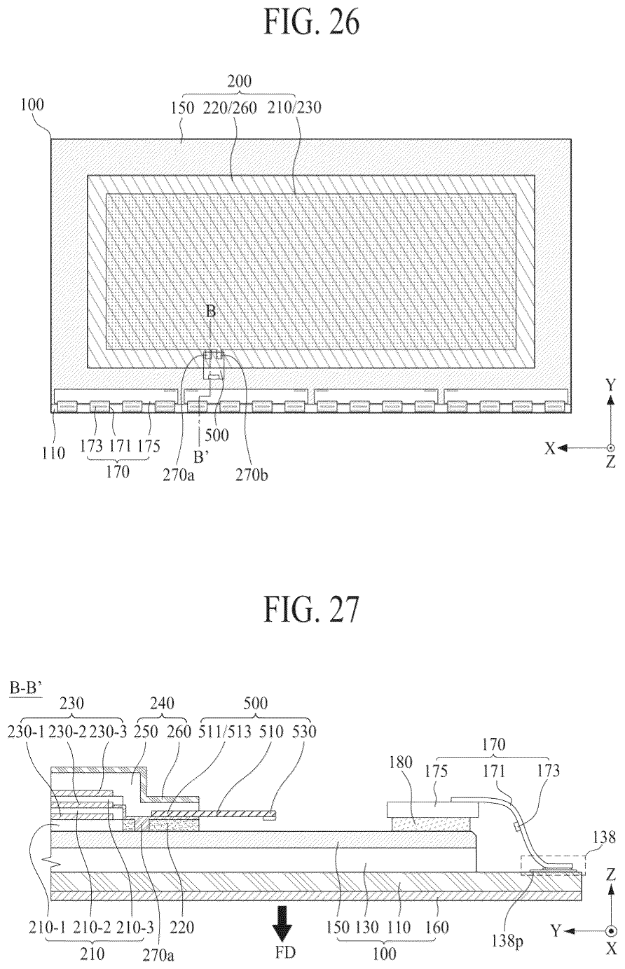

FIG. 26 illustrates a rear surface of a display panel and a vibration generating apparatus, in a display apparatus according to embodiments. FIG. 27 is a cross-sectional view taken along line B-B′ in FIG. 26.

Referring to FIGS. 26 and 27, the display apparatus can further include a panel driving circuit 170 and a signal cable 500.

The panel driving circuit 170 can be electrically connected with a display panel 100. The panel driving circuit 170 can be disposed at a rear surface of the display panel 100 and can be electrically connected with a pad part 138 provided in the display panel 100.

The pad part 138 can be disposed at one side (or one portion) of the display panel 100. For example, the pad part 138 can be disposed at one periphery portion of the display panel 100. For example, the pad part 138 can include a plurality of pads 138p which are electrically connected with signal lines provided in the display panel 100.

The panel driving circuit 170 can include a plurality of flexible films 171, a plurality of data driving ICs 173, and one or more printed circuit boards (PCBs) 175.

Each of the plurality of flexible films 171 can be attached on the pad part 138 of the display panel 100 by a film attachment process. Each of the plurality of flexible films 171 can be attached on a rear surface of the display panel 100.

Each of the plurality of data driving ICs 173 can be individually mounted on a corresponding flexible film 171 of each of the plurality of flexible films 171. Each of the plurality of data driving ICs 173 can receive pixel data and a timing control signal supplied from a display control circuit, convert the pixel data into an analog pixel-based data signal according to the timing control signal, and output the data signal. The pixel-based data signal can be supplied to a data line of the display part 130 through the flexible film 171 and the pad part 138.

The one or more PCBs 175 can be connected with the plurality of flexible films 171 and can be disposed at the rear surface of the display panel 100. For example, the one or more PCBs 175 can be disposed to overlap one rear periphery portion of the display panel 100, or can be disposed to overlap a plate member 150 (or a conductive substrate). The one or more PCBs 175 can be configured to transfer a signal and power between the elements of the panel driving circuit 170. For example, the one or more PCBs 175 can be connected with (or attached on) a second surface (or a rear surface) 150a of the plate member 150 (or the conductive substrate) by a buffer member 180. The buffer member 180 can include a material which prevents or minimizes the transfer of a vibration of the plate member 150 (or the conductive substrate) to the PCB 175, and thus, a noise caused by a vibration of the PCB 175 transferred from the plate member 150. For example, the buffer member 180 can be a double-sided tape or a double-sided cushion tape, but embodiments of the present disclosure are not limited thereto.

The display apparatus or the vibration generating apparatus 200 according to embodiments can further include at least one contact patterns 270a and 270b. For example, the at least one contact patterns 270a and 270b can include a first contact pattern 270a and a second contact pattern 270b.

The first contact pattern 270a can be connected with or coupled to the plate member 150 of the vibration generating apparatus 200 and some of the plurality of electrode layers 230. For example, the first contact pattern 270a can be connected or coupled to the plate member 150 (or the conductive substrate) and the second electrode layer 230-2 of the plurality of electrode layers 230. The first contact pattern 270a can be configured so that the plate member 150 and the second electrode layer 230-2 are electrically connected with (or contact) each other. Further, the first contact pattern 270a can be supplied with the first driving signal from the outside and can apply or transfer the first driving signal to the plate member 150 and the second electrode layer 230-2. The first contact pattern 270a can extend from the plate member 150 and the plurality of electrode layers 230 and can be exposed at the outside. For example, the first contact pattern 270a connected with the plate member 150 can extend or protrude from a portion of the plate member 150. For example, the first contact pattern 270a connected with the plate member 150 can be exposed at the outside through a removed portion of a portion of the insulation layer 220. Further, the first contact pattern 270a connected with the second electrode layer 230-2 of the plurality of electrode layers 230 can extend or protrude from a portion of the second electrode layer 230-2. For example, the first contact pattern 270a connected with the second electrode layer 230-2 of the plurality of electrode layers 230 can extend from a portion of the second electrode layer 230-2 to the second vibration layer 210-2 and can be exposed at the outside. One end (or one side or one portion) of the first contact pattern 270a can be connected with each of the plate member 150 and the second electrode layer 230-2, and the other end (or the other side or the other portion) of the first contact pattern 270a can extend to or be disposed on the insulation layer 220 from a lateral surface of the plurality of vibration layers 230.

The second contact pattern 270b can be connected with or coupled to the other some of the plurality of electrode layers 230 of the vibration generating apparatus 200. For example, the second contact pattern 270b can be connected or coupled to the first electrode layer 230-1 and the third electrode layer 230-3 of the plurality of electrode layers 230. The second contact pattern 270b can be configured so that the first electrode layer 230-1 and the third electrode layer 230-3 are electrically connected with (or contact) each other.

Also, the second contact pattern 270b may be supplied with the second driving signal from the outside and can apply or transfer the second driving signal to the first electrode layer 230-1 and the third electrode layer 230-3. The second contact pattern 270b can extend from the first electrode layer 230-1 and the third electrode layer 230-3 and can be exposed at the outside. For example, the second contact pattern 270b connected with the first electrode layer 230-1 can extend or protrude from a portion of the first electrode layer 230-1. For example, the second contact pattern 270b connected with the first electrode layer 230-1 can extend from a portion of the first electrode layer 230-1 to the first vibration layer 210-1 and can be exposed at the outside. Further, the second contact pattern 270b connected with the third electrode layer 230-3 can extend or protrude from a portion of the third electrode layer 230-3. For example, the second contact pattern 270b connected with the third electrode layer 230-3 can extend from a portion of the third electrode layer 230-3 to the third vibration layer 210-3 and can be exposed at the outside. One end (or one side or one portion) of the second contact pattern 270b can be connected with each of the first electrode layer 230-1 and the third electrode layer 230-3, and the other end (or the other side or the other portion) of the second contact pattern 270b can extend to or be disposed on the insulation layer 220 from the lateral surface of the plurality of vibration layers 230.

The signal cable 500 can be disposed at the rear surface of the display panel 100 so as to be electrically connected with the vibration generating apparatus 200. For example, the signal cable 500 can be configured to be electrically connected with the plate member 150 (or the conductive substrate) of the display panel 100 and the vibration generating apparatus 200. For example, the signal cable 500 can be configured to be electrically connected with the plate member 150 of the vibration generating apparatus 200 and the plurality of electrode layers 230. For example, the signal cable 500 can be configured to be electrically connected with the first contact pattern 270a (or a first driving electrode) connected with the plate member 150 and some of the plurality of electrode layers 230 and the second contact pattern 270b (or a second driving electrode) connected with the other some of the plurality of electrode layers 230. Also, the second contact pattern 270b can be connected with or coupled to the first electrode layer 230-1 and the third electrode layer 230-3 of the plurality of electrode layers 230. For example, the first contact pattern 27a and the second contact pattern 27b may not overlap each other. Further, the first contact pattern 27a and the second contact pattern 27b may not be connected with each other.

The signal cable 500 can be provided as one body with the vibration generating apparatus 200. For example, a portion of the signal cable 500 can be inserted (or accommodated) into the adhesive layer 250 between the plate member 150 and the cover member 260, and thus, can be provided as one body with the vibration generating apparatus 200. Accordingly, the vibration generating apparatus 200 can vibrate based on signals applied from the plate member 150 and the signal cable 500.

The signal cable 500 according to embodiments can include a line part 510, a first contact line 511, a second contact line 513, and a terminal part 530.

The line part 510 can be disposed at the rear surface of the display panel 100. A portion or one periphery portion of the line part 510 can be inserted (or accommodated) into the vibration generating apparatus 200, or can be provided as one body with the vibration generating apparatus 200. For example, the portion or one periphery portion of the line part 510 can be covered by the cover member 260 of the vibration generating apparatus 200. For example, the portion or one periphery portion of the line part 510 can be inserted (or accommodated) into the adhesive layer 250 of the vibration generating apparatus 200, and thus, can be fixed to the vibration generating apparatus 200 or can be provided as one body with the vibration generating apparatus 200. Accordingly, a connection defect between the vibration generating apparatus 200 and the signal cable 500 caused by the movement or bending of the signal cable 500 can be minimized.

The line part 510 can include a base film, a line layer including first and second signal lines formed at the base film, and an insulation layer covering the line layer.

A first contact line 511 can be configured to be electrically connected with (or contact) the first contact pattern 270a (or the first driving electrode) connected with some of the plurality of electrode layers 230 and the plate member 150 of the vibration generating apparatus 200. For example, the first contact line 511 can be a portion of the first signal line exposed at one periphery portion of the line part 510, or can be a first finger line (or a first protrusion signal line) which extends (or protrudes) to have a certain length from the first signal line of the line part 510. The first contact line 511 can be electrically connected with (or contact) or electrically and directly connected with (or contact) the first contact pattern 270a of the vibration generating apparatus 200. Alternatively, the first contact line 511 can be electrically connected with (or contact) the first contact pattern 270a of the vibration generating apparatus 200 by a conductive double-sided tape or an anisotropic conductive film. The first contact line 511 can be covered by the cover member 260 of the vibration generating apparatus 200, and thus, can be fixed to or provided as one body with the vibration generating apparatus 200. Accordingly, a connection defect between the vibration generating apparatus 200 and the signal cable 500 caused by the movement or bending of the signal cable 500 which is caused by a manufacturing process attaching the line part 510 to the first and second contact patterns 270a and 270b can be minimized.

The vibration generating apparatus 200 can use the plate member 150 (or the conductive substrate) of the display panel 100 as an electrode, and thus, a contact portion (or a contact region) between the first contact line 511 and the plate member 150 (or the conductive substrate) is not limited to a specific position of the second surface 150a of the plate member 150 (or the conductive substrate). For example, the contact portion (or the contact region) between the first contact line 511 and the plate member 150 (or the conductive substrate) can be adjacent to the plurality of vibration layers 210 or the second contact pattern 270b of the vibration generating apparatus 200, and thus, a length of the signal cable 500 can be reduced or minimized.

A second contact line 513 can be configured to be electrically connected with (or contact) the second contact pattern 270b (or the second driving electrode) connected with the other some of the plurality of electrode layers 230 of the vibration generating apparatus 200. The second contact line 513 can be a portion of the second signal line exposed at one periphery portion of the line part 510, or can be a second finger line (or a second protrusion signal line) which extends (or protrudes) to have a certain length from the second signal line of the line part 510. The second contact line 513 can be electrically connected with (or contact) or electrically and directly connected with (or contact) the second contact pattern 270b of the vibration generating apparatus 200. Alternatively, the second contact line 513 can be electrically connected with (or contact) the second contact pattern 270b of the vibration generating apparatus 200 by a conductive double-sided tape or an anisotropic conductive film. The second contact line 513 can be covered by the cover member 260 of the vibration generating apparatus 200, and thus, can be fixed to or provided as one body with the vibration generating apparatus 200. Accordingly, a connection defect between the vibration generating apparatus 200 and the signal cable 500 caused by the movement or bending of the signal cable 500 which is caused by a manufacturing process attaching the line part 510 to the first and second contact patterns 270a and 270b can be minimized.

The terminal part 530 can be provided at the other periphery portion of the line part 510. The terminal part 530 can be provided to expose a portion of each of the first and second signal lines disposed at the other periphery portion of the line part 510. For example, the terminal part 530 can be electrically connected with a vibration driving signal (or a sound processing circuit), or can include a connector which is electrically connected with the vibration driving signal (or the sound processing circuit).

The signal cable 500 can be electrically coupled to the first contact pattern 270a and the second contact pattern 270b, and thus, can apply or transfer the first and second vibration driving signals, supplied from the vibration driving signal (or the sound processing circuit), to the first contact pattern 270a and the second contact pattern 270b of the vibration generating apparatus 200 through the terminal part 530. For example, the first vibration driving signal can be applied or transferred to the plate member 150 (or the conductive substrate) and the second electrode layer 230-2 of the plurality of electrode layers 230 through the first contact pattern 270a. Further, the second vibration driving signal can be applied or transferred to the first electrode layer 230-1 and the third electrode layer 230-3 of the plurality of electrode layers 230 through the second contact pattern 270b.

The vibration generating apparatus 200 according to embodiments can vibrate based on first and second vibration driving signals (or sound signals) applied to, through the signal cable 500, the plate member 150 (or the conductive substrate) and the second electrode layer 230-2 connected with the plurality of first contact patterns 270a and the first electrode layer 230-1 and the third electrode layer 230-3 connected with the plurality of second contact patterns 270b, and thus, can vibrate the plate member 150 or the display panel 100.

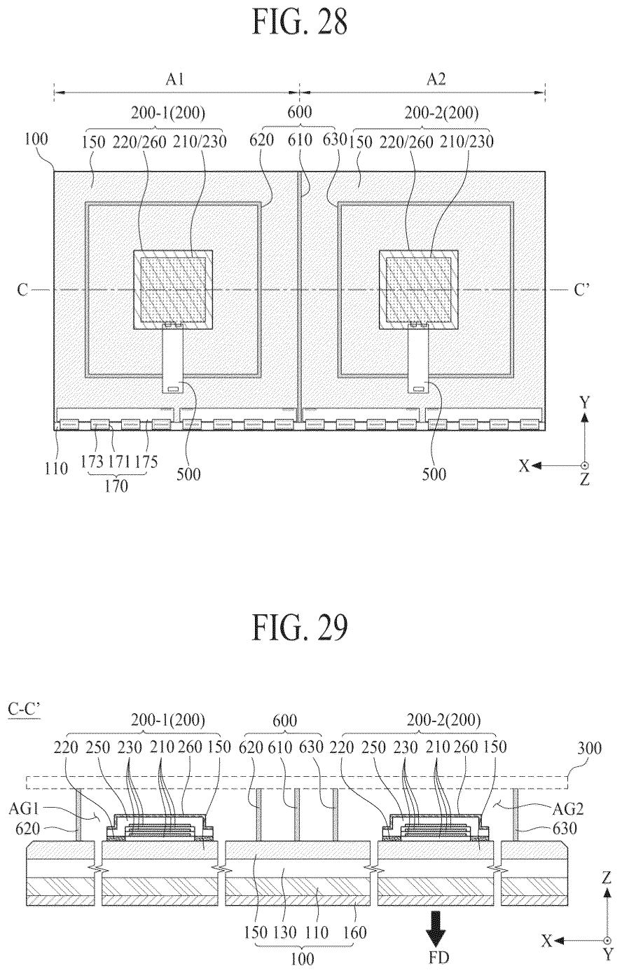

FIG. 28 illustrates a display apparatus according to another embodiment of the present disclosure. FIG. 29 is a cross-sectional view taken along line C-C′ in FIG. 28. FIGS. 28 and 29 illustrate an embodiment implemented by modifying the vibration generating apparatus described above with reference to FIGS. 22 to 27. In the following description, therefore, a modified element will be described in detail, the other elements are referred to by the same reference numerals as FIGS. 22 to 27, and repeated descriptions thereof may be omitted or will be briefly given.

Referring to FIGS. 28 and 29, a vibration generating apparatus 200 can include a plurality of vibration generating apparatuses 200-1 and 200-2. For example, the vibration generating apparatus 200 can include a first vibration generating apparatus 200-1 and a second vibration generating apparatus 200-2.

The first vibration generating apparatus 200-1 can be provided in a first region A1 of a display panel 100. For example, the first region A1 of the display panel 100 can be a first rear region, a left region, a left region of a rear surface of the display panel 100, or a rear left region. The first vibration generating apparatus 200-1 can be configured to have a size (or an area) which is less than that of the first region A1 of the display panel 100. For example, the first vibration generating apparatus 200-1 can be provided to have a square shape in the first region A1 of the display panel 100, but embodiments of the present disclosure are not limited thereto. Except for that the first vibration generating apparatus 200-1 is provided in the first region A1 of the display panel 100, the first vibration generating apparatus 200-1 can be configured to be equal to the vibration generating apparatus 200 described above with reference to FIGS. 22 to 27. For example, the first vibration generating apparatus 200-1 can use a plate member 150 (or a conductive substrate) of the display panel 100 as an electrode (or a first driving electrode) and can include a plurality of vibration layers 210 coupled to (or provided at) a portion of a first region A1 of the plate member 150 (or the conductive substrate), a plurality of electrode layers 230 respectively coupled to the plurality of vibration layers 210, and a cover member 260 covering the plurality of vibration layers 210 and the plurality of electrode layers 230, and thus, repeated descriptions thereof may be omitted.

The first vibration generating apparatus 200-1 can vibrate based on a signal applied through the plate member 150 (or the conductive substrate) and a signal cable (or a first signal cable) 500, and thus, can vibrate the first region A1 of the display panel 100. For example, the first vibration generating apparatus 200-1 can vibrate based on first and second vibration driving signals (or sound signals) applied to a first contact pattern 270a and a second contact pattern 270b through the signal cable 500, and thus, can vibrate the plate member 150 or the first region A1 of the display panel 100. For example, the plate member 150 or the first region A1 of the display panel 100 can vibrate based on a vibration of the first vibration generating apparatus 200-1 to generate a first sound (or a first haptic feedback) or a left or right sound (or a left or right haptic feedback), and thus, the first sound (or the left sound) can be output in a forward direction of the display panel 100.

The second vibration generating apparatus 200-2 can be provided in a second region A2 of a display panel 100. For example, the second region A2 of the display panel 100 can be a second rear region, a right region, a right region of a rear surface of the display panel 100, or a rear right region. The second vibration generating apparatus 200-2 can be configured to have a size (or an area) which is less than that of the second region A2 of the display panel 100. For example, the second vibration generating apparatus 200-2 can be provided to have a square shape in the second region A2 of the display panel 100, but embodiments of the present disclosure are not limited thereto. Except for that the second vibration generating apparatus 200-2 is provided in the second region A2 of the display panel 100, the second vibration generating apparatus 200-2 can be configured to be equivalent to the vibration generating apparatus 200 described above with reference to FIGS. 22 to 27. For example, the second vibration generating apparatus 200-2 can use a plate member 150 (or a conductive substrate) of the display panel 100 as an electrode (or a first driving electrode) and can include a plurality of vibration layers 210 coupled to (or provided at) a portion of a second region A2 of the plate member 150 (or the conductive substrate), a plurality of electrode layers 230 respectively coupled to (or connected to) the plurality of vibration layers 210, and a cover member 260 covering the plurality of vibration layers 210 and the plurality of electrode layers 230, and thus, repeated descriptions thereof may be omitted.

The second vibration generating apparatus 200-2 can vibrate based on a signal applied through the plate member 150 (or the conductive substrate) and a signal cable (or a second signal cable) 500, and thus, can vibrate the second region A2 of the display panel 100. For example, the second vibration generating apparatus 200-2 can vibrate based on first and second vibration driving signals (or sound signals) applied to a first contact pattern 270a and a second contact pattern 270b through the signal cable 500, and thus, can vibrate the plate member 150 or the second region A2 of the display panel 100. For example, the plate member 150 or the second region A2 of the display panel 100 can vibrate based on a vibration of the second vibration generating apparatus 200-2 to generate a second sound (or a second haptic feedback) or a left or right sound (or a left or right haptic feedback), and thus, the second sound (or the right sound) can be output in a forward direction of the display panel 100.

The plate member 150 of the display panel 100 can be used as a driving electrode of each of the first vibration generating apparatus 200-1 and the second vibration generating apparatus 200-2 and can be supplied with the first vibration driving signal through a first signal line of the signal cable 500 connected with each of the first vibration generating apparatus 200-1 and the second vibration generating apparatus 200-2. For example, the first vibration driving signal can be a first sound signal, a common sound signal, a lower electrode signal, a common electrode signal, or a negative vibration signal.

The first vibration generating apparatus 200-1 and the second vibration generating apparatus 200-2 can be provided to be horizontally symmetric with each other with respect to a center (or a partition member 610) between the first region A1 and a second region A2 of the display panel 100, but embodiments of the present disclosure are not limited thereto, and can be provided to be horizontally asymmetric with each other.

The display apparatus can further include a partition 600 which divides the first region A1 and a second region A2 of the display panel 100.

The partition 600 can be an air gap or a space where a sound is generated when the display panel 100 is vibrated by the first and second vibration generating apparatuses 200-1 and 200-2. For example, the partition 600 can separate a sound or can separate a channel, and moreover, can prevent or decrease a reduction in characteristic of a sound caused by interference of the sound. The partition 600 can be disposed between the display panel 100 and a supporting member 300. For example, the partition 600 can be disposed between a rear surface of the display panel 100 and a front surface of the supporting member 300. To decrease an adverse effect of the partition 600 on the image quality of the display panel 100, the partition 600 can be disposed in the supporting member 300. The partition 600 can be referred to as a sound blocking member, a sound separation member, a space separation member, an enclosure, or a baffle, but embodiments of the present disclosure are not limited to the terms.

The partition 600 can include a partition member (or a first partition member) 610 disposed between the first and second vibration generating apparatuses 200-1 and 200-2.

The partition member 610 can be disposed between the first region A1 and the second region A2 of the display panel 100. The partition member 610 can be disposed between the first region A1 and the second region A2 of a rear surface of the display panel 100. The partition member 610 can be disposed between the supporting member 300 and the plate member 150 (or the conductive substrate) of the display panel 100 between the first region A1 and the second region A2 of the display panel 100. For example, the partition member 610 can be disposed between the supporting member 300 and a rear surface of the plate member 150 (or the conductive substrate) between the first region A1 and the second region A2 of the display panel 100. The partition member 610 can separate a first sound generated by the first vibration generating apparatus 200-1 and a second sound generated by the second vibration generating apparatus 200-2. For example, the partition member 610 can prevent a vibration, generated in the first region A1 of the display panel 100 by the first vibration generating apparatus 200-1, from being transferred to the second region A2 of the display panel 100, or can prevent a vibration, generated in the second region A2 of the display panel 100 by the second vibration generating apparatus 200-2, from being transferred to the first region A1 of the display panel 100. Therefore, the partition member 610 can attenuate or absorb a vibration of the display panel 100 at a center of the display panel 100, and thus, can prevent a sound of the first region A1 from being transferred to the second region A2 or can prevent a sound of the second region A2 from being transferred to the first region A1. Accordingly, the partition member 610 can separate a left sound and a right sound to further enhance a sound output characteristic of the display apparatus, and thus, the display apparatus according to embodiments can output a 2-channel sound and/or a stereo sound, including a 2-channel, in a forward direction of the display panel 100 based on the separation of the left and right sounds by the partition member 610.

The partition 600 can include a second partition member 620 surrounding the first vibration generating apparatus 200-1 and a third partition member 630 surrounding the second vibration generating apparatus 200-2.

The second partition member 620 can be disposed between the first region A1 of the display panel 100 and the supporting member 300 to surround the first vibration generating apparatus 200-1. The second partition member 620 can be disposed between the first region A1 of the display panel 100 and the supporting member 300 so as to be spaced apart from the first vibration generating apparatus 200-1 by a certain distance. The second partition member 620 can provide a first air gap AG1 surrounding the first vibration generating apparatus 200-1 between the display panel 100 and the supporting member 300. For example, the second partition member 620 can be disposed between the supporting member 300 and the first region A1 of the plate member 150 corresponding to the first region A1 of the display panel 100. For example, the second partition member 620 can define or limit a vibration region (or a vibration area) of the first region A1 of the display panel 100 by the first vibration generating apparatus 200-1.

The third partition member 630 can be disposed between the second region A2 of the display panel 100 and the supporting member 300 to surround the second vibration generating apparatus 200-2. The third partition member 630 can be disposed between the second region A2 of the display panel 100 and the supporting member 300 so as to be spaced apart from the second vibration generating apparatus 200-2 by a certain distance. The third partition member 630 can provide a second air gap AG2 surrounding the second vibration generating apparatus 200-2 between the display panel 100 and the supporting member 300. For example, the third partition member 630 can be disposed between the supporting member 300 and the second region A2 of the plate member 150 corresponding to the second region A2 of the display panel 100. For example, the third partition member 630 can define or limit a vibration region (or a vibration area) of the second region A2 of the display panel 100 by the second vibration generating apparatus 200-2.

The first air gap AG1 and a second air gap AG2 can each be a sound separation space, a sound blocking space, or a sound interference prevention space, but embodiments of the present disclosure are not limited thereto.

The second and third partition members 620 and 630 can separate the first sound generated by the first vibration generating apparatus 200-1 and the second sound generated by the second vibration generating apparatus 200-2. For example, the second and third partition members 620 and 630 can prevent a vibration, generated in the first region A1 of the display panel 100 by the first vibration generating apparatus 200-1, from being transferred to the second region A2 of the display panel 100, or can prevent a vibration, generated in the second region A2 of the display panel 100 by the second vibration generating apparatus 200-2, from being transferred to the first region A1 of the display panel 100. Therefore, the second and third partition members 620 and 630 can attenuate or absorb a vibration of the display panel 100 at a center of the display panel 100, and thus, can prevent a sound of the first region A1 from being transferred to the second region A2 or can prevent a sound of the second region A2 from being transferred to the first region A1. Accordingly, the second and third partition members 620 and 630 can separate a left sound and a right sound to further enhance a sound output characteristic of the display apparatus, and thus, the display apparatus can output a 2-channel sound and/or a stereo sound, including a 2-channel, in the forward direction of the display panel 100 based on the separation of the left and right sounds by the second and third partition members 620 and 630.

The partition 600, the partition member 610, and the second and third partition members 620 and 630 can include a material having elasticity, which is capable of being compressed to certain degree, but embodiments of the present disclosure are not limited thereto. Each of the partition 600, the partition member 610, and the second and third partition members 620 and 630 can include polyurethane or polyolefin, but embodiments of the present disclosure are not limited thereto. Each of the partition 600, the partition member 610, and the second and third partition members 620 and 630 can include an adhesive, a single-sided adhesive, a double-sided adhesive, a single-sided tape, a single-sided foam tape, a double-sided tape, or a double-sided foam tape, but embodiments of the present disclosure are not limited thereto.

In some embodiments, only one or two of the partition member 610 and the second and third partition members 620 and 630 can be provided. In this case, one or two of the partition member 610 and the second and third partition members 620 and 630 can be disposed between the first vibration generating apparatus 200-1 and the second vibration generating apparatus 200-2, and thus, can separate a left sound and a right sound.

Therefore, because a left sound and a right sound are separated from each other by one or more of the partition member 610 and the second and third partition members 620 and 630, a sound output characteristic of the display apparatus can be further enhanced, and based on the separation of the left sound and the right sound, a stereo sound including a 2-channel and/or a 2-channel sound can be output in the forward direction of the display panel 100.

The display apparatus described above with reference to FIGS. 22 to 27 can output a sound in a forward direction FD of the display panel 100, and a thickness of the display apparatus can be reduced or slimmed. Further, the display apparatus can output a stereo sound including a 2-channel and/or a 2-channel sound in the forward direction of the display panel 100, based on left and right separation vibrations of the display panel 100 based on vibrations of the first and second vibration generating apparatuses 200-1 and 200-2.

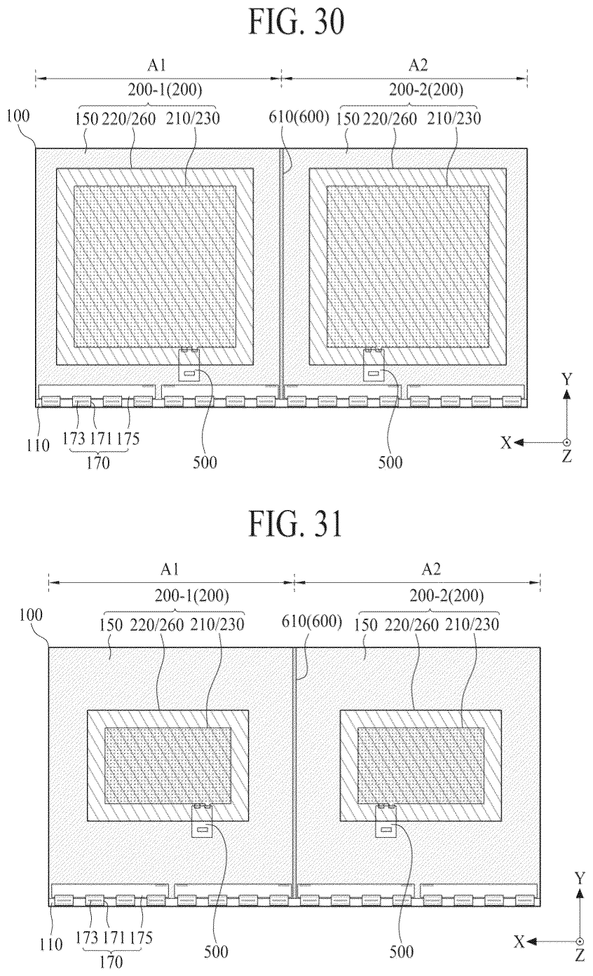

FIGS. 30 to 32 illustrate a display apparatus according to another embodiment. FIGS. 30 to 32 illustrate an embodiment implemented by modifying the vibration generating apparatus described above with reference to FIGS. 28 and 29. In the following description, therefore, a modified element will be described in detail, the other elements are referred to by the same reference numerals as FIGS. 28 and 29, and repeated descriptions thereof may be omitted or will be briefly given.

Referring to FIG. 30a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, a plurality of vibration layers 210 can be configured to have a size (or an area) which is less than that of the first region A1 of the display panel 100 and is greater than half of the first region A1 of the display panel 100. For example, in the first region A1 of the display panel 100, the first vibration generating apparatus 200-1 can be provided to have a square shape having a size (or an area) which is greater than half of the first region A1 and is less than a total size of the first region A1, but embodiments of the present disclosure are not limited thereto. Therefore, a sound of a middle-low pitched sound band generated based on a vibration of the first region A1 of the display panel 100 can be enhanced. For example, a plurality of vibration layers 210 of the first vibration generating apparatus 200-1 can be molded after being formed or coated in a square shape on a second surface of a plate member 150 (or a conductive substrate) corresponding to the first region A1 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, a plurality of vibration layers 210 can be configured to have a size (or an area) which is less than that of the second region A2 of the display panel 100 and is greater than half of the second region A2 of the display panel 100. For example, in the second region A2 of the display panel 100, the second vibration generating apparatus 200-2 can be provided to have a square shape having a size (or an area) which is greater than half of the second region A2 and is less than a total size of the second region A2, but embodiments of the present disclosure are not limited thereto. Therefore, a sound of a middle-low pitched sound band generated based on a vibration of the second region A2 of the display panel 100 can be enhanced. For example, a plurality of vibration layers 210 of the second vibration generating apparatus 200-2 can be molded after being formed or coated in a square shape on a second surface of a plate member 150 (or a conductive substrate) corresponding to the second region A2 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but are not limited thereto and can be provided to be horizontally asymmetric with each other.

Referring to FIG. 31a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, a plurality of vibration layers 210 can be configured to have a rectangular shape having a size (or an area) which is less than or equal to half of the first region A1 of the display panel 100, but embodiments of the present disclosure are not limited thereto and the plurality of vibration layers 210 can be provided to have a rectangular shape having a size (or an area) which is greater than half of the first region A1 and is less than a total size of the first region A1. Therefore, a sound of a middle-low pitched sound band generated based on a vibration of the first region A1 of the display panel 100 can be enhanced. For example, a plurality of vibration layers 210 of the first vibration generating apparatus 200-1 can be molded after being formed or coated in a rectangular shape on a second surface of a plate member 150 (or a conductive substrate) corresponding to the first region A1 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, a plurality of vibration layers 210 can be configured to have a rectangular shape having a size (or an area) which is less than or equal to half of the second region A2 of the display panel 100, but embodiments of the present disclosure are not limited thereto and the plurality of vibration layers 210 can be provided to have a rectangular shape having a size (or an area) which is greater than half of the second region A2 and is less than a total size of the second region A2. Therefore, a sound of a middle-low pitched sound band generated based on a vibration of the second region A2 of the display panel 100 can be enhanced. For example, a plurality of vibration layers 210 of the second vibration generating apparatus 200-2 can be molded after being formed or coated in a rectangular shape on a second surface of a plate member 150 (or a conductive substrate) corresponding to the second region A2 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The plurality of vibration layers 210 of each of the first vibration generating apparatus 200-1 and the second vibration generating apparatus 200-2 can have a rectangular shape which includes a long side parallel to a first direction X (for example, a horizontal length direction of the display panel 100) and a short side parallel to a second direction Y (for example, a vertical length direction of the display panel 100) intersecting with the first direction X.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but are not limited thereto and can be provided to be horizontally asymmetric with each other.

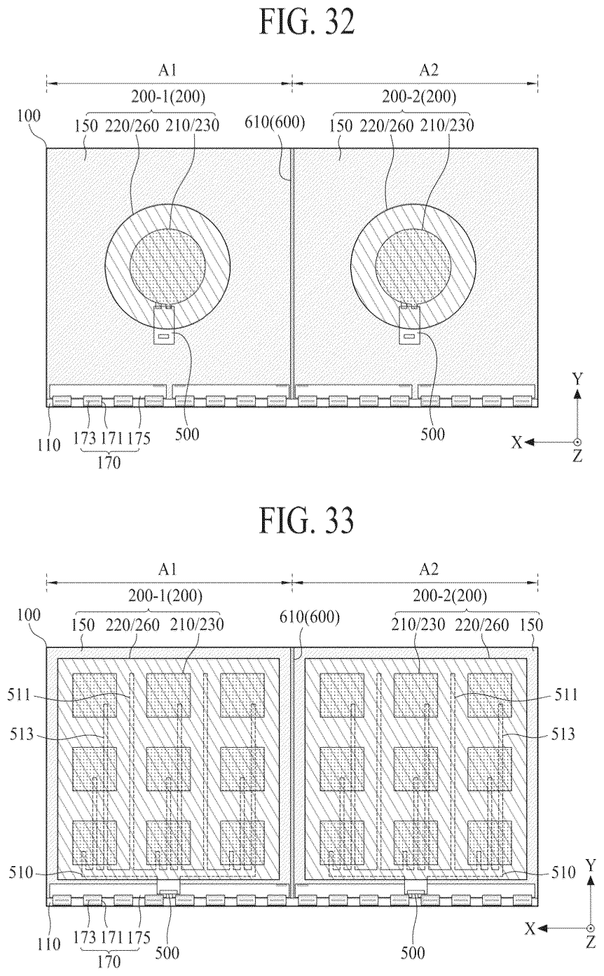

Referring to FIG. 32, in the display apparatus according to another embodiment of the present disclosure, a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, a plurality of vibration layers 210 can be configured to have a circular shape having a size (or an area) which is less than or equal to half of the first region A1 of the display panel 100, but embodiments of the present disclosure are not limited thereto, and the plurality of vibration layers 210 can be provided to have a circular shape having a size (or an area) which is greater than half of the first region A1 and is less than a total size of the first region A1. Therefore, the plurality of vibration layers 210 can configure a vibration source (or a vibrator) having a circular shape, and thus, a vibration characteristic or a sound output characteristic can be enhanced and a sound of a middle-low pitched sound band generated based on a vibration of the first region A1 of the display panel 100 can be enhanced. For example, a plurality of vibration layers 210 of the first vibration generating apparatus 200-1 can be molded after being formed or coated in a circular shape on a second surface of a plate member 150 (or a conductive substrate) corresponding to the first region A1 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, a plurality of vibration layers 210 can be configured to have a circular shape having a size (or an area) which is less than or equal to half of the second region A2 of the display panel 100, but embodiments of the present disclosure are not limited thereto and the plurality of vibration layers 210 can be provided to have a circular shape having a size (or an area) which is greater than half of the second region A2 and is less than a total size of the second region A2. Therefore, the plurality of vibration layers 210 can configure a vibration source (or a vibrator) having a circular shape, and thus, a vibration characteristic or a sound output characteristic can be enhanced and a sound of a middle-low pitched sound band generated based on a vibration of the second region A2 of the display panel 100 can be enhanced. For example, a plurality of vibration layers 210 of the second vibration generating apparatus 200-2 can be molded after being formed or coated in a circular shape on a second surface of a plate member 150 (or a conductive substrate) corresponding to the second region A2 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but are not limited thereto and can be provided to be horizontally asymmetric with each other.

FIG. 33 illustrates a display apparatus according to another embodiment of the present disclosure. FIG. 33 illustrated an embodiment implemented by modifying the vibration generating apparatus described above with reference to FIGS. 28 to 30. In the following description, therefore, a modified element will be described in detail, the other elements are referred to by the same reference numerals as FIGS. 28 to 30, and repeated descriptions thereof may be omitted or will be briefly given.

Referring to FIG. 33 a vibration generating apparatus 200 can include a first vibration generating apparatus 200-1 provided in a first region A1 of a display panel 100 and a second vibration generating apparatus 200-2 provided in a second region A2 of the display panel 100.

Each of the first vibration generating apparatus 200-1 and the second vibration generating apparatus 200-2 can include a plurality of vibrator blocks configured with a plurality of vibration layers 210 and a plurality of electrode layers 230. Each of the first vibration generating apparatus 200-1 and the second vibration generating apparatus 200-2 can further include a cover member 260. Each of the first vibration generating apparatus 200-1 and the second vibration generating apparatus 200-2 can use a plate member 150 (or a conductive substrate) of the display panel 100 as a driving electrode.

In each of the first vibration generating apparatus 200-1 and the second vibration generating apparatus 200-2, the plurality of vibrator blocks configured with the plurality of vibration layers 210 and the plurality of electrode layers 230 can be arranged at a second surface of the plate member 150 (or the conductive substrate) of the display panel 100 to have a certain interval in a first direction X and a second direction Y. For example, the plurality of vibrator blocks can be provided in a lattice form having a certain interval in the first direction X and the second direction Y. For example, the plurality of vibrator blocks can be provided in an N*M form (where N and M can be the same or different natural numbers of 2 or more) having a certain interval in the first direction X and the second direction Y.

Each of the plurality of vibration layers 210 included in the plurality of vibrator blocks can include a three or more-angled polygonal shape, a non-tetragonal shape, a circular shape, or an oval shape, but embodiments of the present disclosure are not limited thereto (the shapes being of the vibration layers in planform or plan view). For example, one or more of the plurality of vibration layers 210 can have different shapes. In embodiments, each of the plurality of vibration layers 210 can have a square shape. In other embodiments, some of the plurality of vibration layers 210 can have a square shape, and the other vibration layers 210 can have a circular shape. In other embodiments, the plurality of vibrator blocks can be divided into first to third groups. A plurality of vibration layers 210 included in a vibrator block of the first group can have a square shape, a plurality of vibration layers 210 included in a vibrator block of the second group can have a rectangular shape, and a plurality of vibration layers 210 included in a vibrator block of the third group can have a circular shape. For example, when each of the first and second regions A1 and A2 of the display panel 100 includes a center region, a middle region, and a periphery region, the vibrator block of the first group can be provided in the center region, the vibrator block of the second group can be provided in the middle region, and the vibrator block of the third group can be provided in the periphery region, but embodiments of the present disclosure are not limited thereto. For example, a shape of a plurality of vibration layers 210 included in a vibrator block provided in each of the center region, the middle region, and the periphery region can be changed based on a sound characteristic and/or a sound pressure level characteristic of a display apparatus.

Each of the plurality of electrode layers 230 included in the plurality of vibrator blocks can be configured to have the same shape as that of a corresponding vibration layer 210 of the plurality of vibration layers 210. An insulation layer 220 can be provided to cover the plate member 150 (or the conductive substrate) at a periphery of the plurality of vibrator blocks. Further, the cover member 260 can be provided to cover the insulation layer 220, and the plurality of vibration layers 210 and the plurality of electrode layers 230 included in each of the plurality of vibrator blocks in common.

The signal cable 500 can include one or more first contact lines 511 and a plurality of second contact lines 513.

The one or more first contact lines 511 can be configured to be electrically connected with the plate member 150 (or the conductive substrate). For example, the one or more first contact lines 511 can be electrically coupled to (or connected to) a second surface of the plate member 150 (or the conductive substrate) exposed at the first region A1 of the display panel 100.

The signal cable 500 can include a plurality of first contact lines 511. For example, the signal cable 500 can include two first contact lines 511. The two first contact lines 511 can extend (or protrude) long from a line part 510 in the second direction Y and can be electrically coupled to (or connected to) the second surface of the plate member 150 (or the conductive substrate) in a region between two vibrator blocks adjacent to each other in the first direction X, and thus, a uniform first vibration driving signal can be applied to each of the plurality of vibrator blocks. In another embodiment of the present disclosure, the one or more first contact lines 511 can include a plurality of first contact lines 511. For example, the plurality of first contact lines 511 can be provided to be equal to the number of vibrator blocks and can be electrically coupled to (or connected to) each of the plurality of vibrator blocks. Each of the plurality of first contact lines 511 can extend (or protrude) long from the line part 510 in the second direction Y and can be electrically coupled to (or connected to) a corresponding vibrator block of the plurality of vibrator blocks.

The plurality of second contact lines 513 can be configured to be electrically connected with each of the plurality of vibrator blocks. Each of the plurality of second contact lines 513 can extend (or protrude) long from the line part 510 in the second direction Y and can be electrically coupled to (or connected to) a corresponding vibrator block of the plurality of vibrator blocks.

In each of the first vibration generating apparatus 200-1 and the second vibration generating apparatus 200-2, each of the plurality of vibrator blocks can identically vibrate or can independently (or individually) vibrate based on the same or different second vibration driving signals. For example, one or more of second vibration driving signals applied to the plurality of vibrator blocks can differ. Therefore, each of the first vibration generating apparatus 200-1 and the second vibration generating apparatus 200-2 can output a 2 or more-channel sound. For example, when all of the second vibration driving signals applied to the plurality of vibrator blocks differ, each of the first vibration generating apparatus 200-1 and the second vibration generating apparatus 200-2 can generate a sound of N*M (or N row*M column or N row M column) channels.

In a plurality of vibrator blocks arranged in a 3*3 form, 1*1^{st} to 1*3^{rd} vibrator blocks can configure a height channel, 2*1^{st} to 2*3^{rd} vibrator blocks can configure a center channel, and 3*1^{st} to 3*3^{rd} vibrator blocks can configure a bottom channel. Accordingly, each of the first vibration generating apparatus 200-1 and the second vibration generating apparatus 200-2 can generate a sound of 3 channels or horizontal 3 channels.

In a plurality of vibrator blocks arranged in a 3*3 form, 1*1^{st}, 2*1^{st}, and 3*1^{st} vibrator blocks can configure a left channel, 1*2^{nd}, 2*2^{nd}, and 3*2^{nd} vibrator blocks can configure a center channel, and 1*3^{rd}, 2*3^{rd}, and 3*3^{rd} vibrator blocks can configure a right channel. Accordingly, each of the first vibration generating apparatus 200-1 and the second vibration generating apparatus 200-2 can generate a sound of 3 channels or a sound of vertical 3 channels.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

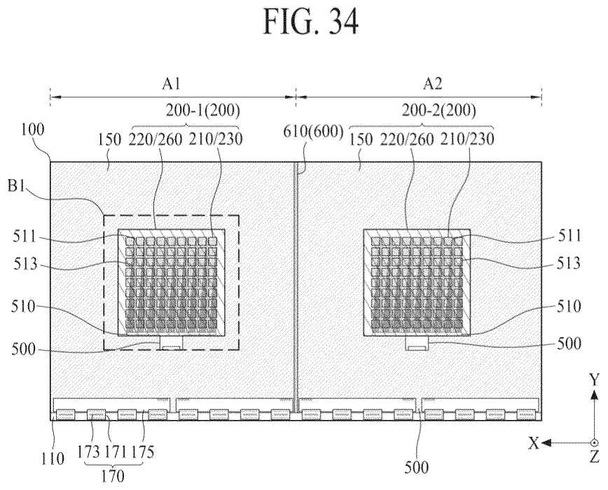

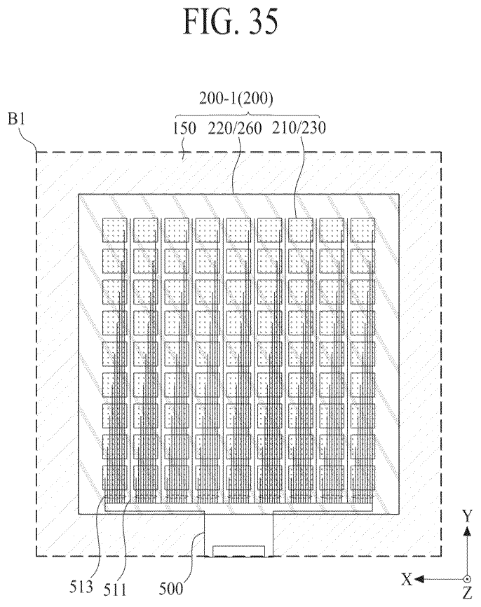

FIG. 34 illustrates a display apparatus according to another embodiment of the present disclosure. FIG. 35 is an enlarged view of a region B1 in FIG. 34. FIGS. 34 and 35 illustrate an embodiment implemented by modifying the plurality of vibration layers of the vibration generating apparatus described above with reference to FIGS. 28 to 30 and 33. In the following description, therefore, a modified element will be described in detail, the other elements are referred to by the same reference numerals as FIGS. 28 to 30 and 33, and repeated descriptions thereof may be omitted or will be briefly given.

Referring to FIGS. 34 and 35, a vibration generating apparatus 200 can include a first vibration generating apparatus 200-1 provided in a first region A1 of a display panel 100 and a second vibration generating apparatus 200-2 provided in a second region A2 of the display panel 100.

Each of the first vibration generating apparatus 200-1 and the second vibration generating apparatus 200-2 can include a plurality of vibrator blocks configured with a plurality of vibration layers 210 and a plurality of electrode layers 230. Each of the first vibration generating apparatus 200-1 and the second vibration generating apparatus 200-2 can further include a cover member 260. Each of the first vibration generating apparatus 200-1 and the second vibration generating apparatus 200-2 can use a plate member 150 (or a conductive substrate) of the display panel 100 as a driving electrode.

In each of the first vibration generating apparatus 200-1 and the second vibration generating apparatus 200-2, except for a size (or an area), the plurality of vibrator blocks configured with the plurality of vibration layers 210 and the plurality of electrode layers 230 can be substantially the same as the plurality of vibrator blocks described above with reference to FIG. 33, and thus, repeated descriptions thereof may be omitted or will be briefly given. The plurality of vibrator blocks can be provided in an N*M form (where N and M can be the same or different natural numbers of 2 or more) having a certain interval in the first direction X and the second direction Y. The descriptions of the plurality of vibration layers 210 included in the plurality of vibrator blocks described above with reference to FIG. 33 can be included in descriptions of the plurality of vibration layers 210 illustrated in FIGS. 34 and 35.

The plurality of vibration layers 210 included in the plurality of vibrator blocks can be provided to have a size (or an area) which enables the display panel 100 to be bent to have a certain curvature radius, or allows the display panel 100 not to be damaged or broken down when being bent. For example, each of the plurality of vibration layers 210 included in the plurality of vibrator blocks can be a micro vibration layer.

Each of the plurality of electrode layers 230 included in the plurality of vibrator blocks can be configured to have the same shape (in a plan view) as that of a corresponding vibration layer 210 of the plurality of vibration layers 210. An insulation layer 220 can be provided to cover the plate member 150 (or the conductive substrate) at a periphery of the plurality of vibrator blocks. Further, the cover member 260 can be provided to cover the insulation layer 220 and the plurality of vibration layers 210 and the plurality of electrode layers 230 included in each of the plurality of vibrator blocks in common.

The signal cable 500 can include one or more first contact lines 511 electrically coupled to (or connected to) the plate member 150 and a plurality of second contact lines 513 electrically coupled to (or connected to) the plurality of electrode layers 230 and can be substantially the same as the signal cable 500 described above with reference to FIG. 33, and thus, repeated descriptions thereof may be omitted.

In each of the first vibration generating apparatus 200-1 and the second vibration generating apparatus 200-2, each of the plurality of vibrator blocks can identically vibrate or can independently (or individually) vibrate based on the same or different second vibration driving signals. For example, one or more of second vibration driving signals applied to the plurality of vibrator blocks can differ. Therefore, each of the first vibration generating apparatus 200-1 and the second vibration generating apparatus 200-2 can output a 2 or more-channel sound. For example, when all of the second vibration driving signals applied to the plurality of vibrator blocks differ, each of the first vibration generating apparatus 200-1 and the second vibration generating apparatus 200-2 can generate a sound of N*M channels.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

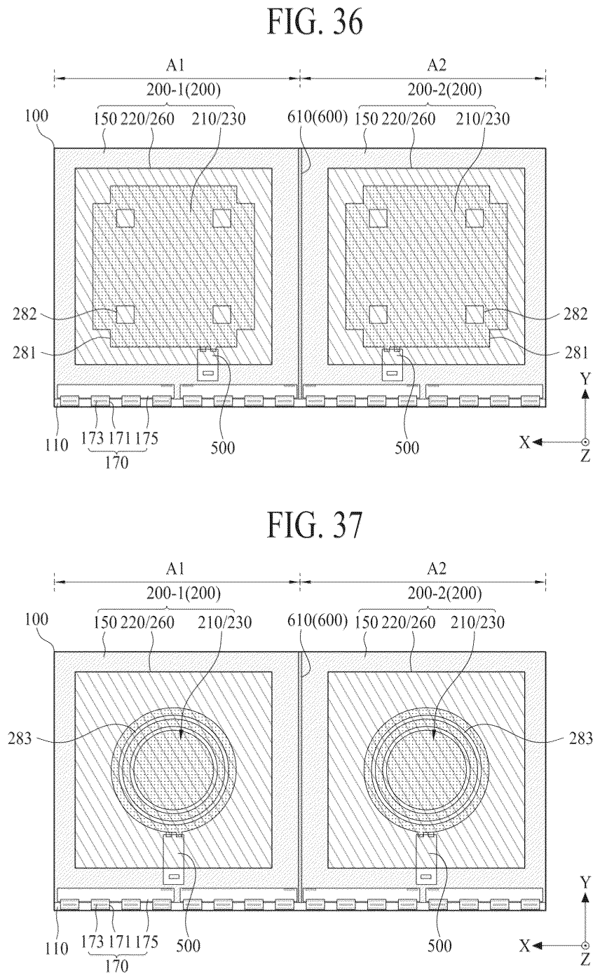

FIG. 36 illustrates a display apparatus according to another embodiment of the present disclosure. FIG. 36 illustrates an embodiment implemented by modifying the plurality of vibration layers of the vibration generating apparatus described above with reference to FIGS. 28 to 30. In the following description, therefore, a modified element will be described in detail, the other elements are referred to by the same reference numerals as FIGS. 28 to 30, and repeated descriptions thereof may be omitted or will be briefly given.

Referring to FIG. 36a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, a plurality of vibration layers 210 can be configured to have a size (or an area) which is less than that of the first region A1 of the display panel 100 and is greater than half of the first region A1 of the display panel 100. For example, in the first region A1 of the display panel 100, the first vibration generating apparatus 200-1 can be provided to have a square shape having a size (or an area) which is greater than half of the first region A1 and is less than a total size of the first region A1. The first vibration generating apparatus 200-1 can include a first pattern 281 where some of a plurality of corner portions included in the square shape are removed and/or a second pattern 282 where a portion of an inner portion of the square shape is removed. Accordingly, a sound characteristic and/or a sound pressure level characteristic of a sound generated based on a vibration of the first region A1 of the display panel 100 can be adjusted, and the flatness of a sound characteristic can be improved. For example, a plurality of vibration layers 210 of the first vibration generating apparatus 200-1 can be molded after being formed or coated in a square shape on a second surface of a plate member 150 (or a conductive substrate) corresponding to the first region A1 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, a plurality of vibration layers 210 can be configured to have a size (or an area) which is less than that of the second region A2 of the display panel 100 and is greater than half of the second region A2 of the display panel 100. For example, in the second region A2 of the display panel 100, the second vibration generating apparatus 200-2 can be provided to have a square shape having a size (or an area) which is greater than half of the second region A2 and is less than a total size of the second region A2. The second vibration generating apparatus 200-2 can include a first pattern 281 where some of a plurality of corner portions included in the square shape are removed and/or a second pattern 282 where a portion of an inner portion of the square shape is removed. Accordingly, a sound characteristic and/or a sound pressure level characteristic of a sound generated based on a vibration of the second region A2 of the display panel 100 can be adjusted, and the flatness of a sound characteristic can be improved. For example, a plurality of vibration layers 210 of the second vibration generating apparatus 200-2 can be molded after being formed or coated in a square shape on a second surface of a plate member 150 (or a conductive substrate) corresponding to the second region A2 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

FIG. 37 illustrates a display apparatus according to another embodiment of the present disclosure. FIG. 37 illustrates an embodiment implemented by modifying the plurality of vibration layers of the vibration generating apparatus described above with reference to FIGS. 28 to 30 and 32. In the following description, therefore, a modified element will be described in detail, the other elements are referred to by the same reference numerals as FIGS. 28 to 30 and 32, and repeated descriptions thereof may be omitted or will be briefly given.

Referring to FIG. 37a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, a plurality of vibration layers 210 can be configured to have a circular shape having a size (or an area) which is less than or equal to half of the first region A1 of the display panel 100, but embodiments of the present disclosure are not limited thereto and the plurality of vibration layers 210 can be provided to have a circular shape having a size (or an area) which is greater than half of the first region A1 and is less than a total size of the first region A1. The plurality of vibration layers 210 can include a third pattern 283 where a portion of an inner portion of the circular shape is removed. For example, the third pattern 283 can have a circular shape and a concentric circle and can be disposed between the plurality of vibration layers 210 having the circular shape. Therefore, the plurality of vibration layers 210 can configure a vibration source (or a vibrator) having a circular shape, and thus, a vibration characteristic or a sound output characteristic can be enhanced, a sound characteristic and/or a sound pressure level characteristic of a sound of a middle-low pitched sound band generated based on a vibration of the first region A1 of the display panel 100 can be enhanced, and the flatness of a sound characteristic can be improved. For example, a plurality of vibration layers 210 of the first vibration generating apparatus 200-1 can be molded after being formed or coated in a circular shape including the third pattern 283 on a second surface of a plate member 150 (or a conductive substrate) corresponding to the first region A1 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, a plurality of vibration layers 210 can be configured to have a circular shape having a size (or an area) which is less than or equal to half of the second region A2 of the display panel 100, but embodiments of the present disclosure are not limited thereto and the plurality of vibration layers 210 can be provided to have a circular shape having a size (or an area) which is greater than half of the second region A2 and is less than a total size of the second region A2 and can include a third pattern 283 where a portion of an inner portion of the circular shape is removed. For example, the third pattern 283 can have a circular shape and a concentric circle and can be disposed between the plurality of vibration layers 210 having the circular shape. Therefore, the plurality of vibration layers 210 can configure a vibration source (or a vibrator) having a circular shape, and thus, a vibration characteristic or a sound output characteristic can be enhanced, a sound characteristic and/or a sound pressure level characteristic of a sound of a middle-low pitched sound band generated based on a vibration of the second region A2 of the display panel 100 can be enhanced, and the flatness of a sound characteristic can be improved. For example, a plurality of vibration layers 210 of the second vibration generating apparatus 200-2 can be molded after being formed or coated in a circular shape including the third pattern 283 on a second surface of a plate member 150 (or a conductive substrate) corresponding to the second region A2 of the display panel 100. A plurality of electrode layers 230 can be provided to have the same shape as that of the plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

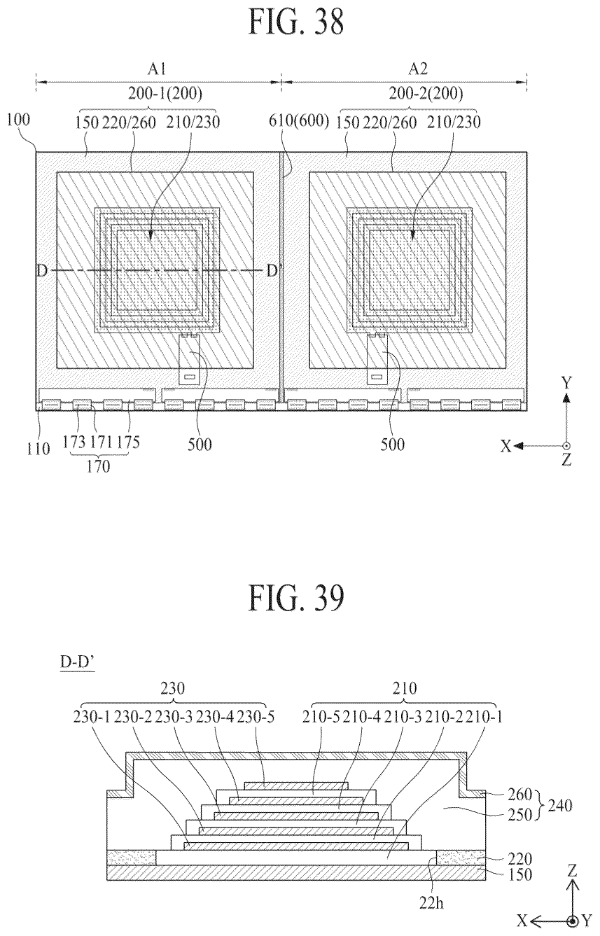

FIG. 38 illustrates a display apparatus according to another embodiment of the present disclosure. FIG. 39 is a cross-sectional view taken along line D-D′ in FIG. 38. FIGS. 38 and 39 illustrate an embodiment implemented by modifying the plurality of vibration layers of the vibration generating apparatus described above with reference to FIGS. 28 to 30. In the following description, therefore, a modified element will be described in detail, the other elements are referred to by the same reference numerals as FIGS. 28 to 30, and repeated descriptions thereof may be omitted or will be briefly given.

Referring to FIG. 38, a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, the plurality of vibration layers 210 can be configured to have different sizes (or areas) or different shapes. For example, the plurality of vibration layers 210 can include a first vibration layer 210-1, a second vibration layer 210-2, a third vibration layer 210-3, a fourth vibration layer 210-4, and a fifth vibration layer 210-5. For example, the first vibration layer 210-1, the second vibration layer 210-2, the third vibration layer 210-3, the fourth vibration layer 210-4, and the fifth vibration layer 210-5 can be configured to have different sizes (or areas) or different shapes. For example, the first vibration layer 210-1 can be configured to have a size (or an area) which is less than that of the first region A1 of the display panel 100 and is greater than half of the first region A1 of the display panel 100. Also, the second vibration layer 210-2 can be configured to have a size (or an area) which is less than that of the first vibration layer 210-1. Further, the third vibration layer 210-3 can be configured to have a size (or an area) which is less than that of the second vibration layer 210-2. Also, the fourth vibration layer 210-4 can be configured to have a size (or an area) which is less than that of the third vibration layer 210-3. Further, the fifth vibration layer 210-5 can be configured to have a size (or an area) which is less than that of the fourth vibration layer 210-4. For example, in the first region A1 of the display panel 100, the first vibration generating apparatus 200-1 can be provided to have a pyramid shape having a size (or an area), which is greater than half of the first region A1 and is less than a total size of the first region A1, and having a step height in a thickness direction Z.

Therefore, a sound characteristic and/or a sound pressure level characteristic of a sound generated based on a vibration of the first region A1 of the display panel 100 can be adjusted. For example, a plurality of vibration layers 210 of the first vibration generating apparatus 200-1 can be molded after being formed or coated in a pyramid shape, where a size (or an area) is sequentially reduced, on a second surface of a plate member 150 (or a conductive substrate) corresponding to the first region A1 of the display panel 100. Each of a plurality of electrode layers 230 can be provided to have the same shape as a corresponding (or adjacent) plurality of vibration layers 210. An insulation layer 220 can be provided to cover the plate member 150 (or the conductive substrate) at a periphery of each of the plurality of vibration layers 210 and the plurality of electrode layers 230. In the first vibration generating apparatus 200-1, the plurality of electrode layers 230 can include a first electrode layer 230-1, a second electrode layer 230-2, a third electrode layer 230-3, a fourth electrode layer 230-4, and a fifth electrode layer 230-5. For example, the plurality of vibration layers 210 and the plurality of electrode layers 230 can be alternately stacked or formed. Further, a cover member 260 can be configured to cover the insulation layer 220, the plurality of vibration layers 210, and the plurality of electrode layers 230.

In the second vibration generating apparatus 200-2, the plurality of vibration layers 210 can be configured to have different sizes (or areas) or different shapes. For example, the plurality of vibration layers 210 can include a first vibration layer 210-1, a second vibration layer 210-2, a third vibration layer 210-3, a fourth vibration layer 210-4, and a fifth vibration layer 210-5. For example, the first vibration layer 210-1, the second vibration layer 210-2, the third vibration layer 210-3, the fourth vibration layer 210-4, and the fifth vibration layer 210-5 can be configured to have different sizes (or areas) or different shapes. For example, the first vibration layer 210-1 can be configured to have a size (or an area) which is less than that of the second region A2 of the display panel 100 and is greater than half of the second region A2 of the display panel 100. Also, the second vibration layer 210-2 can be configured to have a size (or an area) which is less than that of the first vibration layer 210-1. Further, the third vibration layer 210-3 can be configured to have a size (or an area) which is less than that of the second vibration layer 210-2. Also, the fourth vibration layer 210-4 can be configured to have a size (or an area) which is less than that of the third vibration layer 210-3. Further, the fifth vibration layer 210-5 can be configured to have a size (or an area) which is less than that of the fourth vibration layer 210-4. For example, in the second region A2 of the display panel 100, the second vibration generating apparatus 200-2 can be provided to have a pyramid shape having a size (or an area), which is greater than half of the second region A2 and is less than a total size of the second region A2, and having a step height in a thickness direction Z.

Therefore, a sound characteristic and/or a sound pressure level characteristic of a sound generated based on a vibration of the second region A2 of the display panel 100 can be adjusted. For example, a plurality of vibration layers 210 of the second vibration generating apparatus 200-2 can be molded after being formed or coated in a pyramid shape, where a size (or an area) is sequentially reduced, on a second surface of a plate member 150 (or a conductive substrate) corresponding to the second region A2 of the display panel 100. In the second vibration generating apparatus 200-2, the plurality of electrode layers 230 can include a first electrode layer 230-1, a second electrode layer 230-2, a third electrode layer 230-3, a fourth electrode layer 230-4, and a fifth electrode layer 230-5. For example, the plurality of vibration layers 210 and the plurality of electrode layers 230 can be alternately stacked or formed. Each of a plurality of electrode layers 230 can be provided to have the same shape as a corresponding (or adjacent) plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

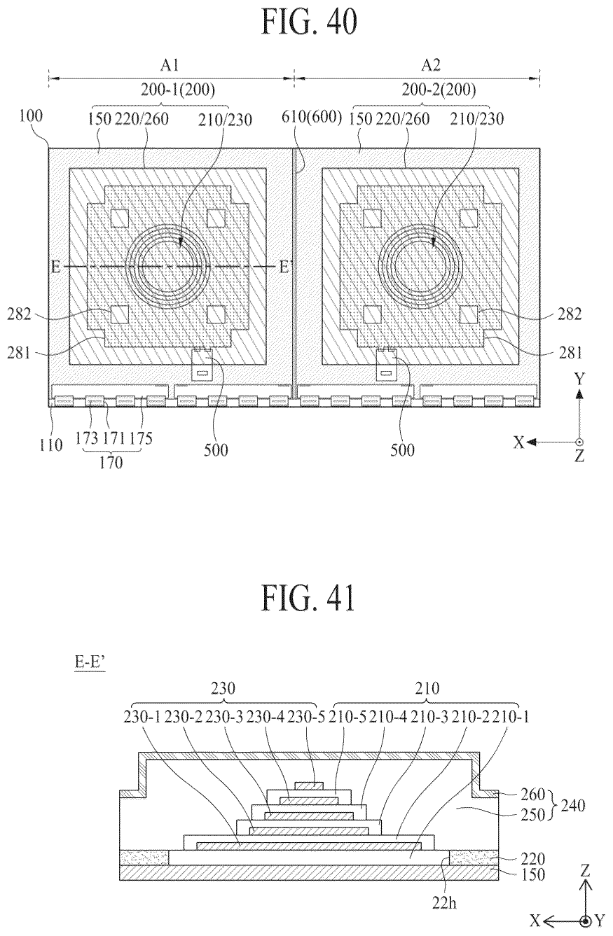

FIG. 40 illustrates a display apparatus according to another embodiment of the present disclosure. FIG. 41 is a cross-sectional view taken along line E-E′ in FIG. 40. FIGS. 40 and 41 illustrate an embodiment implemented by modifying the plurality of vibration layers of the vibration generating apparatus described above with reference to FIGS. 28 to 30. In the following description, therefore, a modified element will be described in detail, the other elements are referred to by the same reference numerals as FIGS. 28 to 30, and repeated descriptions thereof may be omitted or will be briefly given.

Referring to FIG. 40, a vibration generating apparatus 200 can include a first vibration generating apparatus 200-1 provided in a first region A1 of a display panel 100 and a second vibration generating apparatus 200-2 provided in a second region A2 of the display panel 100.

In the first vibration generating apparatus 200-1, the plurality of vibration layers 210 can be configured to have different sizes (or areas) or different shapes. For example, the plurality of vibration layers 210 can include a first vibration layer 210-1, a second vibration layer 210-2, a third vibration layer 210-3, a fourth vibration layer 210-4, and a fifth vibration layer 210-5. For example, the first vibration layer 210-1, the second vibration layer 210-2, the third vibration layer 210-3, the fourth vibration layer 210-4, and the fifth vibration layer 210-5 can be configured to have different sizes (or areas) or different shapes. For example, the first vibration layer 210-1 can be provided to have a square shape having a size (or an area) which is greater than half of the first region A1 of the display panel 100 and is less than that of the first region A1 of the display panel 100. The first vibration layer 210-1 can include a first pattern 281 where some of a plurality of corner portions included in the square shape are removed and/or a second pattern 282 where a portion of an inner portion of the square shape is removed. Also, the second vibration layer 210-2 can be configured to have a size (or an area) which is less than that of the first vibration layer 210-1. Further, the third vibration layer 210-3 can be configured to have a circular shape having a size (or an area) which is less than that of the second vibration layer 210-2. Also, the fourth vibration layer 210-4 can be configured to have a circular shape having a size (or an area) which is less than that of the third vibration layer 210-3. Further, the fifth vibration layer 210-5 can be configured to have a circular shape having a size (or an area) which is less than that of the fourth vibration layer 210-4. For example, in the first region A1 of the display panel 100, the first vibration generating apparatus 200-1 can be provided to have a pyramid shape having a size (or an area), which is greater than half of the first region A1 and is less than a total size of the first region A1, and having a step height in a thickness direction Z. Therefore, a sound characteristic and/or a sound pressure level characteristic of a sound generated based on a vibration of the first region A1 of the display panel 100 can be adjusted. For example, a plurality of vibration layers 210 of the first vibration generating apparatus 200-1 can be molded after being formed or coated in a different shape, where a size (or an area) is sequentially reduced, on a second surface of a plate member 150 (or a conductive substrate) corresponding to the first region A1 of the display panel 100. Each of a plurality of electrode layers 230 can be provided to have the same shape as a corresponding (or adjacent) plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

In the second vibration generating apparatus 200-2, the plurality of vibration layers 210 can be configured to have different sizes (or areas) or different shapes. For example, the plurality of vibration layers 210 can include a first vibration layer 210-1, a second vibration layer 210-2, a third vibration layer 210-3, a fourth vibration layer 210-4, and a fifth vibration layer 210-5. For example, the first vibration layer 210-1, the second vibration layer 210-2, the third vibration layer 210-3, the fourth vibration layer 210-4, and the fifth vibration layer 210-5 can be configured to have different sizes (or areas) or different shapes. For example, the first vibration layer 210-1 can be provided to have a square shape having a size (or an area) which is greater than half of the second region A2 of the display panel 100 and is less than that of the second region A2 of the display panel 100. The first vibration layer 210-1 can include a first pattern 281 where some of a plurality of corner portions included in the square shape are removed and/or a second pattern 282 where a portion of an inner portion of the square shape is removed. Further, the second vibration layer 210-2 can be configured to have a size (or an area) which is less than that of the first vibration layer 210-1. Also, the third vibration layer 210-3 can be configured to have a circular shape having a size (or an area) which is less than that of the second vibration layer 210-2. Further, the fourth vibration layer 210-4 can be configured to have a circular shape having a size (or an area) which is less than that of the third vibration layer 210-3. Furthermore, the fifth vibration layer 210-5 can be configured to have a circular shape having a size (or an area) which is less than that of the fourth vibration layer 210-4. For example, in the second region A2 of the display panel 100, the second vibration generating apparatus 200-2 can be provided to have a pyramid shape having a size (or an area), which is greater than half of the second region A2 and is less than a total size of the second region A2, and having a step height in a thickness direction Z.

Therefore, a sound characteristic and/or a sound pressure level characteristic of a sound generated based on a vibration of the second region A2 of the display panel 100 can be adjusted. For example, a plurality of vibration layers 210 of the second vibration generating apparatus 200-2 can be molded after being formed or coated in a different shape, where a size (or an area) is sequentially reduced, on a second surface of a plate member 150 (or a conductive substrate) corresponding to the second region A2 of the display panel 100. Each of a plurality of electrode layers 230 can be provided to have the same shape as a corresponding (or adjacent) plurality of vibration layers 210. An insulation layer 220 can be provided to cover the plate member 150 (or the conductive substrate) at a periphery of each of the plurality of vibration layers 210 and the plurality of electrode layers 230. Further, a cover member 260 can be configured to cover the insulation layer 220, the plurality of vibration layers 210, and the plurality of electrode layers 230.

The first vibration generating apparatus 200-1 and the second vibration generating apparatus 200-2 can be provided to be horizontally symmetric with each other with respect to a center (or a partition member 610) between the first region A1 and the second region A2 of the display panel 100, but embodiments of the present disclosure are not limited thereto, and can be provided to be horizontally asymmetric with each other.

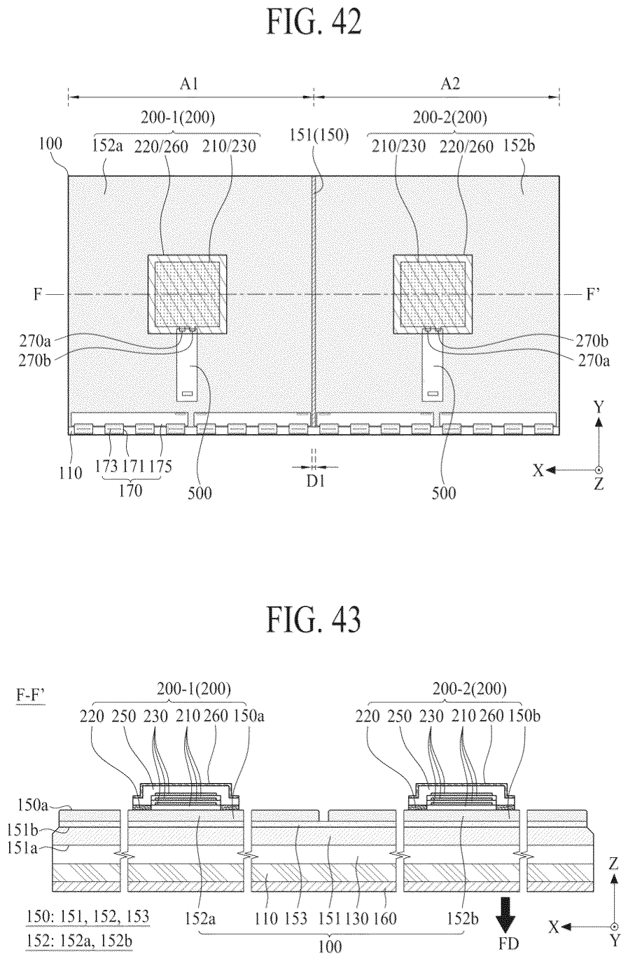

FIG. 42 illustrates a rear surface of a display panel and a vibration generating apparatus, in a display apparatus according to another embodiment of the present disclosure. FIG. 43 is a cross-sectional view taken along line F-F′ in FIG. 42. FIGS. 42 and 43 illustrate an embodiment implemented by modifying the plate member described above with reference to FIGS. 28 and 29. In the following description, therefore, a modified element will be described in detail, the other elements are referred to by the same reference numerals as FIGS. 28 and 29, and repeated descriptions thereof may be omitted or will be briefly given.

Referring to FIGS. 42 and 43, a plate member 150 of a display panel 100 can include an internal plate 151 and a plurality of external plates 152. For example, the internal plate 151 can be a first plate, but embodiments of the present disclosure are not limited thereto. For example, the plurality of external plates 152 can be a second plate, but embodiments of the present disclosure are not limited thereto.

The internal plate 151 can be substantially the same as the plate member 150 described above with reference to FIGS. 22 to 24, and thus, repeated descriptions thereof may be omitted or will be briefly given.

The internal plate 151 can be provided to cover a display part 130. The internal plate 151 can be attached on the display part 130 by an adhesive member. The adhesive member can be provided on a base member 110 to surround the display part 130. A first surface 151a of the internal plate 151 can be coupled to (or attached on) the adhesive member, or can be directly coupled to (or attached on) the adhesive member. The internal plate 151 can additionally or effectively dissipate heat which occurs in the display panel 100, and thus, can minimize a reduction in image quality caused by an afterimage which partially occurs due to heat occurring in the display panel 100. The internal plate 151 can protect the display part 130 or the display panel 100 from an external impact and can prevent external water or moisture from penetrating into a light emitting device layer 134. The internal plate 151 can compensate for the stiffness of the display panel 100. For example, the internal plate 151 can be an internal conductive plate, an internal heat dissipation member, an internal heat dissipation plate, an internal heat dissipation substrate, an encapsulation substrate, an encapsulation plate, a stiff plate, a second substrate, a rear substrate, a rear member, a rear plate, an internal substrate, or an internal plate, but embodiments of the present disclosure are not limited thereto.

The plurality of external plates 152 can be connected with or coupled to the internal plate 151. The plurality of external plates 152 can be spaced apart from or electrically disconnected from one another at a rear surface (or a second surface) 151b of the internal plate 151. The plurality of external plates 152 can be configured to additionally dissipate heat of the internal plate 151. For example, the plurality of external plates 152 can be provided to have a thickness which is relatively thinner than that of the internal plate 151.

According to embodiments, the plurality of external plates 152 can include one or more materials of a Fe—Ni alloy, stainless steel, Al, Mg, a Mg alloy, a Mg—Li alloy, and an Al alloy, but embodiments of the present disclosure are not limited thereto. For example, the plurality of external plates 152 can include one or more materials, which differ from the material of the internal plate 151, of a Fe—Ni alloy, stainless steel, Al, Mg, a Mg alloy, a Mg—Li alloy, and an Al alloy, but embodiments of the present disclosure are not limited thereto. For example, the plurality of external plates 152 can include Al or an Al alloy, but embodiments of the present disclosure are not limited thereto.

The plate member 150 or the plurality of external plates 152 according to embodiments can include a first external plate 152a and a second external plate 152b.

The first external plate 152a can be connected with or coupled to a first region of the internal plate 151 corresponding to a first region A1 of the display panel 100. The second external plate 152b can be connected with or coupled to a second region of the internal plate 151 corresponding to a second region A2 of the display panel 100.

Each of the first external plate 152a and the second external plate 152b can be coupled to (or connected to) a rear surface (or a second surface) 151b of the internal plate 151 by a coupling member 153.

The coupling member 153 can be disposed between the internal plate 151 and each of the first external plate 152a and the second external plate 152b.

The coupling member 153 according to embodiments can include an adhesive material which is good in adhesive force or attaching force between the internal plate 151 and each of the first external plate 152a and the second external plate 152b. For example, the coupling member 153 can include an acryl-based adhesive material or urethane-based adhesive material, but embodiments of the present disclosure are not limited thereto. For example, the coupling member 153 can include an acryl-based adhesive material, having a characteristic where an adhesive force is relatively good and hardness is high, compared to urethane-based adhesive material so that a vibration of the vibration generating apparatus 200 is well transferred to the internal plate 151. For example, the coupling member 153 can include an acryl-based adhesive resin curing layer or a double-sided foam adhesive pad including an acryl-based adhesive layer. The adhesive layer of the coupling member 153 can further include additives such as a tackifier, a wax component, or an anti-oxidation agent, but embodiments of the present disclosure are not limited thereto.

The coupling member 153 according to embodiments can include a PSA, an OCA, or an OCR, but embodiments of the present disclosure are not limited thereto. For example, the coupling member 153 can further include a vibration transfer medium. For example, the vibration transfer medium can reduce the loss of a vibration transferred to the internal plate 151. For example, the vibration transfer medium can include a piezoelectric material which is included in or added to the coupling member 153, but embodiments of the present disclosure are not limited thereto.

The coupling member 153 can further include a hollow portion provided between the internal plate 151 and each of the first external plate 152a and the second external plate 152b. The hollow portion of the coupling member 153 can provide a gap between the internal plate 151 and each of the first external plate 152a and the second external plate 152b. The air gap can allow a sound wave (or a sound pressure level) based on a vibration of the vibration generating apparatus 200 to concentrate on the internal plate 151 without being dispersed by the coupling member 153, and thus, can minimize the loss of a vibration by the coupling member 153.

The first external plate 152a and the second external plate 152b can be spaced apart from each other in a center region between the first region A1 and the second region A2 of the display panel 100. A separation distance DI between the first external plate 152a and the second external plate 152b can be 3 cm or more. For example, the separation distance DI between the first external plate 152a and the second external plate 152b can be 3 cm or more so that each of the first external plate 152a and the second external plate 152b vibrates individually (or independently). For example, when the separation distance DI between the first external plate 152a and the second external plate 152b is less than 3 cm, a sound characteristic and/or a sound pressure level characteristic can be reduced due to interference between a vibration of the first external plate 152a and a vibration of the second external plate 152b, which occurs due to a vibration of the vibration generating apparatus 200.

The vibration generating apparatus 200 can be configured to vibrate each of the plurality of external plates 152a and 152b. For example, the vibration generating apparatus 200 can be configured to use each of the plurality of external plates 152a and 152b as an electrode. For example, the vibration generating apparatus 200 can be configured to individually (or independently) vibrate each of the first and second external plates 152a and 152b. For example, the vibration generating apparatus 200 can be configured to use each of the first and second external plates 152a and 152b as an electrode. For example, the vibration generating apparatus 200 can include a first vibration generating apparatus 200-1 provided at a rear surface of the first external plate 152a and a second vibration generating apparatus 200-2 provided at a rear surface of the second external plate 152b.

Except for that the first vibration generating apparatus 200-1 and the second vibration generating apparatus 200-2 are respectively provided at the rear surface of the first external plate 152a and the rear surface of the second external plate 152b, the first vibration generating apparatus 200-1 and the second vibration generating apparatus 200-2 can be substantially the same as the first vibration generating apparatus 200-1 and the second vibration generating apparatus 200-2 described above with reference to FIG. 28, and thus repeated descriptions thereof may be omitted or will be briefly given.

The first vibration generating apparatus 200-1 can include a plurality of vibration layers 210 and a plurality of electrode layers 230. The plurality of vibration layers 210 of the first vibration generating apparatus 200-1 can be molded after being formed or coated on the rear surface of the first external plate 152a. The plurality of electrode layers 230 of the first vibration generating apparatus 200-1 can be configured to have the same shape as the plurality of vibration layers 210. The first vibration generating apparatus 200-1 can further include a cover member 260 provided to cover the plurality of vibration layers 210 and the plurality of electrode layers 230. In embodiments, the plurality of vibration layers 210 of the first vibration generating apparatus 200-1 can vibrate based on a first vibration driving signal applied to the first external plate 152a or a first contact pattern 270a through a signal cable 500 and a second vibration driving signal applied to a second contact pattern 270b through the signal cable 500, and thus, can vibrate the first external plate 152a and the first region A1 of the display panel 100 to output a first sound. In another embodiment of the present disclosure, the plurality of vibration layers 210 of the first vibration generating apparatus 200-1 can vibrate based on the second vibration driving signal applied to the first external plate 152a or the first contact pattern 270a through the signal cable 500 and the first vibration driving signal applied to the second contact pattern 270b through the signal cable 500, and thus, can vibrate the first external plate 152a and the first region A1 of the display panel 100 to output the first sound.

The second vibration generating apparatus 200-2 can include a plurality of vibration layers 210 and a plurality of electrode layers 230. The plurality of vibration layers 210 of the second vibration generating apparatus 200-2 can be molded after being formed or coated on the rear surface of the second external plate 152b. The plurality of electrode layers 230 of the second vibration generating apparatus 200-2 can be configured to have the same shape as the plurality of vibration layers 210. The second vibration generating apparatus 200-2 can further include a cover member 260 provided to cover the plurality of vibration layers 210 and the plurality of electrode layers 230. In embodiments, the plurality of vibration layers 210 of the second vibration generating apparatus 200-2 can vibrate based on a first vibration driving signal applied to the second external plate 152b or a first contact pattern 270a through a signal cable 500 and a second vibration driving signal applied to a second contact pattern 270b through the signal cable 500, and thus, can vibrate the second external plate 152b and the second region A2 of the display panel 100 to output a second sound. In another embodiment of the present disclosure, the plurality of vibration layers 210 of the second vibration generating apparatus 200-2 can vibrate based on the second vibration driving signal applied to the second external plate 152b or the first contact pattern 270a through the signal cable 500 and the first vibration driving signal applied to the second contact pattern 270b through the signal cable 500, and thus, can vibrate the second external plate 152b and the second region A2 of the display panel 100 to output the second sound.

The first vibration generating apparatus 200-1 and the second vibration generating apparatus 200-2 can be provided to be horizontally symmetric with each other with respect to a center between the first region A1 and the second region A2 of the display panel 100, but embodiments of the present disclosure are not limited thereto, and can be provided to be horizontally asymmetric with each other.

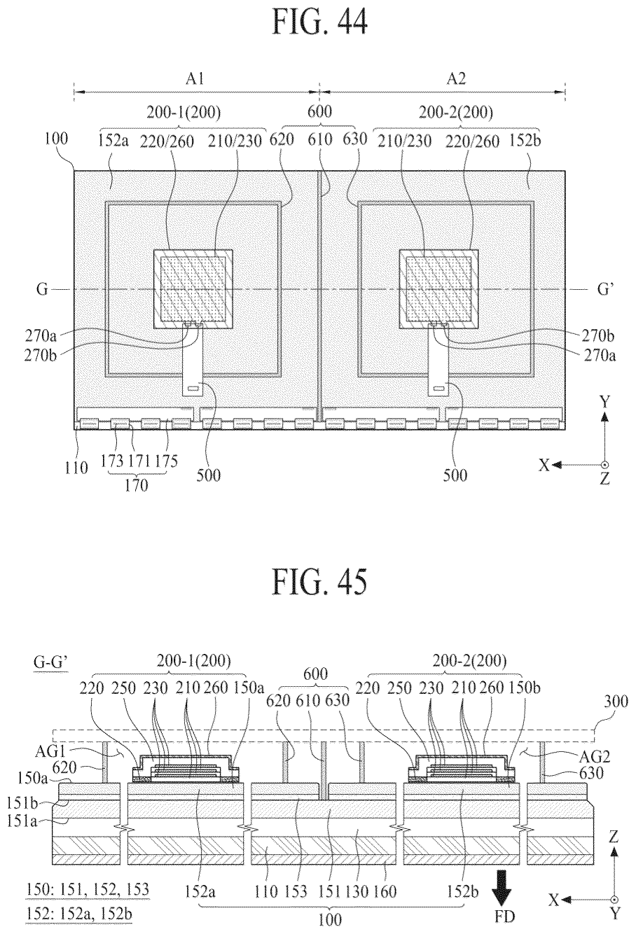

FIG. 44 illustrates a rear surface of a display panel and a vibration generating apparatus, in a display apparatus according to another embodiment of the present disclosure. FIG. 45 is a cross-sectional view taken along line G-G′ in FIG. 44. FIGS. 44 and 45 illustrate an embodiment where a partition is added to the display apparatus described above with reference to FIGS. 28 and 29. In the following description, therefore, a partition and relevant elements will be described in detail, the other elements are referred to by the same reference numerals as FIGS. 28 and 29, and repeated descriptions thereof may be omitted or will be briefly given.

Referring to FIGS. 44 and 45, the display apparatus can further include a partition 600 which divides a first region A1 and a second region A2 of the display panel 100.

The display panel 100 can include regions A1 and A2 which are divided to respectively correspond to a plurality of external plates 152. For example, the display panel 100 can include the regions A1 and A2 which are divided along a region between the plurality of external plates 152. For example, the display panel 100 can include a first region A1 overlapping a first external plate 152a of a plate member 150 and a second region A2 overlapping a second external plate 152a of the plate member 150.

The partition 600 can be an air gap or a space where a sound is generated when the display panel 100 is vibrated by the first and second vibration generating apparatuses 200-1 and 200-2. For example, the partition 600 can separate a sound or can separate a channel, and moreover, can prevent or decrease a reduction in characteristic of a sound caused by interference of the sound. The partition 600 can be disposed between the display panel 100 and a supporting member 300. For example, the partition 600 can be disposed between a rear surface of the display panel 100 and a front surface of the supporting member 300. To decrease an adverse effect of the partition 600 on the image quality of the display panel 100, the partition 600 can be disposed in the supporting member 300. The partition 600 can be referred to as a sound blocking member, a sound separation member, a space separation member, an enclosure, or a baffle, but embodiments of the present disclosure are not limited to the terms.

The partition 600 according to embodiments can include a partition member (or a first partition member) 610 disposed between the first and second vibration generating apparatuses 200-1 and 200-2.

The partition member 610 can be disposed between the first region A1 and the second region A2 of the display panel 100. The partition member 610 can be disposed between a supporting member 300 and an internal plate 151 of the plate member 150 between the first region A1 and the second region A2 of the display panel 100. For example, the partition member 610 can be disposed between the supporting member 300 and a second surface 151b of the internal plate 151 corresponding to a center region between the first region A1 and the second region A2 of the display panel 100. The partition member 610 can separate a first sound generated by the first vibration generating apparatus 200-1 and a second sound generated by the second vibration generating apparatus 200-2. For example, the partition member 610 can prevent a vibration, generated in the first region A1 of the display panel 100 by the first vibration generating apparatus 200-1, from being transferred to the second region A2 of the display panel 100, or can prevent a vibration, generated in the second region A2 of the display panel 100 by the second vibration generating apparatus 200-2, from being transferred to the first region A1 of the display panel 100. Therefore, the partition member 610 can attenuate or absorb a vibration of the display panel 100 at a center of the display panel 100, and thus, can prevent a sound of the first region A1 from being transferred to the second region A2 or can prevent a sound of the second region A2 from being transferred to the first region A1. Accordingly, the partition member 610 can separate a left sound and a right sound to further enhance a sound output characteristic of the display apparatus, and thus, the display apparatus according to embodiments can output a 2-channel sound and/or a stereo sound, including a 2-channel, in a forward direction of the display panel 100 based on the separation of the left and right sounds by the partition member 610.

The partition 600 according to embodiments can include a second partition member 620 surrounding the first vibration generating apparatus 200-1 and a third partition member 630 surrounding the second vibration generating apparatus 200-2.

The second partition member 620 can be disposed between the first region A1 of the display panel 100 and the supporting member 300 to surround the first vibration generating apparatus 200-1. The second partition member 620 can be disposed between the supporting member 300 and the first external plate 152a of the plate member 150 corresponding to the first region A1 of the display panel 100 and so as to be spaced apart from the first vibration generating apparatus 200-1 by a certain distance. The second partition member 620 can provide a first air gap AG1 surrounding the first vibration generating apparatus 200-1 between the first external plate 152a and the supporting member 300. For example, the second partition member 620 can define or limit a vibration region (or a vibration area) of the first region A1 of the display panel 100 by the first vibration generating apparatus 200-1.

The third partition member 630 can be disposed between the second region A2 of the display panel 100 and the supporting member 300 to surround the second vibration generating apparatus 200-2. The third partition member 630 can be disposed between the supporting member 300 and the second external plate 152b of the plate member 150 corresponding to the second region A2 of the display panel 100 and so as to be spaced apart from the second vibration generating apparatus 200-2 by a certain distance. The third partition member 630 can provide a second air gap AG2 surrounding the second vibration generating apparatus 200-2 between the second external plate 152b and the supporting member 300. For example, the third partition member 630 can define or limit a vibration region (or a vibration area) of the second region A2 of the display panel 100 by the second vibration generating apparatus 200-2.

The first air gap AG1 and a second air gap AG2 can be a sound separation space, a sound blocking space, or a sound interference prevention space, but embodiments of the present disclosure are not limited thereto.

Except for that each of the second and third partition members 620 and 630 is disposed between the supporting member 300 and the external plate 152 of the plate member 150, the second and third partition members 620 and 630 can be substantially the same as the second and third partition members 620 and 630 described above with reference to FIGS. 28 and 29, and thus, repeated descriptions thereof may be omitted.

The first vibration generating apparatus 200-1 and the second vibration generating apparatus 200-2 can be provided to be horizontally symmetric with each other with respect to a center between the first region A1 and the second region A2 of the display panel 100, but embodiments of the present disclosure are not limited thereto, and can be provided to be horizontally asymmetric with each other.

The vibration generating apparatus 200 described above with reference to FIGS. 30 to 41 can be identically applied to the vibration generating apparatus 200 described above with reference to FIGS. 44 and 45. For example, the vibration generating apparatus 200 described above with reference to FIGS. 44 and 45 can be configured to be equal to the vibration generating apparatus 200 described above with reference to FIGS. 30 to 41, and thus, repeated descriptions thereof may be omitted.

The display apparatus described above with reference to FIGS. 41 and 42 can output a sound in a forward direction FD of the display panel 100 and can be slimmed or reduced in thickness, and moreover, can more effectively dissipate heat which occurs in the display panel 100, thereby minimizing a reduction in image quality caused by an afterimage which partially occurs due to heat occurring in the display panel 100. Further, the display apparatus according to another embodiment of the present disclosure can output a 2-channel sound and/or a stereo sound, including a 2-channel, in a forward direction of the display panel 100 based on the separation of left and right sounds by one or more of the partition member 610 and the second and third partition members 620 and 630.

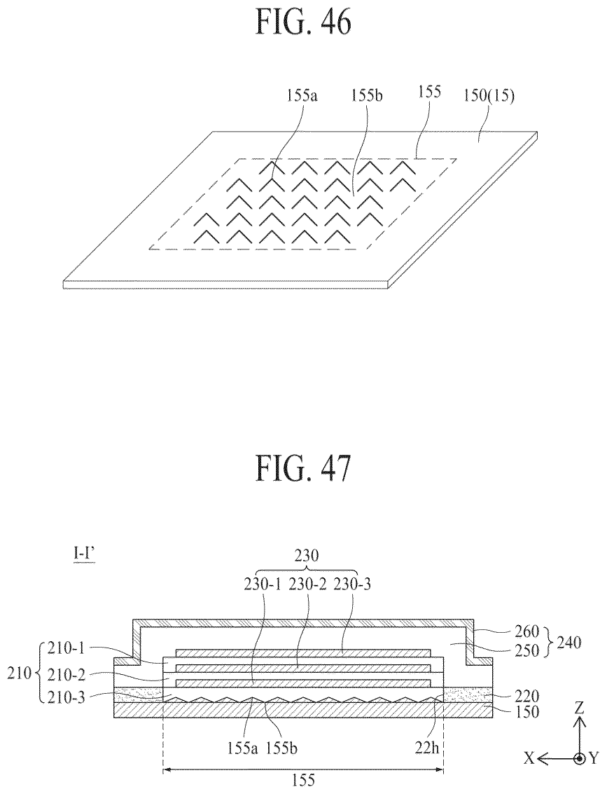

FIG. 46 illustrates a plate member according to another embodiment of the present disclosure. FIG. 47 illustrates a vibration generating apparatus to which the plate member of FIG. 46 is applied.

Referring to FIGS. 46 and 47, a plate member 150 (or a conductive substrate 15) of a display panel 100 can further include a concave-convex pattern part 155. FIG. 47 is another cross-sectional view taken along line I-I′ in FIG. 1, wherein the vibration generating apparatus employs the plate member according to FIG. 46.

The concave-convex pattern part 155 can be formed on at least a portion of a second surface of the plate member 150 (or the conductive substrate 15). The concave-convex pattern part 155 can have surface illumination (or surface roughness) which differs from that of another portion of the plate member 150 (or the conductive substrate 15). For example, the concave-convex pattern part 155 can include a protrusion portion (or convex portion) 155a protruding a surface of the plate member 150 (or the conductive substrate 15) and a recessed portion (or concave portion) 155b which is more recessed than the protrusion portion 155a.

The concave-convex pattern part 155 can be provided to overlap a plurality of vibration layers 210 and a plurality of electrode layers 230. The concave-convex pattern part 155 can increase a specific surface area by the protrusion portion 155a protruding from the surface and the recessed portion 155b recessed from the surface. Accordingly, a coupling force (or an adhesive force) between the plate member 150 (or the conductive substrate 15) and a corresponding (or adjacent) first vibration layer 210-1 can be increased by the concave-convex pattern part 155. For example, a coupling force (or an adhesive force) between a first surface of the first vibration layer 210-1 and a second surface 150a of the plate member 150 (or the conductive substrate 15) can be increased by the concave-convex pattern part 155. Therefore, the concave-convex pattern part 155 can increase a coupling force between the first vibration layer 210-1 and the plate member 150 (or the conductive substrate 15), thereby further enhancing a sound output characteristic of the display apparatus.

A vibration apparatus and a display apparatus including the same according to various embodiments of the present disclosure will be described below.

A vibration apparatus according to various embodiments of the present disclosure can include a conductive substrate, at least one vibration layer at one surface of the conductive substrate, and at least one electrode layer at one surface of the vibration layer. The vibration layer and the electrode layer may be alternately arranged in a stack on the surface of the conductive substrate.

According to various embodiments of the present disclosure, the plurality of vibration layers can be configured to vibrate in response to signals applied to the conductive substrate and the at least one electrode layer.

According to various embodiments of the present disclosure, the conductive substrate can be connected to a first signal line. An electrode layer among the one or more electrode layers adjacent to the conductive substrate can be connected to a second signal line different from the first signal line.

According to various embodiments of the present disclosure, the at least one vibration layer can be a plurality of the vibration layers, and the at least one electrode layer can be a plurality of electrode layer. Or, the at least one electrode layer can be provided to be equal to the number of the at least one vibration layer.

According to various embodiments of the present disclosure, a first electrode layer of the plurality of electrode layers can be connected to a first signal line and a second electrode layer of the plurality of electrode layers can be connected to a second signal line. The first electrode layer can be adjacent to the second electrode layer and the second signal line can be different from the first signal line.

According to various embodiments of the present disclosure, the first signal line and second signal line can be connected to a driver arranged to apply a first voltage signal to the first signal line and a second voltage signal to the second signal line, the second voltage can be different from the first voltage. Or, a difference between the first voltage signal and the second voltage signal can alternate between a positive and a negative voltage, and/or a magnitude of a difference between the first voltage signal and the second voltage signal can vary with time.

According to various embodiments of the present disclosure, the conductive substrate can be configured to be supplied with a different voltage to an electrode layer adjacent to the conductive substrate among the one or more electrode layers such that a potential difference is applied across a vibration layer of the one or more vibration layers sandwiched between the conductive substrate and the electrode layer adjacent to the conductive substrate.

According to various embodiments of the present disclosure, the conductive substrate can be configured to be supplied with a signal having a polarity different from a polarity of a signal supplied to an electrode layer adjacent to the conductive substrate among the one or more electrode layers.

According to various embodiments of the present disclosure, two adjacent electrode layers of the plurality of electrode layers can be configured to be supplied with a different voltage to each other such that a potential difference is applied across a vibration layer of the one or more vibration layers sandwiched between the two adjacent electrode layers.

According to various embodiments of the present disclosure, two adjacent electrode layers of the plurality of electrode layers can be configured to be supplied with signals having different polarities.

According to various embodiments of the present disclosure, the vibration apparatus can further include a protection layer disposed at the one surface of the conductive substrate and covering the plurality of vibration layers and the plurality of electrode layers.

According to various embodiments of the present disclosure, the vibration apparatus can further include one or more signal lines electrically coupled to (or connected to) the conductive substrate and the at least one electrode layer.

According to various embodiments of the present disclosure, the vibration apparatus can further include a protection layer covering a portion of the one or more signal lines, the vibration layer, and the electrode layer.

According to various embodiments of the present disclosure, two adjacent electrode layers of the plurality of electrode layers can be electrically insulated from each other by a corresponding vibration layer of the plurality of vibration layers disposed between the two adjacent electrode layers.

According to various embodiments of the present disclosure, the vibration apparatus can further include an insulation layer at the one surface of the conductive substrate, the insulation layer including an opening region exposing a portion of the one surface of the conductive substrate, the plurality of vibration layers can overlap the opening region of the insulation layer.

According to various embodiments of the present disclosure, the insulation layer can surround a vibration layer adjacent to the conductive substrate among the plurality of vibration layers. The conductive substrate and an electrode layer adjacent to the conductive substrate among the plurality of electrode layers can be electrically insulated from each other by the vibration layer adjacent to the conductive substrate and the insulation layer.

According to various embodiments of the present disclosure, each electrode layer can have a size different from a size of at least one adjacent vibration layer of the plurality of vibration layers, or can have a size less than or equal to a size of the at least one adjacent vibration layer.

According to various embodiments of the present disclosure, each electrode layer can have a size less than a size of a corresponding vibration layer of the plurality of vibration layers and can be disposed centrally on the corresponding vibration layer.

According to various embodiments of the present disclosure, each of the plurality of electrode layers can further include a contact pattern extending to the corresponding vibration layer and being exposed at an outside of the stack.

According to various embodiments of the present disclosure, the contact pattern of each electrode layer may not overlap a contact pattern of an adjacent electrode layer among the electrode layers.

According to various embodiments of the present disclosure, the vibration apparatus can further include at least one signal line electrically coupled to (or connected to) the conductive substrate and at least one contact pattern of the plurality of electrode layers.

According to various embodiments of the present disclosure, the conductive substrate and an uppermost electrode layer of the plurality of electrode layers can be supplied with signals having different polarities.

According to various embodiments of the present disclosure, at least one vibration layer between the conductive substrate and the uppermost electrode layer can further include at least one first through hole. At least one electrode layer between the conductive substrate and the uppermost electrode layer can further include at least one second through hole overlapping the at least one first through hole.

According to various embodiments of the present disclosure, a size of the at least one first through hole can be less than a size of the at least one second through hole.

According to various embodiments of the present disclosure, the at least one first through hole can include a first through hole of a first group provided to be electrically connected with an electrode layer of the first group supplied with a signal having a same polarity as the conductive substrate, in the conductive substrate, and a first through hole of a second group provided to be electrically connected with an electrode layer of the second group supplied with a signal having a same polarity as the uppermost electrode layer. The first through hole of the first group may not overlap the first through hole of the second group.

According to various embodiments of the present disclosure, one of the electrode layers can be electrically connected with the conductive substrate or the uppermost electrode layer by the at least one first through hole and the at least one second through hole. First and second through holes corresponding to the conductive substrate cannot overlap first and second through holes corresponding to the uppermost electrode layer.

According to various embodiments of the present disclosure, the at least one second through hole can include a second through hole of the first group provided to be electrically connected with the electrode layer of the first group, in the conductive substrate, and a second through hole of the second group provided to be electrically connected with the electrode layer of the second group. The second through hole of the first group may not overlap the second through hole of the second group.

According to various embodiments of the present disclosure, the one of the electrode layers can be supplied with a signal having a same polarity as the conductive substrate or the uppermost electrode layer.

According to various embodiments of the present disclosure, the vibration apparatus can further include at least one signal line electrically coupled to (or connected to) the conductive substrate and the uppermost electrode layer.

According to various embodiments of the present disclosure, the plurality of vibration layers can be unimorph-driven or bimorph-driven.

According to various embodiments of the present disclosure, at least a portion of the one surface of the conductive substrate can further include a patterned surface including a plurality of convex and/or concave features.

According to various embodiments of the present disclosure, the patterned surface can overlap the plurality of vibration layers.

According to various embodiments of the present disclosure, each of the vibration layers can include a three or more-angled polygonal shape, a non-tetragonal shape, a circular shape, or an oval shape

According to various embodiments of the present disclosure, each of the vibration layers can include a piezoelectric material.

According to various embodiments of the present disclosure, the conductive substrate can include one or more of an alloy of iron and nickel, stainless steel, aluminum, magnesium, a magnesium alloy.

According to various embodiments of the present disclosure, the magnesium alloy can be an alloy of magnesium and lithium.

According to various embodiments of the present disclosure, the at least one vibration layer can comprise a first piezoelectric material layer, a second piezoelectric material layer, and a third piezoelectric material layer. The at least one electrode layer can comprise a first electrode layer, a second electrode layer, and a third electrode layer. The conductive substrate and the second electrode layer can be configured to be connected to a first voltage supply line. The first electrode layer and the third electrode layer can be configured to be connected to a second voltage supply line different from the first voltage supply line such that the first, second and third piezoelectric material layers vibrate in a thickness direction of the conductive substrate in response to supplication of first and second voltage signal, respectively, to the first and second voltage supply lines.

A display apparatus according to various embodiments of the present disclosure can include a display panel, and one or more vibration generating apparatuses configured to vibrate the display panel. Each of the one or more vibration generating apparatuses can include a conductive substrate, at least one vibration layer at one surface of the conductive substrate, and at least one electrode at one surface of the vibration layer. The at least one electrode layer can correspond to one of the vibration layers. The vibration layers and the electrode layers can be alternately arranged in a stack on the surface of the conductive substrate. The vibration layers and the electrode layers can be alternately arranged in a stack on the surface of the conductive substrate.

According to various embodiments of the present disclosure, the display panel can include a display part between a base member and a plate member. The plate member can be provided as the conductive substrate of the vibration apparatus.

According to various embodiments of the present disclosure, the display part can include a plurality of pixels outputting light, emitted from a light emitting device layer, toward the base member.

According to various embodiments of the present disclosure, the display panel can include a first region and a second region. The one or more vibration generating apparatuses can include a first vibration generating apparatus in the first region, and a second vibration generating apparatus in the second region.

According to various embodiments of the present disclosure, the display apparatus can further include a partition dividing the first region and the second region of the display panel.

According to various embodiments of the present disclosure, the display apparatus can further include a supporting member at one surface of the plate member, the partition can include one or more of first to third partition members. The first partition member can be disposed between the plate member and the supporting member, in a region between the first region and the second region. The second partition member can be disposed between the plate member and the supporting member to surround the first vibration generating apparatus. The third partition member can be disposed between the plate member and the supporting member to surround the second vibration generating apparatus.

According to various embodiments of the present disclosure, the plate member can include an internal plate coupled to (or connected to) the display part, a first external plate coupled to (or connected to) a first region of the internal plate corresponding to the first region of the display panel, and a second external plate coupled to (or connected to) a second region of the internal plate corresponding to the second region of the display panel, the second external plate being spaced apart from the first external plate.

According to various embodiments of the present disclosure, each of the first external plate and the second external plate can be provided as the conductive substrate of the vibration apparatus. The first vibration generating apparatus can be configured to vibrate based on a signal applied through a first signal line electrically coupled to (or connected to) the first external plate and the electrode layer. The second vibration generating apparatus can be configured to vibrate based on a signal applied through a second signal line electrically coupled to (or connected to) the second external plate and the electrode layer.

According to various embodiments of the present disclosure, the display apparatus can further include a partition dividing the first region and the second region of the display panel.

According to various embodiments of the present disclosure, the display apparatus can further include a supporting member at one surface of the plate member. The partition can include one or more of first to third partition members. The first partition member can be disposed between the plate member and the supporting member, in a region between the first region and the second region. The second partition member can be disposed between the first external plate and the supporting member to surround the first vibration generating apparatus. The third partition member can be disposed between the second external plate and the supporting member to surround the second vibration generating apparatus.

An apparatus according to an embodiment of the present disclosure can be applied to or included in a vibration apparatus provided in the apparatus. The apparatus according to an embodiment of the present disclosure can be applied to or included in mobile apparatuses, video phones, smart watches, watch phones, wearable apparatuses, foldable apparatuses, rollable apparatuses, bendable apparatuses, flexible apparatuses, curved apparatuses, sliding apparatus, variable apparatus, electronic organizers, electronic book, portable multimedia players (PMPs), personal digital assistants (PDAs), MP3 players, mobile medical apparatuses, desktop personal computers (PCs), laptop PCs, netbook computers, workstations, navigation apparatuses, automotive navigation apparatuses, automotive display apparatuses, automotive apparatuses, theatrical apparatuses, theatrical display apparatuses, televisions (TVs), wall paper display apparatuses, signage apparatuses, game machines, notebook computers, monitors, cameras, camcorders, home appliances, etc. Further, the vibration apparatus according to embodiments of the present disclosure can be applied to or included in organic light emitting lighting apparatuses or inorganic light emitting lighting apparatuses. In a case where the vibration apparatus is applied to or included in a lighting apparatus, the vibration apparatus can act as lighting and a speaker. Further, in a case where the vibration apparatus according to embodiment of the present disclosure is applied to or included in a mobile apparatus, the vibration apparatus can be one or more of a speaker, a receiver, or a haptic, but embodiments of the present disclosure are not limited thereto.

It will be apparent to those skilled in the art that various modifications and variations can be made in the present disclosure without departing from the scope of the present disclosure. Thus, it is intended that the present disclosure covers the modifications and variations of this disclosure provided they come within the scope of the appended claims and their equivalents.

What is claimed is:

1. A vibration apparatus, comprising:
a conductive substrate;
at least one vibration layer at one surface of the conductive substrate; and
at least one electrode layer at one surface of the at least one vibration layer,
wherein the at least one vibration layer and the at least one electrode layer are alternately arranged in a stack on the surface of the conductive substrate.

2. The vibration apparatus of claim 1, wherein the at least one vibration layer is configured to vibrate in response to signals applied to the conductive substrate and the at least one electrode layer.

3. The vibration apparatus of claim 1, wherein the conductive substrate is connected to a first signal line, and
wherein an electrode layer among the one or more electrode layers adjacent to the conductive substrate is connected to a second signal line different from the first signal line.

4. The vibration apparatus of claim 1, wherein the at least one vibration layer is a plurality of vibration layers, and the at least one electrode layer is a plurality of electrode layers, or
wherein the at least one electrode layer is provided to be equal to the number of the at least one vibration layer.

5. The vibration apparatus of claim 4, wherein a first electrode layer of the plurality of electrode layers is connected to a first signal line and a second electrode layer of the plurality of electrode layers is connected to a second signal line, and wherein the first electrode layer is adjacent to the second electrode layer and the second signal line is different from the first signal line.

6. The vibration apparatus of claim 5, wherein the first signal line and second signal line are connected to a driver arranged to apply a first voltage signal to the first signal line and a second voltage signal to the second signal line, and wherein the second voltage is different from the first voltage, or
wherein a difference between the first voltage signal and the second voltage signal alternates between a positive voltage and a negative voltage, and/or
wherein a magnitude of a difference between the first voltage signal and the second voltage signal varies with time.

7. The vibration apparatus of claim 1, wherein the conductive substrate is configured to be supplied with a different voltage to an electrode layer adjacent to the conductive substrate among the one or more electrode layers such that a potential difference is applied across a vibration layer of the one or more vibration layers sandwiched between the conductive substrate and the electrode layer adjacent to the conductive substrate.

8. The vibration apparatus of claim 2, wherein the conductive substrate is configured to be supplied with a signal having a polarity different from a polarity of a signal supplied to an electrode layer adjacent to the conductive substrate among the one or more electrode layers.

9. The vibration apparatus of claim 4, wherein two adjacent electrode layers of the plurality of electrode layers are configured to be supplied with a different voltage to each other such that a potential difference is applied across a vibration layer of the one or more vibration layers sandwiched between the two adjacent electrode layers.

10. The vibration apparatus of claim 4, wherein two adjacent electrode layers of the plurality of electrode layers are configured to be supplied with signals having different polarities.

11. The vibration apparatus of claim 4, further comprising a protection layer disposed at the one surface of the conductive substrate and covering the plurality of vibration layers and the plurality of electrode layers.

12. The vibration apparatus of claim 1, further comprising one or more signal lines electrically coupled to the conductive substrate and the at least one electrode layer.

13. The vibration apparatus of claim 12, further comprising a protection layer covering a portion of the one or more signal lines, the at least one vibration layer, and the at least one electrode layer.

14. The vibration apparatus of claim 4, wherein two adjacent electrode layers of the plurality of electrode layers are electrically insulated from each other by a corresponding vibration layer of the plurality of vibration layers disposed between the two adjacent electrode layers.

15. The vibration apparatus of claim 4, further comprising an insulation layer at the one surface of the conductive substrate, the insulation layer including an opening region exposing a portion of the one surface of the conductive substrate,
wherein the plurality of vibration layers overlap the opening region of the insulation layer.

16. The vibration apparatus of claim 15, wherein the insulation layer surrounds a vibration layer adjacent to the conductive substrate among the plurality of vibration layers, and
wherein the conductive substrate and an electrode layer adjacent to the conductive substrate among the plurality of electrode layers are electrically insulated from each other by the vibration layer adjacent to the conductive substrate and the insulation layer.

17. The vibration apparatus of claim 4, wherein each electrode layer has a size different from a size of at least one adjacent vibration layer of the plurality of vibration layers, or has a size less than or equal to a size of the at least one adjacent vibration layer.

18. The vibration apparatus of claim 17, wherein each electrode layer has a size less than a size of a corresponding vibration layer of the plurality of vibration layers and is disposed centrally on the corresponding vibration layer.

19. The vibration apparatus of claim 17, wherein each of the plurality of electrode layers further comprises a contact pattern extending to the corresponding vibration layer and being exposed at an outside of the stack.

20. The vibration apparatus of claim 19, wherein the contact pattern of each electrode layer does not overlap a contact pattern of an adjacent electrode layer among the plurality of electrode layers.

21. The vibration apparatus of claim 19, further comprising at least one signal line electrically coupled to the conductive substrate and at least one contact pattern of the plurality of electrode layers.

22. The vibration apparatus of claim 1, wherein the conductive substrate and an uppermost electrode layer of the plurality of electrode layers are supplied with signals having different polarities.

23. The vibration apparatus of claim 22, wherein at least one vibration layer between the conductive substrate and the uppermost electrode layer further comprises at least one first through hole, and
wherein at least one electrode layer between the conductive substrate and the uppermost electrode layer further comprises at least one second through hole overlapping the at least one first through hole.

24. The vibration apparatus of claim 23, wherein a size of the at least one first through hole is less than a size of the at least one second through hole.

25. The vibration apparatus of claim 23, wherein one of the electrode layers is electrically connected with the conductive substrate or the uppermost electrode layer via the at least one first through hole and the at least one second through hole, and
wherein first and second through holes corresponding to the conductive substrate do not overlap first and second through holes corresponding to the uppermost electrode layer.

26. The vibration apparatus of claim 25, wherein the one of the electrode layers is supplied with a signal having a same polarity as the conductive substrate or the uppermost electrode layer.

27. The vibration apparatus of claim 22, further comprising at least one signal line electrically coupled to the conductive substrate and the uppermost electrode layer.

28. The vibration apparatus of claim 1, wherein the plurality of vibration layers are unimorph-driven or bimorph-driven.

29. The vibration apparatus of claim 1, wherein at least a portion of the one surface of the conductive substrate further comprises a patterned surface including a plurality of convex and/or concave features.

30. The vibration apparatus of claim 29, wherein the patterned surface overlaps the plurality of vibration layers.

31. The vibration apparatus of claim 1, wherein each of the vibration layers comprises a three or more-angled polygonal shape, a non-tetragonal shape, a circular shape, or an oval shape.

32. The vibration apparatus of claim 1, wherein each of the vibration layers comprises a piezoelectric material.

33. The vibration apparatus of claim 1, wherein the conductive substrate comprises one or more materials of an alloy of iron and nickel, stainless steel, aluminum, magnesium, a magnesium alloy, and an aluminum alloy.

34. The vibration apparatus of claim 33, wherein the magnesium alloy is an alloy of magnesium and lithium.

35. The vibration apparatus of claim 1,
wherein the at least one vibration layer comprises a first piezoelectric material layer, a second piezoelectric material layer and a third piezoelectric material layer,
wherein the at least one electrode layer comprises a first electrode layer, a second electrode layer and a third electrode layer,
wherein the conductive substrate and the second electrode layer are configured to be connected to a first voltage supply line, and
wherein the first electrode layer and the third electrode layer are configured to be connected to a second voltage supply line different from the first voltage supply line such that the first, second and third piezoelectric material layers vibrate in a thickness direction of the conductive substrate in response to application of first and second voltage signal, respectively, to the first and second voltage supply lines.

36. A display apparatus, comprising:
a display panel; and
one or more vibration generating apparatuses configured to vibrate the display panel,
wherein each of the one or more vibration generating apparatuses comprises:
a conductive substrate;
at least one vibration layer at one surface of the conductive substrate; and
at least one electrode layer at one surface of the vibration layer, and
wherein the vibration layer and the electrode layer are alternately arranged in a stack on the surface of the conductive substrate.

37. The display apparatus of claim 36, wherein the display panel comprises a display part between a base member and a plate member, and
wherein the plate member is provided as the conductive substrate of the vibration apparatus.

38. The display apparatus of claim 37, wherein the display part comprises a plurality of pixels outputting light emitted from a light emitting device layer toward the base member.

39. The display apparatus of claim 37, wherein the display panel comprises a first region and a second region, and
wherein the one or more vibration generating apparatuses comprise:
a first vibration generating apparatus in the first region; and
a second vibration generating apparatus in the second region.

40. The display apparatus of claim 39, further comprising a partition dividing the first region and the second region of the display panel.

41. The display apparatus of claim 40, further comprising a supporting member at one surface of the plate member,
wherein the partition comprises one or more of first to third partition members,
wherein the first partition member is disposed between the plate member and the supporting member, in a region between the first region and the second region,
wherein the second partition member is disposed between the plate member and the supporting member to surround the first vibration generating apparatus, and
wherein the third partition member is disposed between the plate member and the supporting member to surround the second vibration generating apparatus.

42. The display apparatus of claim 39, wherein the plate member comprises:
an internal plate coupled to the display part;
a first external plate coupled to a first region of the internal plate corresponding to the first region of the display panel; and
a second external plate coupled to a second region of the internal plate corresponding to the second region of the display panel, the second external plate being spaced apart from the first external plate.

43. The display apparatus of claim 42, wherein:
each of the first external plate and the second external plate is provided as the conductive substrate of the vibration apparatus;
the first vibration generating apparatus is configured to vibrate in response to a signal applied through a first signal line electrically coupled to the first external plate and the at least one electrode layer; and
the second vibration generating apparatus is configured to vibrate based on a signal applied through a second signal line electrically coupled to the second external plate and the at least one electrode layer.

44. The display apparatus of claim 43, further comprising a partition dividing the first region and the second region of the display panel.

45. The display apparatus of claim 44, further comprising a supporting member at one surface of the plate member,
wherein the partition comprises one or more of first to third partition members,
wherein the first partition member is disposed between the plate member and the supporting member, in a region between the first region and the second region,
wherein the second partition member is disposed between the first external plate and the supporting member to surround the first vibration generating apparatus, and
wherein the third partition member is disposed between the second external plate and the supporting member to surround the second vibration generating apparatus.
